(19) United States
(12) Patent Application Publication
(10) Pub. No.: US 2009/0184424 A1
(43) Pub. Date: Jul. 23, 2009

(54) SEMICONDUCTOR DEVICE AND A METHOD OF MANUFACTURING THE SAME

(75) Inventors: Takeshi Furusawa, Tokyo (JP); Takao Kamoshima, Tokyo (JP); Masatsugu Amishiro, Tokyo (JP)

Correspondence Address: MILES & STOCKBRIDGE PC, 1751 PINNACLE DRIVE, SUITE 500, MCLEAN, VA, 22102-3833, US

(73) Assignee: RENESAS TECHNOLOGY CORP.

(21) Appl. No.: 12/350,268

(22) Filed: Jan. 8, 2009

(30) Foreign Application Priority Data
Jan. 18, 2008 (JP) 2008-009023

(51) Int. Cl. H01L 23/522; H01L 21/768

(52) U.S. Cl. 257/758; 438/622; 257/E23.142; 257/E21.585

(57) ABSTRACT

The production of a crack in an insulating film under an external terminal of a semiconductor device due to external force applied to the external terminal is suppressed or prevented. Over the principal surface of a semiconductor substrate, there are formed multiple wiring layers. In the fifth wiring layer directly under the uppermost wiring layer of the wiring layers, the following measure is taken: a conductor pattern (fifth wiring, dummy wiring, and plug) is not formed directly under the probe contact area of each bonding pad PD in the uppermost wiring layer. In the fifth wiring layer, conductor patterns (fifth wiring, dummy wirings, and plugs) are formed in the areas other than directly under the probe contact area of each bonding pad in the uppermost wiring layer.

### CROSS-REFERENCE TO RELATED APPLICATIONS

The disclosure of Japanese Patent Application No. 2008-9023 filed on Jan. 18, 2008 including the specification, drawings and abstract is incorporated herein by reference in its entirety.

### BACKGROUND OF THE INVENTION

The present invention relates to semiconductor devices and manufacturing techniques therefor and in particular to a technique for suppressing or preventing the production of a crack in an insulating film under an external terminal of a semiconductor device due to external force applied to the external terminal.

Manufacturing processes for semiconductor devices include a probe inspection step. At this step, a probe (exploring needle) is applied to a bonding pad (hereafter, simply referred to as pad) as an external terminal of a semiconductor chip formed in a semiconductor wafer to inspect a semiconductor device for electrical characteristics. The external force (impact) applied to the pad at this time causes cracking in an insulating film under the pad and as a result, a problem of the degraded reliability of semiconductor devices arises.

Japanese Unexamined Patent Publication No. 2005-50963 (Patent Document 1) discloses a configuration in which a stress buffer layer is formed directly under a bonding pad using an aluminum wiring layer.

As a technique for suppressing or preventing cracking under a pad mentioned above, for example, the following technique is disclosed in Japanese Unexamined Patent Publication No. 2005-109491 (Patent Document 2): a reinforcing layer formed of high-melting point metal is provided under a contact pad and a first metal layer substantially identical in size with the pad and formed of copper or aluminum is further formed thereunder. In the disclosed configuration, multiple pieces of high-melting point metal arranged at certain intervals or high-melting point metal in a lattice pattern is used as the reinforcing layer.

For example, Japanese Unexamined Patent Publication No. 2003-324122 (Patent Document 3) discloses the following. configuration: a reinforcing layer formed of tungsten or tungsten alloy, substantially identical in size with a pad and 1 μm in thickness, is buried in an interlayer insulating film under a bonding pad.

For example, Japanese Unexamined Patent Publication No. 2002-324797 (Patent Document 4) discloses the following configuration: a high-melting point metal layer is provided in contact with the surface of a first pad and a second pad is further provided in contact with the surface thereof. The high-melting point metal layer is filled in a pad opening formed in an insulating film over the first pad and is provided in contact with the first pad and the second pad. The first pad is substantially identical in size with the second pad.

For example, Japanese Unexamined Patent Publication No. Hei 10 (1998)-199925 (Patent Document 5) discloses a configuration in which a tungsten structure is buried in an insulating layer under a pad. Patent Document 5 also discloses the following configurations: a configuration in which multiple tungsten structures arranged at certain intervals are provided in contact with the under surfaces of pads; and a configuration in which a tungsten structure is provided in a wiring layer directly under a pad so that the tungsten structure is not in contact with the pad.

For example, Japanese Unexamined Patent Publication No. 2003-68740 (Patent Document 6) discloses the following configuration: a configuration in which a laminated film having a U cross-sectional shape, formed of tungsten, is provided between a pad and the wiring of a wiring layer directly thereunder in contact with the pad and the wiring. The laminated film of tungsten and the wiring layer directly thereunder are substantially identical in size with the pad.
[Patent Document 1]
Japanese Unexamined Patent Publication No. 2005-50963
[Patent Document 2]
Japanese Unexamined Patent Publication No. 2005-109491
[Patent Document 3]
Japanese Unexamined Patent Publication No. 2003-324122
[Patent Document 4]
Japanese Unexamined Patent Publication No. 2002-324797
[Patent Document 5]
Japanese Unexamined Patent Publication No. Hei 10 (1998)-199925
[Patent Document 6]
Japanese Unexamined Patent Publication No. 2003-68740

In recent years, an element or a wiring has come to be disposed also under a pad for the purpose of reducing the area of a semiconductor chip. For this reason, it has become a significant challenge how a crack should be prevented from being produced in an insulating film under a pad. When an element or the like is disposed under a pad, therefore, the necessity for taking the following measures, especially, as in Patent Documents 1 to 6 has grown: forming a stress buffer layer directly under a pad using the same material as that of a wiring layer; providing reinforcement using tungsten or high-melting point metal that is higher in modulus of elasticity and less prone to be plastically deformed than SiO₂; and the like

According to the review by the present inventors, however, these techniques involve problems. When a stress buffer layer is formed of the same metal (aluminum or copper) as a wiring layer directly under a pad as disclosed in Patent Document 1, the following takes place: the stress buffer layer is plastically deformed by impact produced when a probe is applied to a pad. This causes cracking in an insulating film in the wiring layer and this cracking propagates to lower layers. Even when a reinforcing layer of tungsten or high-melting point metal is used as disclosed in Patent Documents 2 to 6, problems arise. First, with the structure in which a wiring layer (aluminum or copper) is in contact with the area directly under tungsten or high-melting point metal, as disclosed in Patent Documents 2, 4, and 6, the following takes place: a crack is produced in the tungsten or high-melting point metal by plastic deformation of the wiring layer and this plastic deformation propagates to lower layers. The plastic deformation becomes larger with increase in the width of the directly under wiring layer and when the width is substantially the same as the size of a pad (30 to 100 μm), cracking becomes especially notable. Second, when there are an area containing tungsten and an area free from tungsten as disclosed in Patent Documents 2 and 5, a crack is produced in the interface therebetween and propagates to lower layers. Third, when a thick film of tungsten high in stress is formed as disclosed in Patent Document 3, the tungsten is stripped by its own stress.

In every area, including areas under pads, in a chip, the following measure is generally taken to adjust the pattern occupation ratio to some degree or above: a dummy pattern formed of wiring material is formed in areas low in the density of wiring pattern in each wiring layer. The reason for this is as follows: if there is any area low in occupation ratio, a difference of elevation is produced at a CMP step and upper layers are brought out of focus during lithography.

When an element or a wiring is not disposed directly under a pad, a dummy pattern could also be disposed directly under the pad for the above purpose. According to the review by the present inventors, however, the following problem arises when a dummy pattern exists also directly under a pad: the dummy pattern (wiring material) is plastically deformed by impact produced when a probe is applied to the pad and a crack is produced in an insulating film; and this crack propagates to lower layers.

When a crack exists in an insulating film in a wiring layer as mentioned above, moisture enters from there and causes a problem of the degraded reliability of a device or a wiring. Further, when a wire bond or a bump receives force because of heat stress after packaging, a pad portion is stripped starting at the above area of cracking and this causes a problem of breaking of wire.

When a low-dielectric constant film (Low-k film) low in mechanical strength is used for the insulating film of a wiring layer, the above problems of cracking and stripping become especially notable.

One of methods for suppressing or preventing the above cracking is to reduce the probe pressure of a probe at a probe inspection step. When the probe pressure is reduced, the contact resistance between the probe and pads is increased and the electrical characteristics of semiconductor devices cannot be accurately measured. As a result, a problem of the degraded reliability of semiconductor devices arises.

### SUMMARY OF THE INVENTION

It is an object of the invention to provide a technique that makes it possible to suppress or prevent the production of a crack in an insulating film under an external terminal of a semiconductor device due to external force applied to the external terminal.

The above and other objects and novel features of the invention will be apparent from the description in this specification and the accompanying drawings.

The following is a brief description of the gist of an embodiment of the invention laid open in this application.

In this embodiment, the following measure is taken in the wiring layer directly under the uppermost wiring layer of multiple wiring layers formed over the principal surface of a semiconductor substrate: a conductor pattern is not formed directly under a first area of an external terminal formed in the uppermost wiring layer and a conductor pattern is formed in the areas other than directly under the first area of the external terminal.

The following is a brief description of the gist of another embodiment of the invention laid open in this application.

In this embodiment, the following measure is taken directly under a first area of an external terminal formed in the uppermost wiring layer of multiple wiring layers formed over the principal surface of a semiconductor substrate: a conductor pattern having a U cross-sectional shape formed of high-melting point metal, a high-melting point metal nitride, or a laminated body of them is formed on the under surface of the external terminal. The conductor pattern is so formed that the conductor pattern is in contact with the under surface of the external terminal and does not have an interface within the first area of the external terminal. In the wiring layer directly under the uppermost wiring layer, a conductor pattern does not exist directly under the first area of the external terminal or the conductor pattern having a U cross-sectional shape.

The following is a brief description of the gist of the effect obtained by embodiments of the invention laid open in this application.

The production of a crack in an insulating film under an external terminal of a semiconductor device due to external force applied to the external terminal can be suppressed or prevented.

### BRIEF DESCRIPTION OF THE DRAWINGS

FIG. 1 is a plan view of a substantial part of a semiconductor chip of a semiconductor device in an embodiment of the invention;

FIG. 2 is sectional views of the semiconductor chip in FIG. 1, the left sketch being taken along line Y1-Y1 in the internal area of the semiconductor chip in FIG. 1 and the right sketch being taken along line X1-X1 in a pad placement area of the semiconductor chip in FIG. 1;

FIG. 3 is an enlarged sectional view of wiring layers in the area encircled with broken line A in FIG. 2;

FIG. 4 is an enlarged sectional view of wiring layers in the area encircled with broken line B in FIG. 2;

FIG. 5 is a substantial part plan view illustrating the layout of conductor patterns in a fifth wiring layer in proximity to a pad formation region of the semiconductor chip in FIG. 1;

FIG. 6 is a substantial part plan view illustrating the layout of conductor patterns in a fourth wiring layer in proximity to a pad formation region of the semiconductor chip in FIG. 1;

FIG. 7 is a sectional view of a substantial part of a semiconductor chip reviewed by the present inventors;

FIG. 8 is a substantial part plan view illustrating the layout of conductor patterns in a fifth wiring layer in proximity to a pad formation region of the semiconductor chip in FIG. 7;

FIG. 9 is a substantial part plan view illustrating the layout of conductor patterns in a fourth wiring layer in proximity to a pad formation region of the semiconductor chip in FIG. 7;

FIG. 10 is sectional views illustrating the internal area (left) and a pad placement area (right) of a semiconductor substrate in a manufacturing process for the semiconductor device described with reference to FIG. 1 to FIG. 6;

FIG. 11 is sectional views of the internal area (left) and the pad placement area (right) of the semiconductor substrate in the manufacturing process for the semiconductor device, following FIG. 10;

FIG. 12 is sectional views of the internal area (left) and the pad placement area (right) of the semiconductor substrate in the manufacturing process for the semiconductor device, following FIG. 11;

FIG. 13 is sectional views of the internal area (left) and the pad placement area (right) of the semiconductor substrate in the manufacturing process for the semiconductor device, following FIG. 12;

FIG. 14 is sectional views of the internal area (left) and the pad placement area (right) of the semiconductor substrate in the manufacturing process for the semiconductor device, following FIG. 13;

FIG. 15 is sectional views of the internal area (left) and the pad placement area (right) of the semiconductor substrate in the manufacturing process for the semiconductor device, following FIG. 14;

FIG. 16 is a substantial part plan view illustrating the layout of conductor patterns in a fifth wiring layer in proximity to a pad formation region in a modification to the semiconductor chip in FIG. 1;

FIG. 17 is a substantial part plan view illustrating the layout of conductor patterns in a fourth wiring layer in proximity to a pad formation region in a modification to the semiconductor chip in FIG. 1;

FIG. 18 is sectional views of a semiconductor chip of a semiconductor device in another embodiment (second embodiment) of the invention, the left sketch illustrating the internal area corresponding to the area taken along line Y1-Y1 of FIG. 1 and the right sketch illustrating a pad placement area of the same semiconductor chip corresponding to the area taken along line X1-X1 of FIG. 1;

FIG. 19 is a substantial part plan view illustrating the layout of conductor patterns in a fifth wiring layer in proximity to a pad formation region of the semiconductor chip in FIG. 18;

FIG. 20 is a substantial part plan view illustrating the layout of conductor patterns in a fourth wiring layer in proximity to a pad formation region of the semiconductor chip in FIG. 18;

FIG. 21 is a sectional view of a substantial part of a semiconductor chip reviewed by the present inventors;

FIG. 22 is a sectional view of a substantial part of a semiconductor chip reviewed by the present inventors;

FIG. 23 is a substantial part plan view illustrating the layout of conductor patterns in a fifth wiring layer in proximity to a pad formation region in a modification to the semiconductor chip in FIG. 18;

FIG. 24 is sectional views of a semiconductor chip of a semiconductor device in another embodiment (third embodiment) of the invention, the left sketch illustrating the internal area corresponding to the area taken along line Y1-Y1 of FIG. 1 and the right sketch illustrating a pad placement area of the same semiconductor chip corresponding to the area taken along line X1-X1 of FIG. 1;

FIG. 25 is a substantial part plan view illustrating the layout of conductor patterns in a fifth wiring layer in proximity to a pad formation region of the semiconductor chip in FIG. 24;

FIG. 26 is a substantial part plan view illustrating the layout of conductor patterns in a fourth wiring layer in proximity to a pad formation region of the semiconductor chip in FIG. 24;

FIG. 27 is sectional views of a semiconductor chip of a semiconductor device in another embodiment (fourth embodiment) of the invention, the left sketch illustrating the internal area corresponding to the area taken along line Y1-Y1 of FIG. 1 and the right sketch illustrating a pad placement area of the same semiconductor chip corresponding to the area taken along line X1-X1 of FIG. 1;

FIG. 28 is an enlarged sectional view of a substantial part of the uppermost wiring layer in the pad placement area of the semiconductor chip in FIG. 27;

FIG. 29 is a sectional view of a pad placement part of the uppermost wiring layer of a semiconductor device reviewed by the present inventors;

FIG. 30 is sectional views of the internal area (left) and a pad placement area (right) of a substrate in a manufacturing process for the semiconductor device described with reference to FIG. 27 and FIG. 28;

FIG. 31 is sectional views of the internal area (left) and the pad placement area (right) of the substrate in the manufacturing process for the semiconductor device described with reference to FIG. 27 and FIG. 28, following FIG. 30;

FIG. 32 is sectional views of the internal area (left) and the pad placement area (right) of the substrate in the manufacturing process for the semiconductor device described with reference to FIG. 27 and FIG. 28, following FIG. 31;

FIG. 33 is sectional views of the internal area (left) and the pad placement area (right) of the substrate in the manufacturing process for the semiconductor device described with reference to FIG. 27 and FIG. 28, following FIG. 32;

FIG. 34 is sectional views of a semiconductor chip of a semiconductor device in another embodiment (fifth embodiment) of the invention, the left sketch illustrating the internal area corresponding to the area taken along line Y1-Y1 of FIG. 1 and the right sketch illustrating a pad placement area of the same semiconductor chip corresponding to the area taken along line X1-X1 of FIG. 1;

FIG. 35 is sectional views of a semiconductor chip of a semiconductor device in another embodiment (sixth embodiment) of the invention, the left sketch illustrating the internal area corresponding to the area taken along line Y1-Y1 of FIG. 1 and the right sketch illustrating a pad placement area of the same semiconductor chip corresponding to the area taken along line X1-X1 of FIG. 1;

FIG. 36 is sectional views of a semiconductor chip of a semiconductor device in another embodiment (seventh embodiment) of the invention, the left sketch illustrating the internal area corresponding to the area taken along line Y1-Y1 of FIG. 1 and the right sketch illustrating a pad placement area of the same semiconductor chip corresponding to the area taken along line X1-X1 of FIG. 1;

FIG. 37 is a substantial part plan view illustrating the layout of conductor patterns in a fifth wiring layer in proximity to a pad formation region of the semiconductor chip in FIG. 36;

FIG. 38 is a substantial part plan view illustrating the layout of conductor patterns in a fourth wiring layer in proximity to a pad formation region of the semiconductor chip in FIG. 36;

FIG. 39 is a substantial part plan view illustrating the layout of conductor patterns in a fifth wiring layer in proximity to a pad formation region of a semiconductor chip reviewed by the present inventors;

FIG. 40 is sectional views of a semiconductor chip of a semiconductor device in another embodiment (eighth embodiment) of the invention, the left sketch illustrating the internal area corresponding to the area taken along line Y1-Y1 of FIG. 1 and the right sketch illustrating a pad placement area of the same semiconductor chip corresponding to the area taken along line X1-X1 of FIG. 1;

FIG. 41 is a substantial part plan view illustrating the layout of conductor patterns in a fourth wiring layer in proximity to a pad formation region of the semiconductor chip in FIG. 40;

FIG. 42 is sectional views of a semiconductor chip of a semiconductor device in another embodiment (ninth embodiment) of the invention, the left sketch illustrating the internal area corresponding to the area taken along line Y1-Y1 of FIG. 1 and the right sketch illustrating a pad placement area of the same semiconductor chip corresponding to the area taken a long line X1-X1 of FIG. 1;

FIG. 43 is a substantial part plan view illustrating the layout of conductor patterns in a fifth wiring layer in proximity to a pad formation region of the semiconductor chip in FIG. 42;

FIG. 44 is a substantial part plan view illustrating the layout of conductor patterns in a fifth wiring layer in proximity to a pad formation region in a modification to the semiconductor chip in FIG. 42;

FIG. 45 is sectional views of a semiconductor chip of a semiconductor device in another embodiment (10th embodiment) of the invention, the left sketch illustrating the internal area corresponding to the area taken along line Y1-Y1 of FIG. 1 and the right sketch illustrating a pad placement area of the same semiconductor chip corresponding to the area taken along line X1-X1 of FIG. 1;

FIG. 46 is a substantial part plan view illustrating the layout of conductor patterns in a fourth wiring layer in proximity to a pad formation region of the semiconductor chip in FIG. 45;

FIG. 47 is sectional views of a semiconductor chip of a semiconductor device in another embodiment (11th embodiment) of the invention, the left sketch illustrating the internal area corresponding to the area taken along line Y1-Y1 of FIG. 1 and the right sketch illustrating a pad placement area of the same semiconductor chip corresponding to the area taken along line X1-X1 of FIG. 1;

FIG. 48 is a substantial part plan view illustrating the layout of conductor patterns in a fifth wiring layer in proximity to a pad formation region of the semiconductor chip in FIG. 47;

FIG. 49 is sectional views of a semiconductor chip of a semiconductor device in another embodiment (12th embodiment) of the invention, the left sketch illustrating the internal area corresponding to the area taken along line Y1-Y1 of FIG. 1 and the right sketch illustrating a pad placement area of the same semiconductor chip corresponding to the area taken along line X1-X1 of FIG. 1;

FIG. 50 is a substantial part plan view illustrating the layout of conductor patterns in a fourth wiring layer in proximity to a pad formation region of the semiconductor chip in FIG. 49;

FIG. 51 is sectional views of a semiconductor chip of a semiconductor device in another embodiment (13th embodiment) of the invention, the left sketch illustrating the internal area corresponding to the area taken along line Y1-Y1 of FIG. 1 and the right sketch illustrating a pad placement area of the same semiconductor chip corresponding to the area taken along line X1-X1 of FIG. 1;

FIG. 52 is sectional views of a semiconductor chip of a semiconductor device in another embodiment (14th embodiment) of the invention, the left sketch illustrating the internal area corresponding to the area taken along line Y1-Y1 of FIG. 1 and the right sketch illustrating a pad placement area of the same semiconductor chip corresponding to the area taken along line X1-X1 of FIG. 1;

FIG. 53 is sectional views of a semiconductor chip of a semiconductor device in another embodiment (15th embodiment) of the invention, the left sketch illustrating the internal area corresponding to the area taken along line Y1-Y1 of FIG. 1 and the right sketch illustrating a pad placement area of the same semiconductor chip corresponding to the area taken along line X1-X1 of FIG. 1;

FIG. 54 is sectional views of a semiconductor chip of a semiconductor device in another embodiment (16th embodiment) of the invention, the left sketch illustrating the internal area corresponding to the area taken along line Y1-Y1 of FIG. 1 and the right sketch illustrating a pad placement area of the same semiconductor chip corresponding to the area taken along line X1-X1 of FIG. 1;

FIG. 55 is a substantial part plan view illustrating the layout of conductor patterns in a fifth wiring layer in proximity to a pad formation region of the semiconductor chip in FIG. 54; and

FIG. 56 is a substantial part plan view illustrating the layout of conductor patterns in a fourth wiring layer in proximity to a pad formation region of the semiconductor chip in FIG. 54.

### DETAILED DESCRIPTION OF THE PREFERRED EMBODIMENTS

When mention is made of any number of elements (including a number of pieces, a numeric value, a quantity, a range, and the like) in the following description of embodiments, the number is not limited to that specific number. Unless explicitly stated otherwise or the number is obviously limited to a specific number in principle, the foregoing applies and the number may be above or below that specific number. In the following description of embodiments, needless to add, their constituent elements (including elemental steps and the like) are not always indispensable unless explicitly stated otherwise or they are obviously indispensable in principle. Similarly, when mention is made of the shape, positional relation, or the like of a constituent element or the like in the following description of embodiments, it includes those substantially approximate or analogous to that shape or the like. This applies unless explicitly stated otherwise or it is apparent in principle that some shape or the like does not include those substantially approximate or analogous to that shape or the like. This is the same with the above-mentioned numeric values and ranges. In every drawing for explaining embodiments of the invention, members having the same function will be marked with the same numerals or codes and the repetitive description thereof will be omitted as much as possible.

In the description of embodiments of the invention, a bonding pad cited as an example of an external terminal will be simply referred to as pad. The high-melting point metal cited in the description of embodiments of the invention refers to a metal whose melting point is higher than that of copper.

Hereafter, detailed description will be given to embodiments of the invention with reference to the drawings.

### First Embodiment

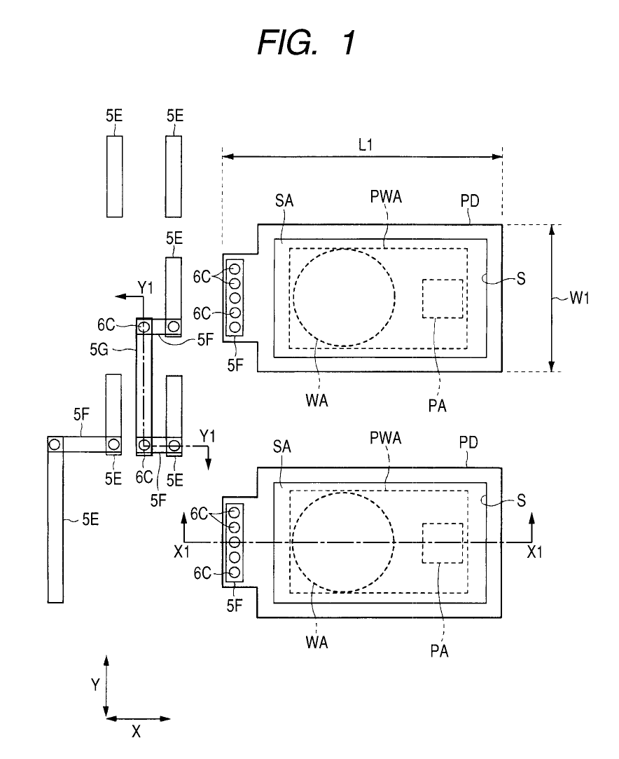

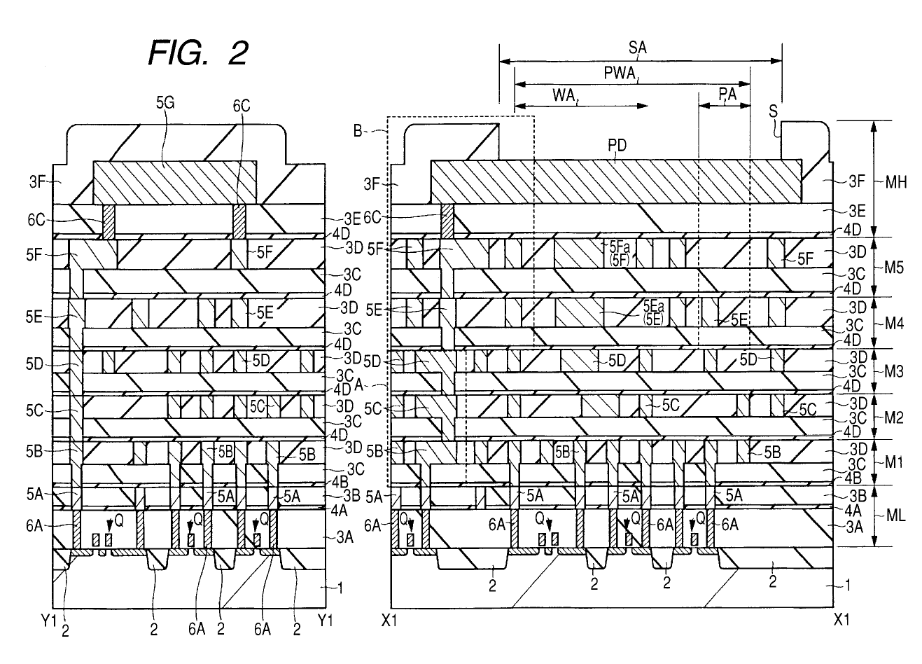

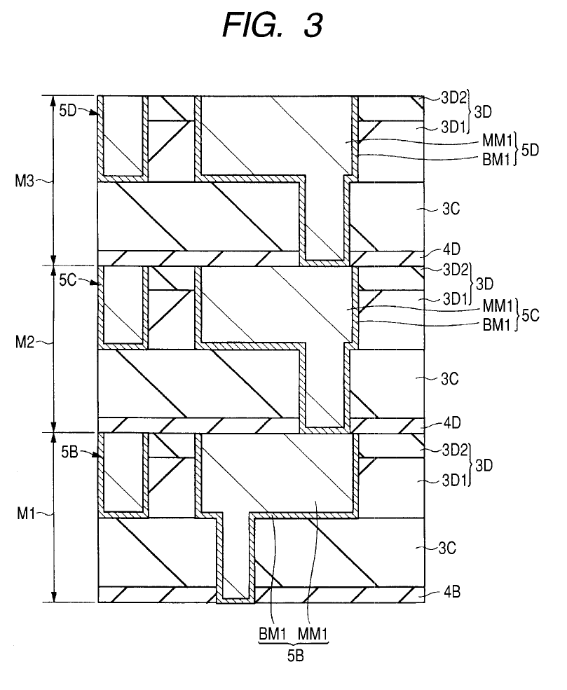

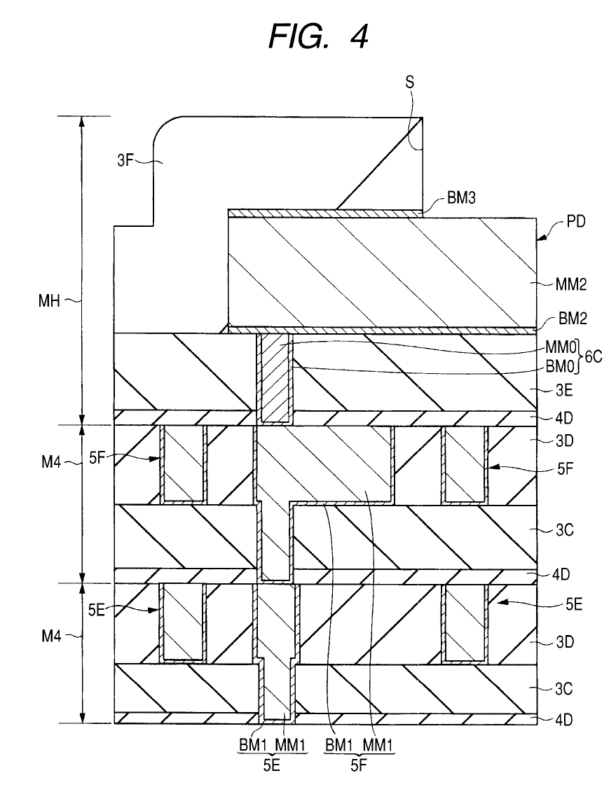

FIG. 1 is a plan view of a substantial part of a semiconductor chip of a semiconductor device in the first embodiment. The left sketch in FIG. 2 is a sectional view of the internal area of the semiconductor chip in FIG. 1 taken along line Y1-Y1 of FIG. 1. The right sketch in FIG. 2 is a sectional view of a pad placement area of the semiconductor chip in FIG. 1 taken along line X1-X1 of FIG. 1. FIG. 3 is an enlarged sectional view of wiring layers in the area encircled with broken line A in FIG. 2 and FIG. 4 is an enlarged sectional view of wiring layers in the area encircled with broken line B in FIG. 2. In FIG. 1, code X indicates a first direction and code Y indicates a second direction orthogonal to the first direction X.

The semiconductor substrate (hereafter, simply referred to as substrate) 1 comprising the semiconductor chip is formed of, for example, a p-type silicon (Si) single crystal. Over the principal surface (first principal surface) of this substrate 1, there is formed, for example, a trench-like isolation section 2. This trench-like isolation section 2 is formed by filling a trench formed in the principal surface of the substrate 1 with an insulating film of, for example, silicon oxide (SiO₂ or the like).

In active areas encircled with this isolation section 2, there is formed an integrated circuit element, such as a field effect transistor (hereafter, referred to as MIS FET (Metal Insulator Semiconductor FET)) Q typified by, for example, MOS FET (Metal Oxide Semiconductor Field Effect Transistor).

Each MIS FET Q includes: a pair of semiconductor regions for source and drain formed in the principal surface of the substrate 1; a gate insulating film formed over the principal surface of the substrate 1 between the pair of semiconductor regions; and a gate electrode formed over the gate insulating film. In the description of the first embodiment, the case illustrated in FIG. 2 is taken as an example. That is, multiple MIS FETs Q are disposed not only in the internal area of the semiconductor chip as a matter of course but also in pad placement areas (directly under pads PD).

Over the principal surface of this substrate 1, there are formed, for example, seven wiring layers. The wiring layers include the lowermost wiring layer ML, a first wiring layer Ml to a fifth wiring layer M5 (intermediate wiring layers) placed thereover, and the uppermost wiring layer MH placed further thereover. The number of the wiring layers is not limited to this and can be variously changed.

The lowermost wiring layer ML includes insulating films 3A, 4A, 3B, a lowermost wiring (conductor pattern) 5A, and a plug (junction) 6A.

The insulating films 3A, 4A, 3B are deposited in this order over the principal surface of the substrate 1. The insulating films 3A, 3B are formed of, for example, silicon oxide and have a function of insulating one conductor pattern (wiring, plug, and dummy wiring) from another. The insulating film 4A thinner than the insulating films 3A, 3B is formed of, for example, silicon carbonitride (SiCN) and has a function of insulating one conductor pattern (wiring, plug, and dummy wiring) from another and the functions of an etching stopper.

The lowermost wiring 5A is formed by filling wiring trenches formed in the insulating films 3B, 4A with a conductor film (buried wiring or damocene wiring). The conductor film forming the lowermost wiring 5A includes a main wiring member and a barrier metal film. This main wiring member is formed of such metal as copper (Cu). For example, aluminum, silver (Ag), or tin (Sn) may be added to this main wiring member to cope with migration. The barrier metal film is provided between the main wiring member and the insulating film on the periphery (side face and bottom face) thereof so that the barrier metal film is in contact with the member and the film. This barrier metal film has a function of suppressing or preventing the diffusion of copper of the main wiring member and a function of enhancing the adhesion between the wiring and the insulating film. The barrier metal film is so formed that it is thinner than the main wiring member and is formed of, for example, a laminated film of a tantalum nitride (TaN) film and a tantalum (Ta) film placed thereover. The tantalum nitride film is in contact with the insulating film and the tantalum film is in contact with the main wiring member.

Each plug 6A is formed by filling a contact hole formed in the insulating film 3A with a conductor film. The conductor film forming the plugs 6A includes a main wiring member and a barrier metal film. This main wiring member is formed of high-melting point metal, such as tungsten (W). The barrier metal is provided between the main wiring member and the insulating film on the periphery (side face and bottom face) thereof so that the barrier metal in contact with the member and the film. This barrier metal film has a function of triggering the growth of tungsten and a function of enhancing the adhesion between the wiring and the insulating film. The barrier metal film is so formed that it is thinner than the main wiring member and is formed of, for example, a titanium nitride (TiN) film.

The lowermost wiring 5A is electrically coupled to the semiconductor regions for the sources and drains of the MIS FETs Q through the plugs 6A.

The first wiring layer M1 includes insulating films 4B, 3C, 3D and a first wiring (conductor pattern) 5B.

The insulating films 4B, 3C, 3D of the first wiring layer M1 are deposited in this order over the insulating film 3B. The insulating film 3C is formed of a single-layer film and the insulating film 3D is formed of a laminated film of an insulating film 3D1 and an insulating film 3D2 placed thereover, as illustrated in FIG. 3. The insulating films 3C, 3D have a function of insulating one conductor pattern (wiring, plug, and dummy wiring) from another.

The insulating films 3C, 3D1 are formed of a low-dielectric constant film (Low-k film). In the description of this embodiment, the low-dielectric constant film refers to an insulating film whose relative dielectric constant is lower than the relative dielectric constant (=3.8 to 4.3) of silicon oxide (SiO₂) and especially, an insulating film whose relative dielectric constant is lower than 3.3. Concrete examples of the material of the insulating films 3C, 3D1 include silicon oxide containing carbon (SiOC (relative dielectric constant=2.0 to 3.2)), SILK (registered trademark) (relative dielectric constant=2.7), FLARE (registered trademark) (relative dielectric constant=2.8), silicon oxide containing methyl group (MSQ: methylsilsesquioxane), and porous MSQ.

The insulating film 3D2 is formed of, for example, silicon oxide (SiOₓ typified by SiO₂) or SiOC (silicon oxide containing carbon). In case of SiOC, a SiOC film having a dielectric constant equal to or higher than the dielectric constant of the insulating film 3D1 is used. This insulating film 3D2 has the following functions: a function of protecting the low-dielectric constant films (insulating films 3D1, 3C) if these films are fragile when a buried wiring (damocene wiring) is formed; and a function of enhancing the mechanical strength of the wiring layers including the low-dielectric constant films (insulating films 3D1, 3C).

The insulating film 4B thinner than the insulating films 3C, 3D has a function of insulating one conductor pattern (wiring, plug, and dummy wiring) from another and the functions of an etching stopper. The insulating film 4B is formed of, for example, SiCN (silicon carbonitride).

The first wiring 5B is formed by filling a wiring trench formed in the insulating film 3D and a through hole formed in the insulating films 3C, 4B at the bottom of the wiring trench with a conductor film (buried wiring or dual damocene wiring). That is, in the first wiring 5B, a wiring portion (conductor pattern) formed in a wiring trench and a plug portion (junction) formed in a through hole are integrally formed. The conductor film forming the first wiring 5B includes a main wiring member MM1 and a barrier metal film BM1 as illustrated in FIG. 3.

This main wiring member MM1 is formed of such metal as copper (Cu). For example, aluminum, silver (Ag), or tin (Sn) maybe added to this main wiring member MM1 to cope with migration.

The barrier metal film BM1 is formed between the main wiring member MM1 and the insulating film on the periphery (side face and bottom face) thereof so that the barrier metal film is contact with the member and the film. This barrier metal film BM1 has a function of suppressing or preventing the diffusion of copper of the main wiring member MM1 and a function of enhancing the adhesion between the wiring and the insulating film. The barrier metal film BM1 is so formed that it is thinner than the main wiring member MM1 and is formed of, for example, a laminated film of a tantalum nitride (TaN) film and a tantalum (Ta) film placed thereover. The tantalum nitride film is in contact with the insulating film and the tantalum film is in contact with the main wiring member MM1.

The first wiring 5B is electrically coupled to the lowermost wiring 5A through the plug portions thereof.

The width (short-direction length), thickness, pitch, and adjoining distance of the first wiring 5B are larger than the width (short-direction length), thickness, pitch, and adjoining distance of the lowermost wiring 5A.

The second wiring layer M2 includes insulating films 4D, 3C, 3D and a second wiring (conductor pattern) 5C.

The insulating films 4D, 3C, 3D of the second wiring layer M2 are deposited in this order over the insulating film 3D of the first wiring layer M1. The configuration and functions of the insulating films 3C, 3D of the second wiring layer M2 are the same as the configuration and functions of the insulating films 3C, 3D of the first wiring layer M1. (Refer to FIG. 3.)

The insulating film 4D thinner than the insulating films 3C, 3D of the second wiring layer M2 has a function of insulating one conductor pattern (wiring, plug, and dummy wiring) from another and the functions of an etching stopper. The insulating film 4D of the second wiring layer M2 is formed of, for example, SiCN (silicon carbonitride).

The second wiring 5C is formed by filling a wiring trench formed in the insulating film 3D and a through hole formed in the insulating films 3C, 4D at the bottom of the wiring trench with a conductor film (buried wiring or dual damocene wiring). That is, in the second wiring 5C, a wiring portion (conductor pattern) formed in a wiring trench and a plug portion (junction) formed in a through hole are integrally formed. The material composition of the second wiring 5C is the same as that of the first wiring 5B. (Refer to FIG. 3.) The second wiring 5C is electrically coupled to the first wiring 5B through the plug portions thereof.

The configuration of the third wiring layer M3 is the same as the configuration of the second wiring layer M2. The configuration of the third wiring 5D of the third wiring layer M3 is the same as that of the second wiring 5C. (Refer to FIG. 3.) The dimensions (width (short-direction size), thickness, pitch, and adjoining distance) of the first wiring layer M1 to the third wiring layer M3 (the first wiring 5B to the third wiring 5D) are identical with one another. The width and adjoining distance of the first wiring 5B, second wiring 5C, and third wiring 5D are, for example, 100 nm or so and the thickness thereof is, for example, 200 nm or so.

In the above description, a case where the insulating films 3C, 3D1, 3D2 of the first wiring layer M1 to the third wiring layer M3 are formed of different films has been taken as an example. In this case, for example, the insulating film 3C can be formed of the above MSQ (for example, the relative dielectric constant=2.5 or so); the insulating film 3D1 can be formed of the above SILK (registered trademark) (relative dielectric constant=2.7 or so); and the insulating film 3D2 can be formed of a SiOC film (for example, the relative dielectric constant=3.0 or so).

As another embodiment, the following measure may be taken in the insulating films 3C, 3D1, 3D2 of the first wiring layer M1 to the third wiring layer M3: the entire insulating films 3C, 3D1 may be formed of the same low-dielectric constant film (one low-dielectric constant film). In this case, for example, the insulating film 3D2 can be formed of a SiOC film (for example, the relative dielectric constant=3.0 or so); and the entire insulating films 3C, 3D1 can be formed of any other SiOC film whose dielectric constant (for example, the relative dielectric constant=2.5 or so) is lower than that of the insulating film 3D2.

As another embodiment, the following measure may be taken in the insulating films 3C, 3D1, 3D2 of the first wiring layer M1 to the third wiring layer M3: the entire insulating films 3C, 3D1, 3D2 may formed of the same low-dielectric constant film (one low-dielectric constant film). In this case, it is more desirable that a film relatively high in resistance to CMP should be used as the low-dielectric constant film. For example, the entire insulating films 3C, 3D1, 3D2 can be formed of a SiOC film (for example, the relative dielectric constant=3.0 or so).

The fourth wiring layer M4 includes insulating films 4D, 3C, 3D and a fourth wiring (conductor pattern) 5E.

The insulating films 4D, 3C, 3D of the fourth wiring layer M4 are deposited in this order over the insulating film 3D of the third wiring layer M3. Unlike the insulating films 3C, 3D of the first wiring layer M1 to the third wiring layer M3, the insulating films 3C, 3D of the fourth wiring layer M4 are formed of, for example, a single film of silicon oxide. That is, the insulating films 3C, 3D of the fourth wiring layer M4 do not have a low-dielectric constant film. (Refer to FIG. 4.) In each of the fourth wiring layer M4 and the fifth wiring layer M5, the entire insulating films 3C, 3D may be formed of the same film (one film).

The insulating film 4D thinner than the insulating films 3C, 3D of the fourth wiring layer M4 has a function of insulating one conductor pattern (wiring, plug, and dummy wiring) from another and the functions of an etching stopper. The insulating film 4D of the fourth wiring layer M4 is formed of, for example, SiCN (silicon carbonitride).

The configuration (except size) of the fourth wiring 5E of the fourth wiring layer M4 is the same as that of the third wiring 5D of the third wiring layer M3 (buried wiring or dual damocene wiring). The fourth wiring 5E is electrically coupled to the third wiring 5D through the plug portions thereof.

The dimensions (width (short-direction size), thickness, pitch, and adjoining distance) of the fourth wiring 5E are larger than the following: the dimensions (width (short-direction size), thickness, pitch, and adjoining distance) of the first wiring 5B, second wiring 5C, and third wiring 5D of the first wiring layer M1 to the third wiring layer M3. The width and adjoining distance of the fourth wiring 5E are, for example, 200 nm or so and the thickness thereof is, for example, 400 nm or so.

The configuration (except size) of the fifth wiring layer M5 is the same as the configuration of the fourth wiring layer M4. The configuration of the fifth wiring 5F of the fifth wiring layer M5 is the same as that of the fourth wiring 5E. (Refer to FIG. 4.) The dimensions (width (short-direction size), thickness, pitch, and adjoining distance) of the fifth wiring 5F of the fifth wiring layer M5 are larger than the following: the dimensions (width (short-direction size), thickness, pitch, and adjoining distance) of the fourth wiring 5E of the fourth wiring layer M4. The width and adjoining distance of the fifth wiring 5F are, for example, 400 nm or so and the thickness thereof is, for example, 800 nm.

In the above description, a case where the insulating films 3C, 3D of the fifth wiring layer M5 are formed of a single film of silicon oxide has been taken as an example. Instead, silicon oxide containing fluorine (FSG: Fluorinated Silicate Glass=SiOF) may be used for either or both of the insulating films 3C, 3D of the fifth wiring layer M5. The relative dielectric constant of this silicon oxide containing fluorine is larger than 3.3 and is, for example, 3.6 to 3.8 or so. In the fifth wiring layer M5, the entire insulating films 3C, 3D may be formed of the same film (one film). In this case, a silicon oxide film or a silicon oxide film containing fluorine can be used.

In the above description, a case where the insulating films 3C, 3D of the fourth wiring layer M4 are formed of a single film of silicon oxide has been taken as an example. Instead, the above silicon oxide containing fluorine may be used for either or both of the insulating films 3C, 3D of the fourth wiring layer M4. In the fourth wiring layer M4, the entire insulating films 3C, 3D may be formed of the same film (one film). The film configuration of the insulating films 3C, 3D of the fourth wiring layer M4 may be identical with the film configuration of the insulating films 3C, 3D of the first wiring layer M1 to the third wiring layer M3. (This film configuration is a film configuration using a low-dielectric constant film.)

The uppermost wiring layer MH includes insulating films 4D, 3E, 3F, an uppermost wiring (conductor pattern) 5G, a pad PD, and a plug (junction) 6C.

The insulating films 4D, 3E, 3F are deposited in this order above the insulating film 3D of the fifth wiring layer M5. The configuration and functions of the insulating film 4D of the uppermost wiring layer MH are the same as the configuration and functions of the insulating films 4D of the second wiring layer M2 to the fifth wiring layer M5. The insulating film 3E is formed of, for example, silicon oxide and has a function of insulating one conductor pattern (wiring, plug, and dummy wiring) from another.

The insulating film 3F is formed of, for example, a laminated body of a silicon oxide film, a silicon nitride film deposited thereover, and a polyimide resin film deposited further thereover. The insulating film 3F has a function of insulating one conductor pattern (wiring, plug, and dummy wiring) from another and the functions of a surface protective film. The surface of the uppermost wiring 5G and part of the surface of each pad PD are covered with the insulating film 3F. The longitudinal size and lateral size W1, L1 of each pad PD illustrated in FIG. 1 are, for example, 30 to 100 μm or so (that is, approximately, 30 μm≦W1≦100 μm, 30 μm≦L1≦100 μm).

In the insulating film 3F, there is formed an opening S in which part of the upper surface of a pad PD is exposed. The area of the upper surface of the pad PD exposed in the opening S is an area where an external member, such as a bonding wire (hereafter, simply referred to as wire), a bump, and a probe, can be brought into contact with the pad PD.

In the description of this embodiment, the following area in the upper surface area of a pad PD exposed in an opening S, as illustrated in FIG. 1, will be referred to as probe contact area (first area) PA: an area with which a probe (exploring needle) is brought into contact during an electrical characteristic test on a semiconductor chip. It is desirable that the planar size of this probe contact area PA should be smaller than the formation region of an opening S but should be larger than the size of a probe mark left on the upper surface of the pad PD. In the first embodiment, it is desirable that the planar size of the probe contact area PA should be equal to or larger than at least 10 μm×10 μm since the contact face (probe mark) of the tip of the probe is 10 μm or so in diameter. However, it is more desirable that the size (planar size) of the probe contact area PA should be equal to or larger than 20 μm×20 μm with misalignment between the probe and the pad PD taken into account.

The following area in the upper surface area of a pad PD exposed in an opening S will be referred to as wire embracing area (first area) PWA: an area embracing the above probe contact area PA and a wire bonding area WA where a wire is bonded. It is desirable that the planar size of the wire embracing area PWA should be smaller than the formation region of an opening S but should be larger than the probe contact area PA and the wire bonding area WA (the area of contact of a wire (or a bump)). In the first embodiment, it is desirable that the planar size of the wire embracing area PWA should be equal to or larger than at least 30 μm×30 μm since the contact face of the wire (or bump) is 30 μm or so in diameter. However, it is more desirable that the size (planar size) of the wire embracing area PWA should be equal to or larger than 40 μm×40 μm with misalignment between the wire (or bump) and the pad PD taken into account.

The formation region of an opening S in the upper surface area of a pad PD (the entire area of the upper surface of the pad PD exposed in the opening S) will be referred to as opening formation region (first area) SA. In this case, it is unnecessary to take misalignment with the probe or the wire (or bump) into account.

The uppermost wiring 5G and each pad PD are formed by patterning one and the same conductor film by photolithography and dry etching. The conductor film forming the uppermost wiring 5G and each pad PD includes a main wiring member MM2 and relatively thin barrier metal films BM2, BM3 formed above and below the main wiring member MM2 as illustrated in FIG. 4. However, in the portion of the upper surface of a pad PD exposed in an opening S, the barrier metal film BM3 is removed and the main wiring member MM2 is exposed.

This main wiring member MM2 is formed of, for example, aluminum. For example, silicon or copper may be added to the main wiring member MM2 to cope with migration.

The barrier metal film BM2 on the side of the under surface of the main wiring member MM2 has the following functions: a function of suppressing reaction between the material (aluminum) of the main wiring member and a lower wiring; and a function of enhancing the adhesion between the wiring and the insulating film. The barrier metal film BM2 is formed of, for example, a laminated film of a titanium film, a titanium nitride film placed thereover, and a titanium film placed further thereover.

The barrier metal film BM3 on the side of the upper surface of the main wiring member MM2 has the following functions: a function of enhancing the adhesion between the wiring and the insulating film; and the functions of a reflection preventing film that prevents reflection during exposure in photolithography processing. The barrier metal film BM3 is formed of, for example, a titanium nitride film.

Each plug 6C is formed by filling a through hole formed in the insulating films 3E, 4D with a conductor film. The configuration (except size) of the plug 6C is the same as that of the above plug 6A. The plugs 6C are electrically coupled to the uppermost wiring 5G, fifth wiring 5F, and pad PD. That is, the uppermost wiring 5G and the pads PD are electrically coupled to the fifth wiring 5F positioned in the lower layer through the plugs 6C.

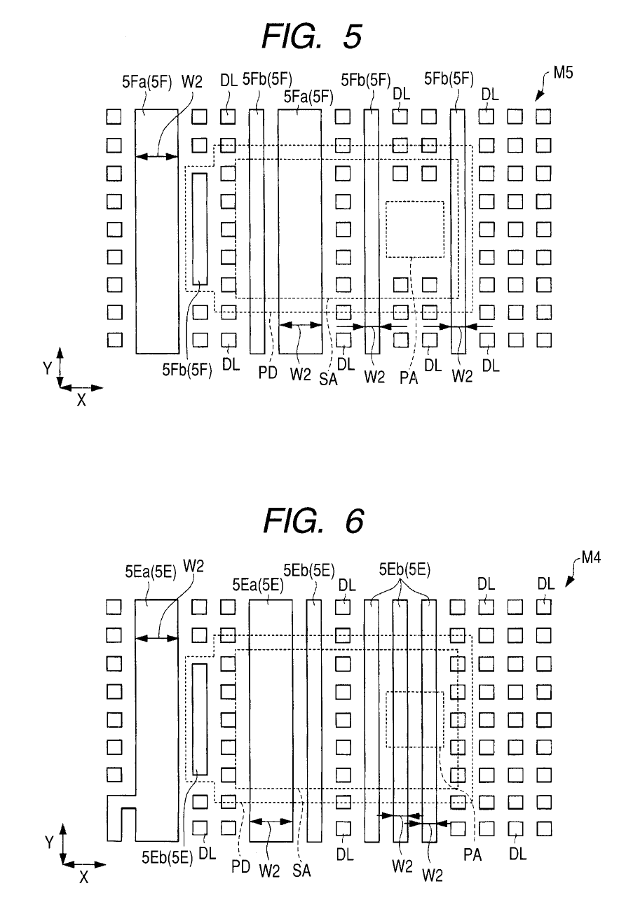

FIG. 5 and FIG. 6 are plan views of a substantial part of a semiconductor chip of a semiconductor device in the first embodiment. FIG. 5 illustrates an example of the layout of conductor patterns (fifth wiring 5F and dummy wiring DL) in the fifth wiring layer M5 in proximity to a pad PD formation region. FIG. 6 illustrates an example of the layout of conductor patterns (fourth wiring 5E and dummy wiring DL) in the fourth wiring layer M4 in proximity to a pad PD formation region. In FIG. 5 and FIG. 6, the positions of a pad PD, an opening formation region SA, and a probe contact area PA are indicated by broken lines.

The dummy wirings DL illustrated in FIG. 5 and FIG. 6 are provided to enhance the planarity of each wiring layer. In general, the dummy wirings are formed at the same step as a wiring in the same layer is formed but they are formed of a conductor pattern irrelevant to the configuration of the integrated circuit itself. The dummy wirings DL are disposed all around areas where no wiring is disposed. Therefore, the dummy wirings DL in the fifth wiring 5F illustrated in FIG. 5 are formed at the same step as the fifth wiring layer M5 is formed and are disposed all around the areas where the fifth wiring 5F is not disposed. The dummy wirings DL in the fourth wiring layer M4 illustrated in FIG. 6 are formed at the same step as the fourth wiring 5E is formed and are disposed all around the areas where the fourth wiring 5E is not disposed. In the sectional view in FIG. 2, dummy wirings are not marked with code DL for the purpose of making the drawing clearly understandable. In the drawing, however, some wirings are formed as dummy wirings DL as required.

In FIG. 5, the following measure is taken: of the fifth wirings 5F, wirings whose width (wiring width) W2 is larger than 2 μm (that is, W2>2 μm) are marked with code 5Fa and designated as wiring 5Fa; and wirings whose width (wiring width) W2 is equal to or smaller than 2 μm (that is, W2≦2 μm) are marked with code 5Fb and designated as wiring 5Fb. In FIG. 6, the following measure is taken: of the fourth wirings 5E, wirings whose width (wiring width) W2 is larger than 2 μm (that is, W2>2 μm) are marked with code 5Ea and designated as wiring 5Ea; and wirings whose width (wiring width) W2 is equal to or smaller than 2 μm (that is, W2≦2 μm) are marked with code 5Eb and designated as wiring 5Eb. This is the same with the following drawings.

In the first embodiment, as seen from FIG. 2, FIG. 5, and FIG. 6, the following measure is taken in the fifth wiring layer M5 directly under the uppermost wiring layer MH: a conductor pattern (fifth wiring 5F, dummy wiring DL, and plug 6C) is not formed directly under the above probe contact area PA (probe mark) of each pad PD. The following measure is also taken in the fifth wiring layer M5: a conductor pattern (fifth wiring 5F, dummy wiring DL, and plug 6C) is formed in the areas other than directly under the probe contact area PA of each pad PD. That is, in the fifth wiring layer M5, conductor patterns comprised of the fifth wiring 5F and dummy wirings DL are disposed in, preferably all around, the areas other than directly under the probe contact areas PA. In the description of the first embodiment, the following case is taken as an example: a case where even directly under the above probe contact area PA of each pad PD, a conductor pattern (wiring, dummy wiring, plug) is formed in the lowermost wiring layer ML to the fourth wiring layer M4.

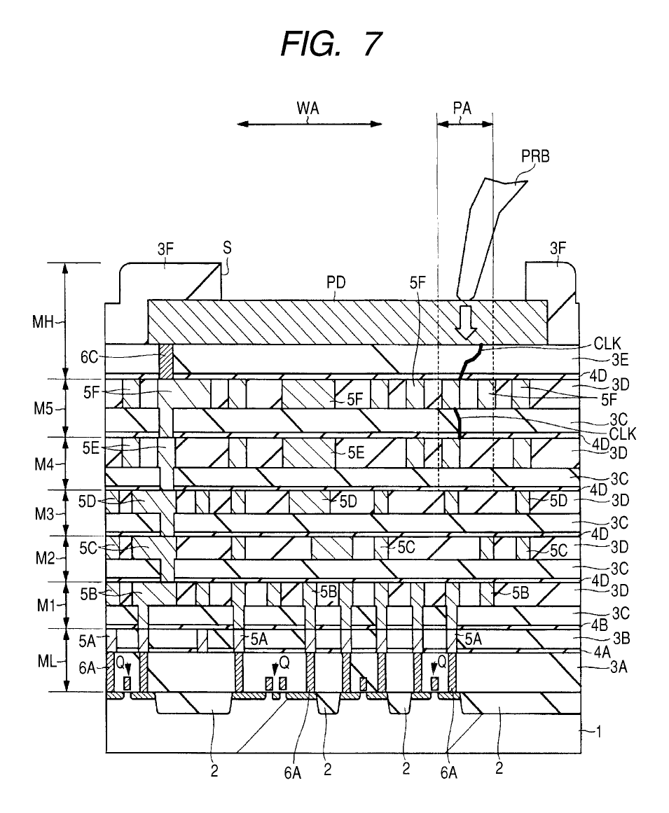

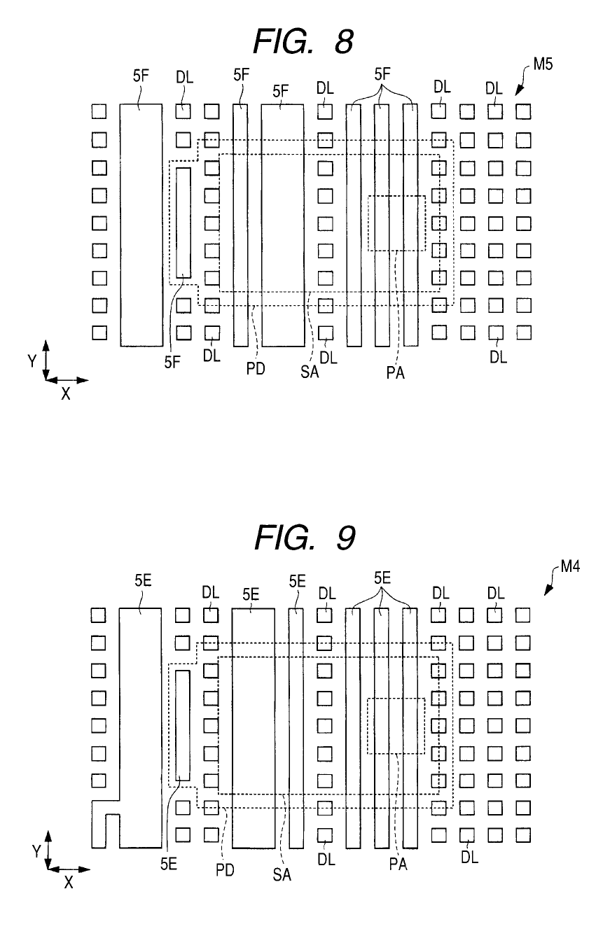

The reason why this configuration is adopted will be described with reference to FIG. 7 to FIG. 9 and the like. FIG. 7 is a sectional view of a substantial part of a semiconductor chip (semiconductor chip as a comparative example) reviewed by the present inventors and corresponds to the sectional view on the right of FIG. 2 referred to in relation to this embodiment. FIG. 8 and FIG. 9 are plan views of a substantial part of the semiconductor chip (semiconductor chip as a comparative example) in FIG. 7, reviewed by the present inventors and respectively correspond to FIG. 5 and FIG. 6 referred to in relation to this embodiment. Therefore, FIG. 8 illustrates an example of the layout of conductor patterns (fifth wiring 5F and dummy wiring DL) in the fifth wiring layer M5 of the semiconductor chip (semiconductor chip as a comparative example) in FIG. 7 in proximity to a pad PD formation region; and FIG. 9 illustrates an example of the layout of conductor patterns (fourth wiring 5E and dummy wiring DL) in the fourth wiring layer M4 in proximity to a pad PD formation region.

In the semiconductor chip as a comparative example illustrated in FIG. 7 to FIG. 9, the following measure is taken in the fifth wiring layer M5 directly under the uppermost wiring layer MH: the fifth wiring 5F is formed directly under the probe contact area PA of each pad PD. As mentioned above, this fifth wiring 5F is formed of a buried wiring in which copper is used for the main wiring member MM2.

In this case, the following takes place when the tip of the probe PRB of testing equipment is pressed against the probe contact area PA of a pad PD during an electrical characteristic test on a semiconductor chip: the fifth wiring 5F directly under the probe contact area PA of the pad PD is plastically deformed by load applied by the probe PRB. As a result, stress is applied to the insulating film 3E directly under the pad PD and the insulating film 3C directly under the fifth wiring 5F and a crack CLK is produced in the insulating film 3E or 3C. When copper or aluminum is used as the wiring material of a wiring layer directly under a pad PD, the following takes place: the respective moduli of elasticity (70 GPa, 130 GPa) of copper and aluminum are less than twice the modulus of elasticity (70 GPa) of the silicon oxide film and copper and aluminum are more prone to be plastically deformed than the silicon oxide film; therefore, the above problem of cracks CLK becomes notable. When a low-dielectric constant film is used as the insulation material for wiring layers, the above problem of cracks CLK becomes notable since the low-dielectric constant film is low in mechanical strength.

In the technique disclosed in Patent Document 1, a stress buffer layer is formed directly under a bonding pad using an aluminum wiring layer. Also in this case, however, the present inventors found that the following problem arises: the stress buffer layer is plastically deformed by impact produced when a probe is pressed against a pad; and this causes cracking in an insulating film in a wiring layer and this crack propagates to lower layers.

In the technique disclosed in Patent Document 2, the following measure is taken: a reinforcing layer formed of high-melting point metal is provided under a contact pad layer; and a first metal layer formed of copper or aluminum, substantially identical in size with pads, is provided further thereunder. In this technique disclosed in Patent Document 2, pieces of high-melting point metal arranged at certain intervals or a structure of high-melting point metal in a lattice pattern is used as a reinforcing layer. Therefore, stress is concentrated on an interface (edge) between patterns of tungsten structures by load produced when a probe is pressed against a contact pad layer. As a result, a crack is produced in proximity to the interface (edge) of the patterns and this crack propagates to lower layers. In addition, the first metal layer directly under the reinforcing layer is plastically deformed and thus a cracking becomes more notable.

In the technique disclosed in Patent Document 3, a reinforcing layer comprised of tungsten or tungsten alloy whose size is substantially equal to that of each pad and whose thickness is 1 μm is buried in an interlayer insulating film under pads. In this case, however, the reinforcing layer itself is thick and there is a possibility that the reinforcing layer is stripped by its own stress.

In the technique disclosed in Patent Document 4, the following configuration is adopted: a high-melting point metal layer is provided in contact with the under surface of a second pad and a first pad is provided further thereunder in contact with the high-melting point metal layer. Also in this case, the first pad is formed of aluminum and the first pad and the second pad are substantially identical in size with each other. Therefore, plastic deformation is caused in the first pad under the high-melting point metal layer by load produced when a probe is pressed against the second pad and a crack is produced in an insulating film.

In the technique disclosed in Patent Document 5, the following configuration is adopted: tungsten structures arranged at certain intervals are buried in an insulating layer under pads in contact with the under surfaces of the pads. In this case, however, stress is concentrated on an interface (edge) between patterns of tungsten structures and a crack is produced in proximity to the interface (edge) between the patterns and this crack propagates to lower layers.

In the technique disclosed in Patent Document 6, the following configuration is adopted: a laminated body having a U cross-sectional shape formed of tungsten is formed between pads and the wiring in the wiring layer directly thereunder in contact with the pads and the wiring. Also in this case, however, the wiring under pads is formed of aluminum alloy and is substantially identical in size with each pad. Therefore, plastic deformation is caused in the wiring under the laminated body by load produced when a probe is pressed against a pad and a crack is produced in an insulating film.

Further, the following problem arises after a wire (or bump) is bonded to a pad PD and the semiconductor chip is packaged: force is applied to a wire bond or a bump due to a difference in coefficient of thermal expansion between the semiconductor chip and the package material (resin or substrate) and a pad portion is stripped starting at the crack portion. As a result, breaking of wire occurs.

In the first embodiment, meanwhile, the measure illustrated in FIG. 2 and FIG. 5 is taken in the fifth wiring layer M5 directly under the uppermost wiring layer MH. That is, a conductor pattern (fifth wiring 5F, dummy wiring DL, and plug 6C) is not dared to be provided directly under the probe contact area PA (probe mark) of each pad PD.

That is, in the fifth wiring layer M5, a conductor pattern (wide pattern substantially identical in size (30 to 100 μm) with each pad) does not exist directly under the probe contact area PA of each pad PD. Only an insulating film of silicon oxide or the like is formed there. Therefore, plastic deformation is less prone to be caused even though a probe PRB is pressed against a pad PD and a crack is less prone to be produced in the insulating film. In the fifth wiring layer M5, an interface (edge) between conductor patterns does not exist directly under the probe contact area PA of each pad PD. Therefore, a crack arising from stress concentration on an interface (edge) between conductor patterns is not produced, either, in the insulating film.

Therefore, it is possible to suppress or prevent a trouble that a crack CLK is produced in an insulating film under a pad PD by external force applied to the pad PD during probe inspection. For this reason, it is possible to enhance the yield and reliability of the semiconductor device.

In the fifth wiring layer M5, an area where the disposition of a conductor pattern is prohibited can be limited to a probe contact area PA. That is, even under a pad PD, the fifth wiring 5F and dummy wirings DL can be disposed in the area other than the probe contact areas PA. In the fifth wiring layer M5, a wide conductor pattern (wide pattern substantially identical in size with each pad; impact buffer pattern or the like) formed by a damocene method is not provided directly under the probe contact area PA of each pad PD. In the fifth wiring layer M5, therefore, it is possible to dispose the fifth wiring 5F even in proximity to the area where the disposition of a conductor pattern is prohibited directly under the probe contact area PA of each pad PD. For the foregoing reasons, it is possible to enhance the degree of freedom in disposing the fifth wiring 5F in the fifth wiring layer M5. Therefore, designing the wiring of a semiconductor chip can be facilitated. Since the alternative disposition of wiring can be reduced, the chip size can be reduced.

Since the above crack CLK can be suppressed or prevented, a problem of a wire (or bump) being stripped due to the crack CLK can also be suppressed or prevented. For this reason, it is possible to enhance the yield and reliability of the semiconductor device.

In electrical characteristic tests on semiconductor devices, it is unnecessary to reduce the probe pressure of a probe for the suppression or prevention of the above crack CLK. Therefore, it is possible to reduce the contact resistance between the probe and a pad and to enhance the accuracy of measurement of the electrical characteristics of each semiconductor device. For this reason, the reliability of the semiconductor device can be enhanced.

In the first embodiment, it is desirable to take the following measure in the fourth wiring layer M4 directly under the fifth wiring layer M5 directly under the uppermost wiring layer MH: a conductor pattern (wiring 5Ea, dummy wiring DL, and plug) whose width is larger than 2 μm is not formed directly under the probe contact area PA (probe mark) of each pad PD. In addition, it is desirable to take the following measure in the fourth wiring layer M4: a conductor pattern (wiring 5Eb, dummy wiring DL, and plug) whose width is equal to or smaller than 2 μm is disposed (formed) directly under the probe contact area PA of each pad PD. In the example illustrated in FIG. 6, the following measure is taken in the fourth wiring layer M4: wirings 5Eb having a width (wiring width) equal to or smaller than 2 μm are disposed directly under the probe contact area PA of a pad PD; and wirings 5Ea having a width (wiring width) larger than 2 μm are not disposed directly under the probe contact area PA of the pad PD but are disposed in areas other than directly under the probe contact area PA.

The fourth wiring 5E is farther from a pad PD than the fifth wiring 5F is and is less prone to be plastically deformed than the fifth wiring 5F is. If the probe pressure of a probe is nevertheless high, there is a possibility that the fourth wiring 5E is plastically deformed and a crack is produced in the insulating film. To cope with this, the above-mentioned measure is taken in the fourth wiring layer M4: the width of a conductor pattern (fourth wiring 5E) disposed directly under the probe contact area PA of each pad PD is limited to 2 μm or less. As a result, the plastic deformation is further suppressed and it is possible to bring a probe into contact with each pad PD with higher probe pressure and further stabilize testing (probe testing). This is the same with the fourth and 16th embodiments described below.

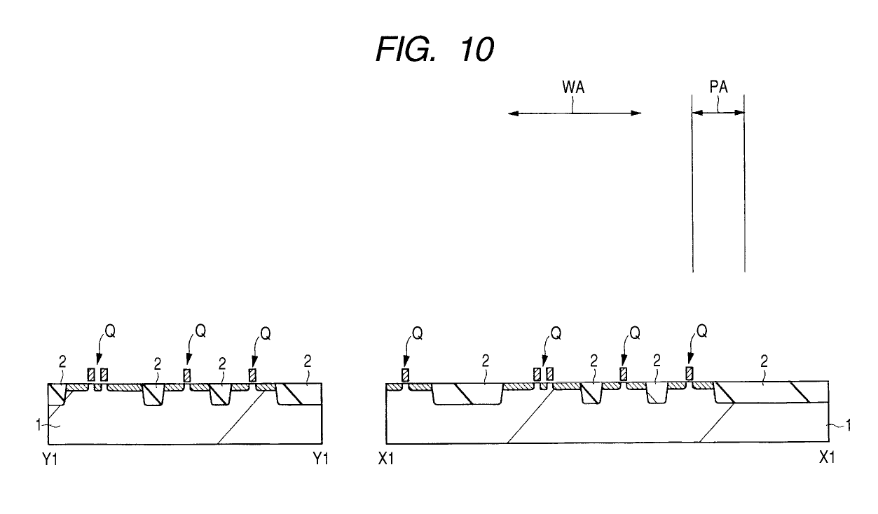

Description will be given to a method of manufacturing the semiconductor device in the first embodiment with reference to FIG. 10 to FIG. 15. The drawings from FIG. 10 to FIG. 15 are sectional views of the internal area (left) and a pad placement area (right) of the substrate 1 of the semiconductor device described with reference to FIG. 1 to FIG. 4 in a manufacturing process.

First, a substrate 1 having a principal surface (first principal surface) and a back surface (second principal surface) positioned opposite to each other along the thickness direction as illustrated in FIG. 10 is prepared. (At this stage, the substrate is a semiconductor thin plate in a planar circular shape called semiconductor wafer.)

Subsequently, a trench-like isolation section 2 is formed in the principal surface of the substrate 1 and then multiple elements (for example, MIS FETs Q) are formed in active areas encircled with the isolation section 2.

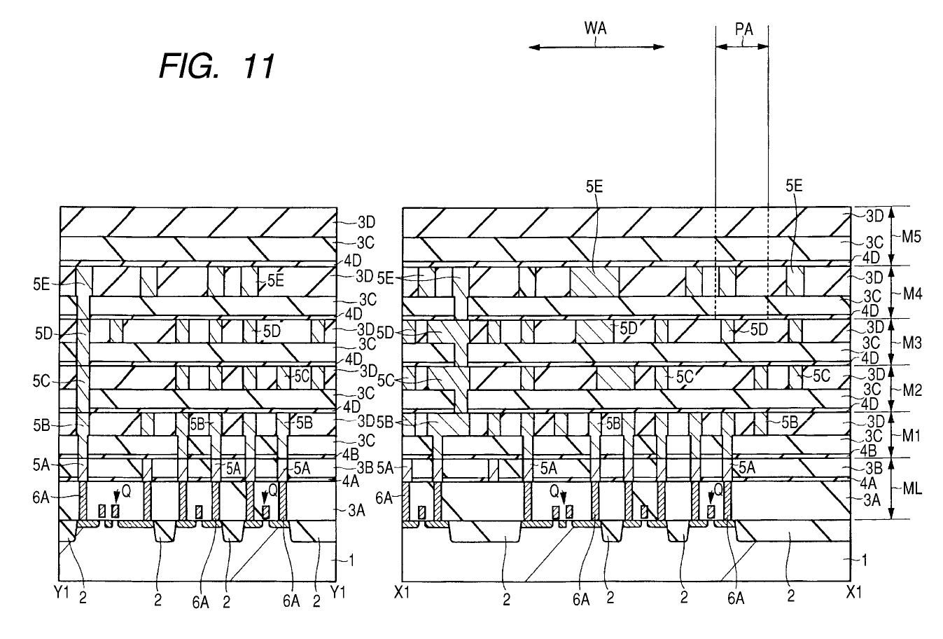

Thereafter, multiple wiring layers are formed over the principal surface of the substrate 1. Description will be given to the method of forming these wiring layers with reference to FIG. 11 to FIG. 15. FIG. 11 illustrates a state in which the wiring layers up to the fourth wiring layer M4 have been formed. The methods of forming the first wiring layer M1 to the fifth wiring layer M5 are the same. Therefore, description will be given to the methods of forming the first wiring layer M1 to the fifth wiring layer M5 with the method of forming the fifth wiring layer M5 taken as an example.

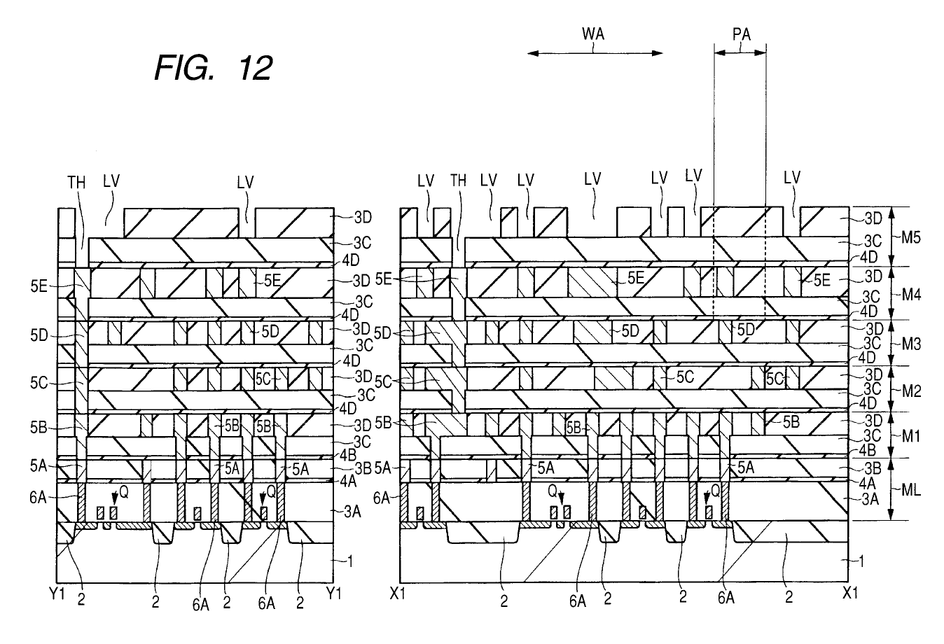

As illustrated in FIG. 11, the insulating films 4D, 3C, 3D of the fifth wiring layer M5 are deposited in this order over the insulating film 3D of the fourth wiring layer M4 by CVD (Chemical Vapor Deposition). (When a low-dielectric constant film is involved, an application method or the like may be used.) Subsequently, as illustrated in FIG. 12, wiring trenches LV are formed in the wiring formation regions in the insulating film 3D of the fifth wiring layer M5. Through holes TH extended from the bottom of wiring trenches LV to the upper surface of the fourth wiring 5E are formed in the insulating films 3C, 4D of the fifth wiring layer M5 by photolithography and dry etching. Photolithography refers to a series of processing involving the application, exposure, and development of a photoresist film.

At this time, the etch selectivity of the insulating films 3C, 3D to the insulating film 4D is increased. As a result, when the insulating films 3D, 3C are etched, the insulating film 4D is caused to function as an etching stopper; and when the insulating film 4D is etched, the insulating films 3D, 3C are prevented from being etched.

In the first embodiment, the following measure is taken in the fifth wiring layer M5: a wiring trench LV or a through hole TH is not formed under each probe contact area PA.

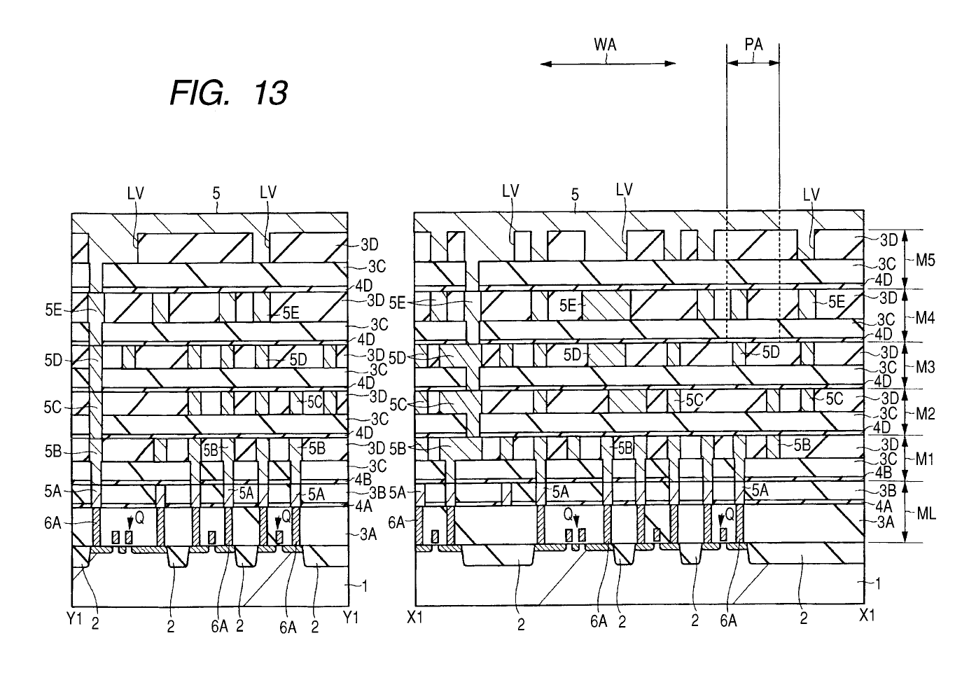

Thereafter, as illustrated in FIG. 13, a conductor film 5 is deposited over the principal surface of the substrate 1 so that the wiring trenches LV and the through holes TH are filled therewith. The conductor film 5 is obtained by depositing the barrier metal film BM1 and the main wiring member MM1 in this order from below. The barrier metal film BM1 is deposited by sputtering or the like. The main wiring member MM1 is deposited by sputtering and plating or the like. Specifically, the main wiring member MM1 is formed by depositing a thin seed layer formed of, for example, copper by sputtering or the like and then depositing a conductor film formed of, for example, copper over the seed layer by plating or the like.

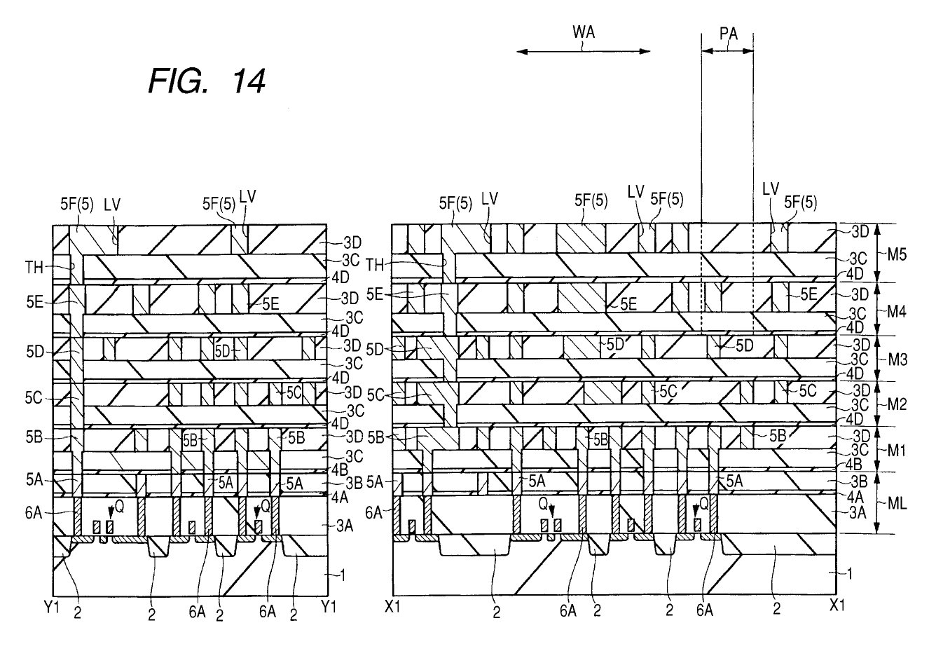

Thereafter, the portion of the conductor film 5 external to the wiring trenches LV and the through holes TH is removed by chemical mechanical polishing (CMP). As a result, the fifth wiring 5F formed of the conductor film 5 is formed in the wiring trenches LV and the through holes TH as illustrated in FIG. 14.

In the first embodiment, the following measure is taken in the fifth wiring layer M5 directly under the uppermost wiring layer MH: the fifth wiring 5F or the plug 6C is not formed directly under the probe contact area PA of each pad PD.

The lowermost wiring 5A is formed by a single damocene technique. However, the basic formation process is the same as the formation method for the first wiring 5B to the fifth wiring 5F.

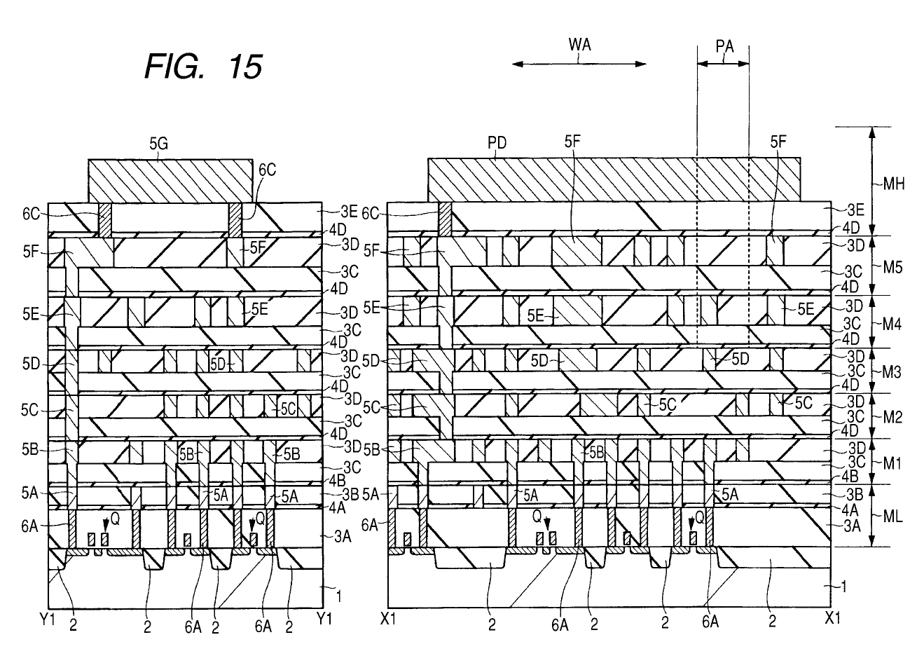

Subsequently, as illustrated in FIG. 15, the insulating films 4D, 3E are deposited in this order over the principal surface of the substrate 1 by CVD or the like. The insulating films 4D, 3E are so deposited that the upper surfaces of the insulating film 3D and fifth wiring 5F of the fifth wiring layer M5 are covered therewith. Thereafter, through holes TH are formed in the insulating films 3E, 4D and the plugs 6C are formed therein similarly with the fifth wiring 5F.

Thereafter, the barrier metal film BM2, main wiring member MM2, and barrier metal film BM3 are deposited in this order over the principal surface of the substrate 1 by sputtering or the like. They are so deposited that the upper surfaces of the insulating film 3E and plugs 6C of the uppermost wiring layer MH are covered therewith. Thereafter, this laminated conductor film is patterned by photolithography and etching, and the uppermost wiring (first conductor pattern) 5G and pads (first conductor patterns, external terminals) PD are thereby formed at the same step.

Subsequently, a silicon oxide film and a silicon nitride film are deposited in this order over the principal surface of the substrate 1 by CVD or the like so that the uppermost wiring 5G and the pads PD are covered therewith. Then a polyimide resin film is deposited further thereover by an application method or the like to form the insulating film 3F. Thereafter, openings S are formed in the insulating film 3F so that part of each pad PD is exposed. At this time, the portions of the uppermost barrier metal film BM3 of the pads PD exposed in the openings S are also removed.

Subsequently, a probe PRB is brought into contact with the pads PD of each of the multiple semiconductor chips on the principal surface of the substrate 1 to inspect the semiconductor chips on the substrate 1 for electrical characteristics. In the first embodiment, as mentioned above, the following measure is taken in the fifth wiring layer M5 directly under the uppermost wiring layer MH: a conductor pattern (fifth wiring 5F, dummy wiring DL, and plug 6C) is not dared to be provided directly under the probe contact area PA of each pad PD. In the above inspection, therefore, it is possible to suppress or prevent a trouble that a crack is produced in an insulating film directly under a pad PD due to load from the probe PRB. As a result, it is possible to enhance the yield and reliability of the semiconductor device.

Thereafter, the substrate 1 is diced to cut individual semiconductor chips out of the substrate 1. Then a wire is bonded to the wire bonding area WA of each pad PD of each semiconductor chip. (In case bumps are joined with pads PD, they are joined before semiconductor chips are cut out of the semiconductor wafer.) Thereafter, a sealing step is carried out to finish the manufacture of the semiconductor device.

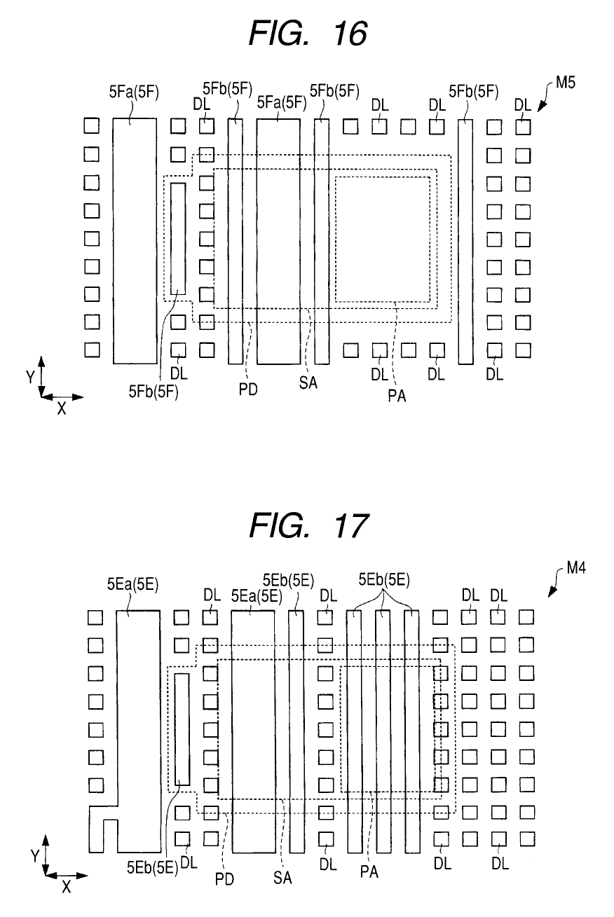

FIG. 16 and FIG. 17 are substantial part plan views illustrating a modification to the semiconductor chip of a semiconductor device in the first embodiment and respectively correspond to FIG. 5 and FIG. 6. That is, FIG. 16 illustrates an example of the layout of conductor patterns (fifth wiring 5F and dummy wirings DL) in the fifth wiring layer M5 in proximity to a pad PD formation region; and FIG. 17 illustrates an example of the layout of conductor patterns (fourth wiring 5E and dummy wirings DL) in the fourth wiring layer M4 in proximity to the pad PD formation region. In FIG. 16 and FIG. 17, the positions of a pad PD, an opening formation region SA, and a probe contact area PA are indicated by broken lines.

In the modification to the first embodiment illustrated in FIG. 16 and FIG. 17, the planar size (area) of the probe contact area PA is larger than in the case illustrated in FIG. 1 to FIG. 6. For example, approximately half of the opening formation region SA (the right half of the opening formation region SA in FIG. 16) is used as a probe contact area PA. The other configurations are the same as in the case illustrated in FIG. 1 to FIG. 6. Also in the modification illustrated in FIG. 16 and FIG. 17, therefore, the following measure is taken in the fifth wiring layer M5 directly under the uppermost wiring layer MH as in the case in FIG. 1 to FIG. 6: a conductor pattern (fifth wiring 5F, dummy wiring DL, and plug 6C) is not formed directly under the probe contact area PA (probe mark) of each pad PD.

In the modification to the first embodiment illustrated in FIG. 16 and FIG. 17, the planar size (area) of each probe contact area PA is made larger. As a result, a margin for the misalignment of a probe can be obtained.

### Second Embodiment

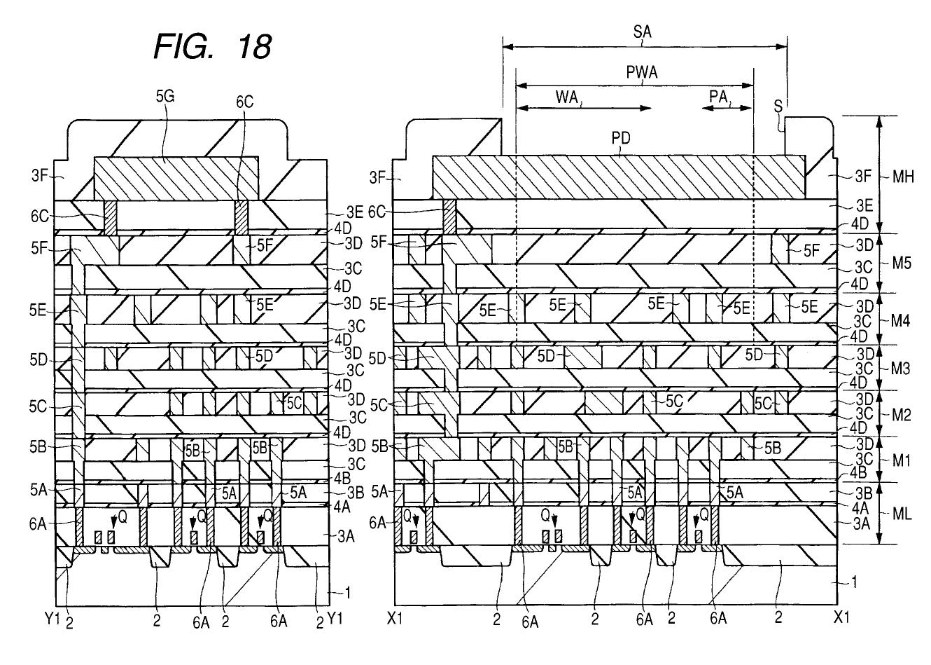

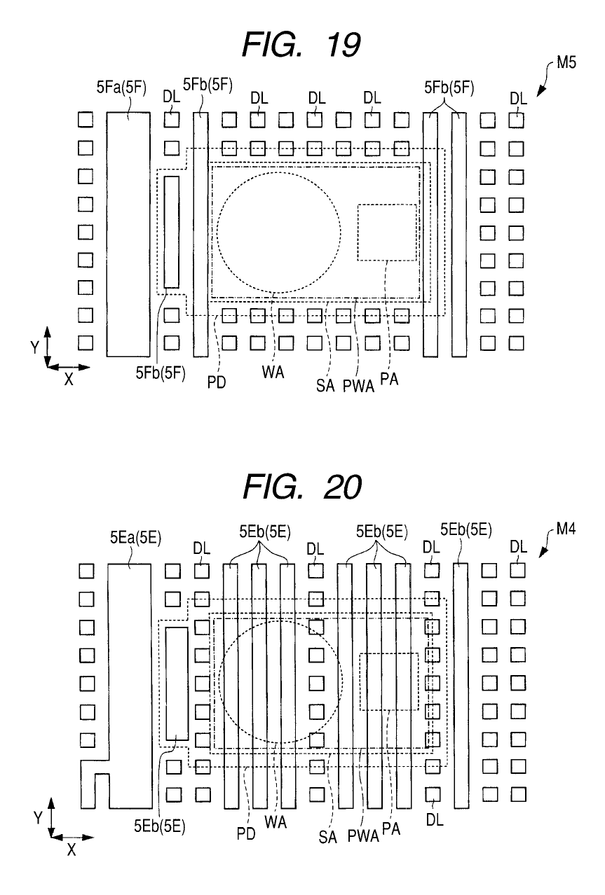

The left sketch in FIG. 18 is a sectional view of the internal area of the semiconductor chip of a semiconductor device in the second embodiment, corresponding to the area taken along line Y1-Y1 of FIG. 1. The right sketch is a sectional view of a pad placement area of the same semiconductor chip, corresponding to the area taken along line X1-X1 of FIG. 1. FIG. 19 and FIG. 20 are substantial part plan views illustrating the semiconductor chip of a semiconductor device in the second embodiment and respectively correspond to FIG. 5 and FIG. 6. That is, FIG. 19 illustrates an example of the layout of conductor patterns (fifth wiring 5F and dummy wirings DL) in the fifth wiring layer M5 in proximity to a pad PD formation region; and FIG. 20 illustrates an example of the layout of conductor patterns (fourth wiring 5E and dummy wirings DL) in the fourth wiring layer M4 in proximity to the pad PD formation region. In FIG. 19 and FIG. 20, the positions of a pad PD, an opening formation region SA, a probe contact area PA, and a wire bonding area WA are indicated by broken lines and the position of a wire embracing area PWA is indicated by alternate long and short dash lines.

In the second embodiment, as seen from FIG. 18 to FIG. 20, the following measure is taken in the fifth wiring layer M5 directly under the uppermost wiring layer MH: a conductor pattern (fifth wiring 5F, dummy wiring DL, and plug 6C) is not formed directly under the wire embracing area PWA (area including the probe contact area PA and the wire bonding area WA) of each pad PD.

In the fifth wiring layer M5, a conductor pattern (fifth wiring 5F, dummy wiring DL, and plug 6C) is formed in areas other than directly under the wire embracing area PWA of each pad PD. That is, in the fifth wiring layer M5, conductor patterns comprised of the fifth wiring 5F and dummy wirings DL are disposed in, preferably all around, the areas other than directly under the wire embracing areas PWA. In the second embodiment, conductor patterns (wiring, dummy wirings, plugs) are formed in the lowermost wiring layer ML to the fourth wiring layer M4 even directly under the wire embracing area PWA of each pad PD.

According to the second embodiment, not only the same effect as in the first embodiment but also the following effect can be obtained.

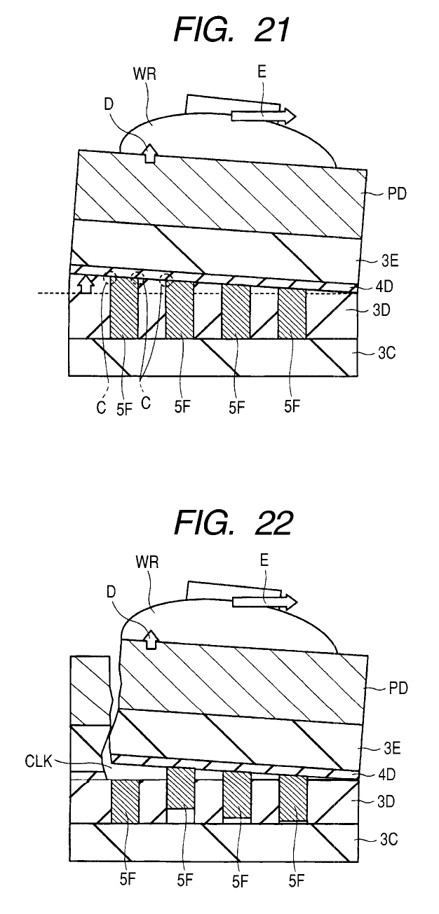

First, description will be given to a problem found by the present inventors with reference to FIG. 21 and FIG. 22. FIG. 21 and FIG. 22 are sectional views of a substantial part of a semiconductor chip reviewed by the present inventors.

In FIG. 21 and FIG. 22, the following measure is taken in the fifth wiring layer M5 directly under the uppermost wiring layer MH: multiple fifth wirings 5F are formed even directly under the wire embracing area PWA of the pad PD. As mentioned above, the fifth wiring 5F is formed of a buried wiring in which copper is used for the main wiring member MM2.

In this case, the following takes place when a wire WR (or bump) is bonded to the pad PD or when the state of bond of the wire WR (or bump) is inspected: a fifth wiring 5F directly under the wire bonding area WA of the pad PD is plastically deformed by force D, E applied at this time as illustrated in FIG. 21. As a result, stress is concentrated on an interface (edge) C of the fifth wiring 5F. Further, to relieve the stress, as illustrated in FIG. 22, a crack CLK is produced and a problem of the wire WR (or bump) being stripped arises.

In the second embodiment, meanwhile, the measure illustrated in FIG. 18 and FIG. 19 is taken in the fifth wiring layer M5 directly under the uppermost wiring layer MH: a conductor pattern (fifth wiring 5F, dummy wiring DL, and plug 6C) is not dared to be provided directly under the wire embracing area PWA of each pad PD.

That is, the following measure is taken in the fifth wiring layer M5: a conductor pattern (wide pattern substantially identical in size with each pad) does not exist directly under the wire embracing area PWA of each pad PD and only an insulating film of silicon oxide or the like is formed there. Therefore, plastic deformation is less prone to be caused and a crack is less prone to be produced in an insulating film. Further, in the fifth wiring layer M5, an interface (edge) of a conductor pattern does not exist directly under the wire embracing area PWA of each pad PD. Therefore, a crack in an insulating film due to stress concentration on an interface (edge) of a conductor pattern is not produced, either.

Therefore, it is possible to suppress or prevent the production of a crack CLK in an insulating film under a pad PD due to external force applied to the pad PD when a wire WR (or bump) is bonded or when a bond is inspected. As a result, it is also possible to suppress or prevent a problem of a wire WR (or bump) being stripped due to the above crack CLK. For this reason, it is possible to enhance the yield and reliability of the semiconductor device.

In the fifth wiring layer M5, an area where the disposition of a conductor pattern is prohibited under each pad PD is larger than in the first embodiment. However, a conductor pattern (wide pattern substantially identical in size with each pad, impact buffer pattern) formed by a damocene method is not provided in the fifth wiring layer M5 directly under the wire embracing area PWA of each pad PD. In the fifth wiring layer M5, therefore, it is possible to dispose the fifth wiring 5F even in proximity to the area where the disposition of a conductor pattern is prohibited directly under the wire embracing area PWA. For this reason, the following can be implemented as compared with cases where a wide fifth wiring 5F (wide pattern substantially identical in size with each pad) formed by a damocene method is formed under pads PD: the degree of freedom in disposing the fifth wiring 5F in the fifth wiring layer M5 can be enhanced. Therefore, the following can be implemented as compared with cases where a wide fifth wiring 5F (wide pattern substantially identical in size with each pad) formed by a damocene method is disposed under pads PD: designing the wiring of a semiconductor chip can be facilitated. Further, the following can be implemented as compared with cases where a wide fifth wiring 5F (wide pattern substantially identical in size with each pad) formed by a damocene method is disposed under pads PD: the alternative disposition of wiring can be reduced and thus the chip size can be reduced.

In the second embodiment, it is desirable to take the following measure in the fourth wiring layer M4 directly under the fifth wiring layer M5 directly under the uppermost wiring layer MH: a conductor pattern (wiring 5Ea, dummy wiring DL, and plug) whose width is larger than 2 μm is not formed directly under the wire embracing area PWA (area including the probe contact area PA and the wire bonding area WA) of each pad PD. In the fourth wiring layer M4, the following measure is taken: a conductor pattern (wiring 5Eb, dummy wiring DL, and plug) whose width is equal to or smaller than 2 μm is disposed (formed) directly under the wire embracing area PWA of each pad PD. In the example illustrated in FIG. 20, the following measure is taken in the fourth wiring layer M4: wirings 5Eb having a width (wiring width) equal to or smaller than 2 μm are disposed directly under the wire embracing area PWA of a pad PD; and wirings 5Ea having a width (wiring width) larger than 2 μm are not disposed directly under the wire embracing area PWA of the pad PD but are disposed in areas other than directly under the wire embracing area PWA.

The fourth wiring 5E is farther from a pad PD than the fifth wiring 5F is and is less prone to be plastically deformed than the fifth wiring 5F. If the probe pressure of a probe is nevertheless high, there is a possibility that the fourth wiring 5E is plastically deformed and a crack is produced in the insulating film. To cope with this, the above-mentioned measure is taken in the fourth wiring layer M4: the width of a conductor pattern (fourth wiring 5E) disposed directly under the wire embracing area PWA of each pad PD is limited to 2 μm or less. As a result, the plastic deformation is further suppressed and it is possible to bring a probe into contact with each pad PD with higher probe pressure and further stabilize testing (probe testing). This is the same with the fifth embodiment described below.

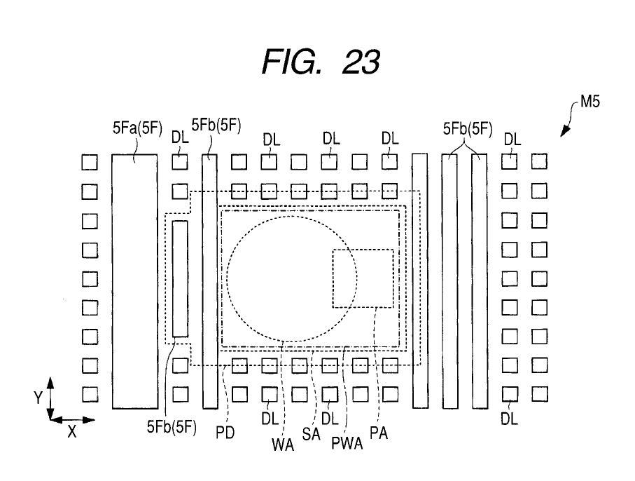

FIG. 23 is a substantial part plan view illustrating a modification to the semiconductor chip of a semiconductor device in the second embodiment and corresponds to FIG. 19. That is, FIG. 23 illustrates an example of the layout of conductor patterns (fifth wiring 5F and dummy wirings DL) in the fifth wiring layer M5 in proximity to a pad PD formation region.

In the modification to the second embodiment illustrated in FIG. 23, a wire bonding area WA and a probe contact area PA are so disposed that they at least partly overlap each other (overlap each other on a plane). The other configurations are the same as in the case illustrated in FIG. 18 to FIG. 20. Also in the modification to the second embodiment illustrated in FIG. 23, therefore, the following measure is taken in the fifth wiring layer M5 directly under the uppermost wiring layer MH as in the case in FIG. 18 to FIG. 20: a conductor pattern (fifth wiring 5F, dummy wiring DL, and plug 6C) is not formed directly under the wire embracing area PWA (area including the probe contact area PA and the wire bonding area WA) of each pad PD.

In the second embodiment, a conductor pattern (fifth wiring 5F, dummy wiring DL, and plug 6C) is not formed directly under the wire embracing area PWA (area including the probe contact area PA and the wire bonding area WA) of each pad PD. In this case, the following can be implemented as in the modification illustrated in FIG. 23: the wire bonding area WA and the probe contact area PA can be so disposed that they at least partly overlap each other (overlap each other on a plane). As a result, it is possible to reduce the planar size (area) of the wire embracing area PWA by an amount equivalent to the area provided to make them overlap each other. Thus it is possible to reduce the planar size (area) of the opening formation region SA and the pad PD. For this reason, the planar size (area) of the semiconductor chip can be reduced. Further, since a crack due to a probe is not produced in the probe contact area PA, the following problem does not arise: when a wire bond or a bump receives force because of heat stress after packaging, a pad portion is stripped starting at the area of cracking in the probe contact area PA and breaking of wire results.

### Third Embodiment

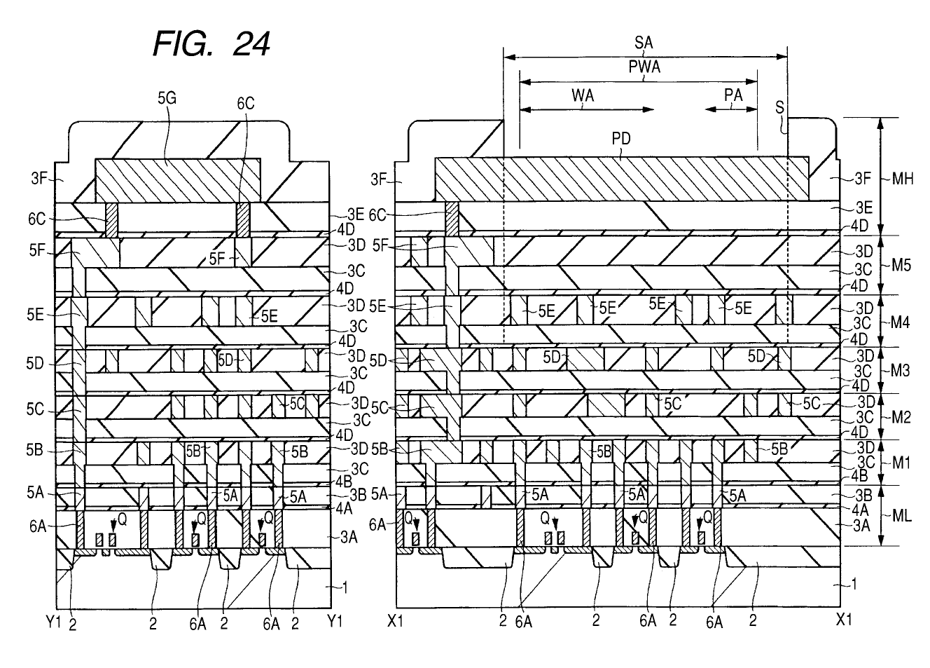

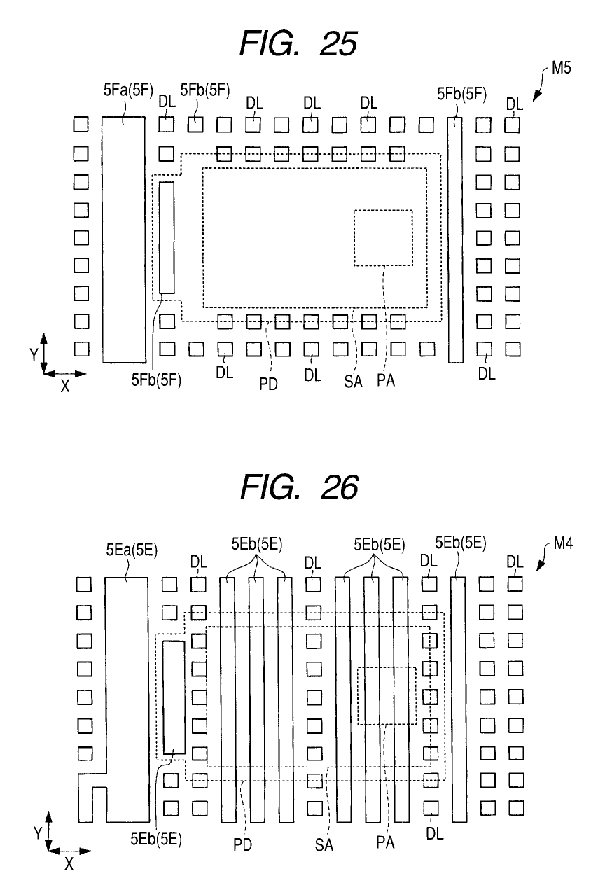

The left sketch in FIG. 24 is a sectional view of the internal area of the semiconductor chip of a semiconductor device in the third embodiment, corresponding to the area taken along line Y1-Y1 of FIG. 1. The right sketch is a sectional view of a pad placement area of the same semiconductor chip, corresponding to the area taken along line X1-X1 of FIG. 1. FIG. 25 and FIG. 26 are substantial part plan views illustrating the semiconductor chip of a semiconductor device in the third embodiment and respectively correspond to FIG. 5 and FIG. 6. That is, FIG. 25 illustrates an example of the layout of conductor patterns (fifth wiring 5F and dummy wirings DL) in the fifth wiring layer M5 in proximity to a pad PD formation region; and FIG. 26 illustrates an example of the layout of conductor patterns (fourth wiring 5E and dummy wirings DL) in the fourth wiring layer M4 in proximity to the pad PD formation region. In FIG. 25 and FIG. 26, the positions of a pad PD, an opening formation region SA, and a probe contact area PA are indicated by broken lines.

In the third embodiment, as seen from FIG. 24 to FIG. 26, the following measure is taken in the fifth wiring layer M5 directly under the uppermost wiring layer MH: a conductor pattern (fifth wiring 5F, dummy wiring DL, and plug 6C) is not formed directly under the opening formation region SA (area including the wire embracing area PWA) of each pad PD.

In the fifth wiring layer M5, a conductor pattern (fifth wiring 5F, dummy wiring DL, and plug 6C) is formed in areas other than directly under the opening formation region SA of each pad PD. That is, in the fifth wiring layer M5, conductor patterns comprised of the fifth wiring 5F and dummy wirings DL are disposed in, preferably all around, the areas other than directly under the opening formation regions SA. In the third embodiment, conductor patterns (wiring, dummy wirings, plugs) are formed in the lowermost wiring layer ML to the fourth wiring layer M4 even directly under the opening formation region SA of each pad PD.

According to the third embodiment, the same effect as in the first and second embodiments can be obtained.

In the third embodiment, it is desirable to take the following measure in the fourth wiring layer M4 directly under the fifth wiring layer M5 directly under the uppermost wiring layer MH: a conductor pattern (wiring 5Ea, dummy wiring DL, and plug) whose width is larger than 2 μm is not formed directly under the opening formation region SA (area including the wire embracing area PWA) of each pad PD. In the fourth wiring layer M4, the following measure is taken: a conductor pattern (wiring 5Eb, dummy wiring DL, and plug) whose width is equal to or smaller than 2 μm is disposed (formed) directly under the opening formation region SA of each pad PD. In the example illustrated in FIG. 26, the following measure is taken in the fourth wiring layer M4: wirings 5Eb having a width (wiring width) equal to or smaller than 2 μm are disposed directly under the opening formation region SA of a pad PD; and wirings 5Ea having a width (wiring width) larger than 2 μm are not disposed directly under the opening formation region SA of the pad PD but are disposed in areas other than directly under the opening formation region SA.

The fourth wiring 5E is farther from a pad PD than the fifth wiring 5F is and is less prone to be plastically deformed than the fifth wiring 5F. If the probe pressure of a probe is nevertheless high, there is a possibility that the fourth wiring 5E is plastically deformed and a crack is produced in the insulating film. To cope with this, the above-mentioned measure is taken in the fourth wiring layer M4: the width of a conductor pattern (fourth wiring 5E) disposed directly under the opening formation region SA of each pad PD is limited to 2 μm or less. As a result, the plastic deformation is further suppressed and it is possible to bring a probe into contact with each pad PD with higher probe pressure and further stabilize testing (probe testing). This is the same with the sixth embodiment described below.

As a modification to the third embodiment, the wire bonding area WA and the probe contact area PA may be disposed as in the above modification (FIG. 23) to the second embodiment. That is, they may be so disposed that they at least partly overlap each other (overlap each other on a plane). As a result, it is possible to reduce the planar size (area) of each pad PD and reduce the planar size (area) of the semiconductor chip.

### Fourth Embodiment

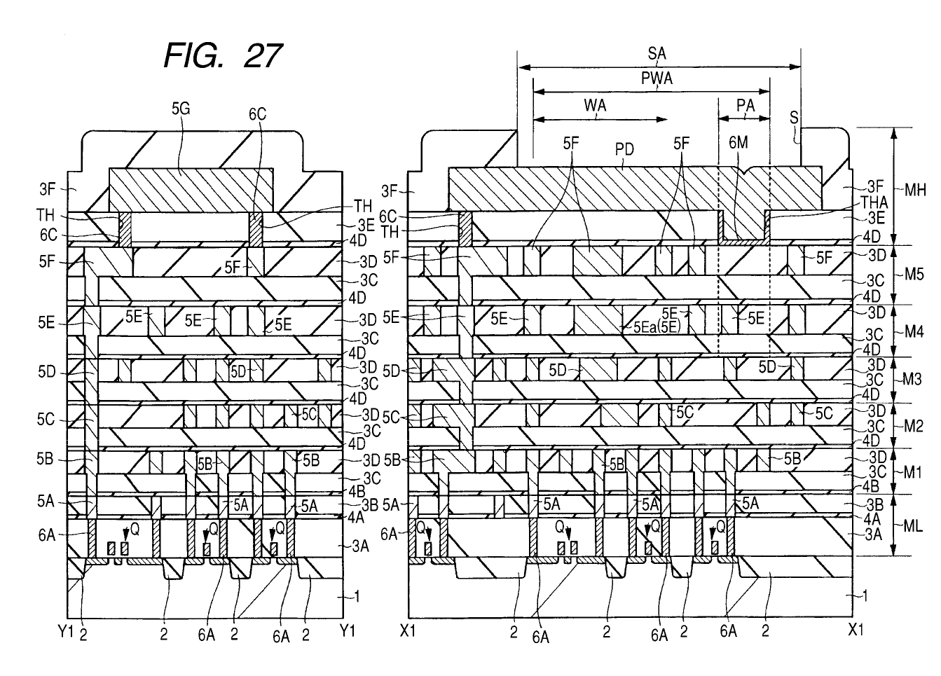

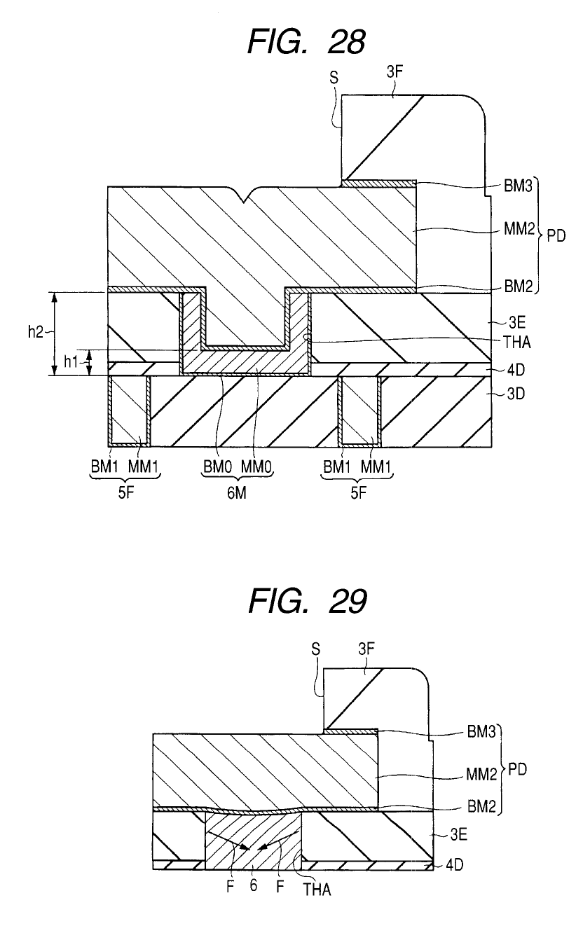

The left sketch in FIG. 27 is a sectional view of the internal area of the semiconductor chip of a semiconductor device in the fourth embodiment, corresponding to the area taken along line Y1-Y1 of FIG. 1. The right sketch is a sectional view of a pad placement area of the same semiconductor chip, corresponding to the area taken along line X1-X1 of FIG. 1. FIG. 28 is an enlarged sectional view of a substantial part of the uppermost wiring layer in a pad placement area of the semiconductor chip in FIG. 27.

The layout of the following in the fourth embodiment is substantially identical with that in the first embodiment (FIG. 5 and FIG. 6): the layout of conductor patterns (fifth wiring 5F and dummy wirings DL) in the fifth wiring layer M5 and conductor patterns (fourth wiring 5E and dummy wirings DL) in the fourth wiring layer M4 in proximity to a pad PD formation region. Therefore, the graphical representation of the layout will be omitted here.

In the fourth embodiment, the following measure is taken in the fifth wiring layer M5 directly under the uppermost wiring layer MH as in the first embodiment: a conductor pattern (fifth wiring 5F, dummy wiring DL, and plug 6C) is not formed directly under the probe contact area PA (probe mark) of each pad PD. As a result, the same effect as in the first embodiment can be obtained.

In the fourth embodiment, a conductor pattern (second conductor pattern) 6M having a U cross-sectional shape is formed directly under the probe contact area PA (probe mark) of each pad PD in contact with the under surface of the pad PD. More specific description will be given. In the fourth embodiment, a large hole THA is formed in the insulating films 3E, 4D in the uppermost wiring layer MH in the probe contact area PA; and the above conductor pattern 6M having a U cross-sectional shape and part of the conductor film of the pad PD are deposited (buried) in this order in the hole THA.

The configuration of the conductor pattern 6M is the same as that of the above plugs 6A, 6C. That is, the conductor pattern 6M includes a main wiring member MM0 and a barrier metal film BM0 as illustrated in FIG. 28. This main wiring member MM0 of the conductor pattern 6M is formed of high-melting point metal, such as tungsten (W). The thickness of the main wiring member MM0 is, for example, 400 nm or so. The upper surface of the main wiring member MM0 of the conductor pattern 6M is in contact with the barrier metal film BM2 of the pad PD.

The barrier metal film BM0 is provided between the main wiring member MM0 and an insulating film on the periphery (side face and bottom face) thereof in contact with the member and the film. This barrier metal film BM0 has a function of triggering the growth of tungsten and a function of enhancing the adhesion between the wiring and the insulating film.

The barrier metal film BM0 is so formed that the thickness thereof is smaller than that of the main wiring member MM0 and is formed of, for example, a laminated film of a titanium (Ti) film and a titanium nitride (TiN) film placed thereover. The titanium film is in contact with the insulating film and the titanium nitride film is in contact with the main wiring member MM0. The thickness of the barrier metal film BM0 is, for example, 60 nm or so.

As the material of the conductor pattern 6M, for example, the following can be used: high-melting point metal, such as tungsten, titanium, and tantalum; high-melting point metal nitride, such as tungsten nitride, titanium nitride, and tantalum nitride; or a laminated body of two or more materials selected from among the above materials.

The moduli of elasticity of tungsten and titanium are respectively 400 Gpa and 600 GPa, which are twice or more the modulus of elasticity, 70 Gpa, of silicon oxide. In addition the high-melting point metal, such as tungsten and titanium, is less prone to be plastically deformed than aluminum and copper.

In the fourth embodiment, as mentioned above, a conductor pattern 6M having a U cross-sectional shape is provided directly under the probe contact area PA of each pad PD. As a result, it is possible to disperse stress applied to the insulating film directly under the probe contact area PA when a probe PRB is pressed against the pad PD. Therefore, it is possible to further enhance the effect of suppressing or preventing cracking in an insulating film.

The formation range (planar position and planar size) of the above hole THA is identical with the planar range (planar position and planar size) of the probe contact area PA. For this reason, the formation range (planar position and planar size) of the conductor pattern 6M is also identical with the planar range (planar position and planar size) of the probe contact area PA. That is, the conductor patterns 6M are so formed that they do not have an interface (edge) in a probe contact area PA. Therefore, even though a conductor pattern 6M is provided directly under the probe contact area PA of a pad PD, a crack in an insulating film due to stress concentration on an interface (edge) of the conductor pattern is not produced, either.

For the foregoing reasons, it is possible to further suppress or prevent the production of a crack CLK in an insulating film under a pad PD by external force applied to the pad PD during probe inspection. Therefore, it is possible to further enhance the yield and reliability of the semiconductor device.

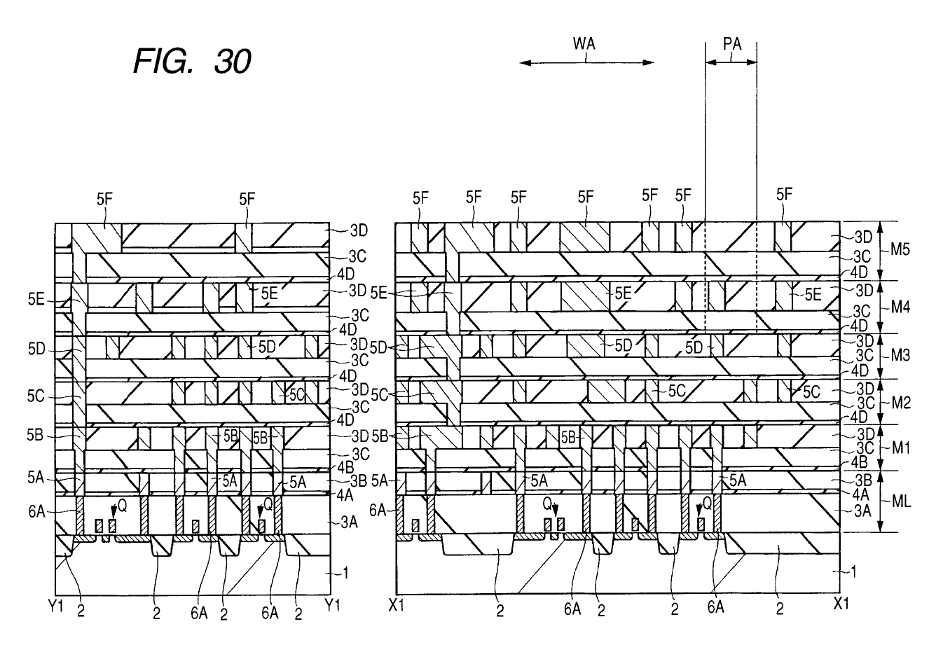

The planar size of the hole THA is larger than the planar size of through holes TH in the same wiring layer (uppermost wiring layer MH). At the same time, the planar size of the hole THA is larger than twice the thickness of each conductor pattern 6M so that the conductor pattern 6M does not completely fill each hole THA. For this purpose, the conductor pattern 6M is formed in a U cross-sectional shape so that the following is implemented: the holes THA are not completely filled therewith and the insulating films 3E, 4D on the inner side faces and bottom faces of the holes THA are covered therewith. That is, each conductor pattern 6M has a portion deposited along the inner side face of a hole and a portion deposited along the bottom face of the hole THA. A corner of the conductor pattern 6M is formed on the side where the junction between these portions and a constituent material of a pad PD is in contact. The reason why this configuration is adopted will be described with reference to FIG. 29.

FIG. 29 is a sectional view of a pad placement portion in the uppermost wiring layer of a semiconductor device reviewed by the present inventors. As illustrated in FIG. 29, the hole THA could be completely filled with the conductor film 6. The material of the conductor film 6 is identical with that of the conductor pattern 6M. However, to prevent increase in the capacitance between the pad PD and the uppermost wiring 5G and the fifth wiring 5F, the following measure is taken: the total thickness of the insulating films 3E, 4D between the pad PD and the uppermost wiring 5G and the fifth wiring 5F directly thereunder is, for example, 600 nm or above. That is, the depth of the hole THA is 600 nm or above. For this reason, the following can take place if the hole THA is completely filled with the conductor film 6: the conductor film 6 becomes too thick and the conductor film 6 can be stripped by its own stress (arrow F).

In the fourth embodiment, meanwhile, the conductor pattern 6M is formed in a U cross-sectional shape so that the following is implemented: the hole THA is not filled therewith and the insulating films 3E, 4D on the inner side face and bottom face of the hole THA are covered therewith. Therefore, large stress is not applied to the conductor pattern 6M. In addition, the conductor pattern 6M is formed in such a cross-sectional shape that there is not continuity along the direction of stress (arrow F) in FIG. 29. That is, it is formed in such a cross-sectional shape that the stress (arrow F) in FIG. 29 is divided. For the foregoing reasons, the conductor pattern 6M can be prevented from being stripped.

It has been found from the review by the present inventors that to prevent the conductor pattern 6M from being stripped by its own stress, the thickness of the conductor pattern should be set to, for example, 500 nm or below. If the conductor pattern 6M is too thin, however, the sufficient effect cannot be obtained in suppressing or preventing cracking in an insulating film under the above probe contact area PA. It has been found from the review by the present inventors that the following measure should be taken to obtain the sufficient effect in suppressing or preventing cracking in an insulating film under the probe contact area PA of a pad PD: the thickness of the conductor pattern 6M is set to a thickness, for example, 200 nm or above, larger than the thickness of the barrier metal films BM2, BM3 of the pad PD. In the fourth embodiment, therefore, it is desirable that the thickness h1 of the conductor pattern 6M should be, for example, 200 nm to 500 nm. Since the depth of the hole THA is 600 nm or above, the thickness h2 of the peripheral portion of the conductor pattern 6M is, for example, 600 nm or above.

In the fourth embodiment, the conductor pattern 6M is so formed that it has a U cross-sectional shape and part of the conductor film of the pad PD is filled in the recess of the U in contact with the conductor pattern 6M. As a result, the area of contact between the conductor pattern 6M and the pad PD can be increased. For this and other reasons, it is possible to enhance the adhesion between the conductor pattern 6M and the pad PD.

As a modification to the fourth embodiment, the following measure may be taken in the fifth wiring layer M5 directly under the uppermost wiring layer MH: a conductor pattern (fifth wiring 5F, dummy wiring DL, and plug 6C) is not provided directly under the wire embracing area PWA or opening formation region SA of each pad PD.

Description will be given to the method of manufacturing the semiconductor device in the fourth embodiment with reference to FIG. 30 to FIG. 33. The drawings from FIG. 30 to FIG. 33 are sectional views of the internal area (left) and a pad placement area (right) of the substrate 1 in the manufacturing process for the semiconductor device described with reference to FIG. 27 and FIG. 28.

First, as illustrated in FIG. 30, multiple wiring layers are formed over the principal surface of the substrate 1 by the same steps as described in relation to the first embodiment with reference to FIG. 10 to FIG. 14. (At this stage, the substrate is a semiconductor thin plate in a planar circular shape called semiconductor wafer.) FIG. 30 illustrates a state in which the wiring layers up to the fifth wiring layer M5 have been formed.

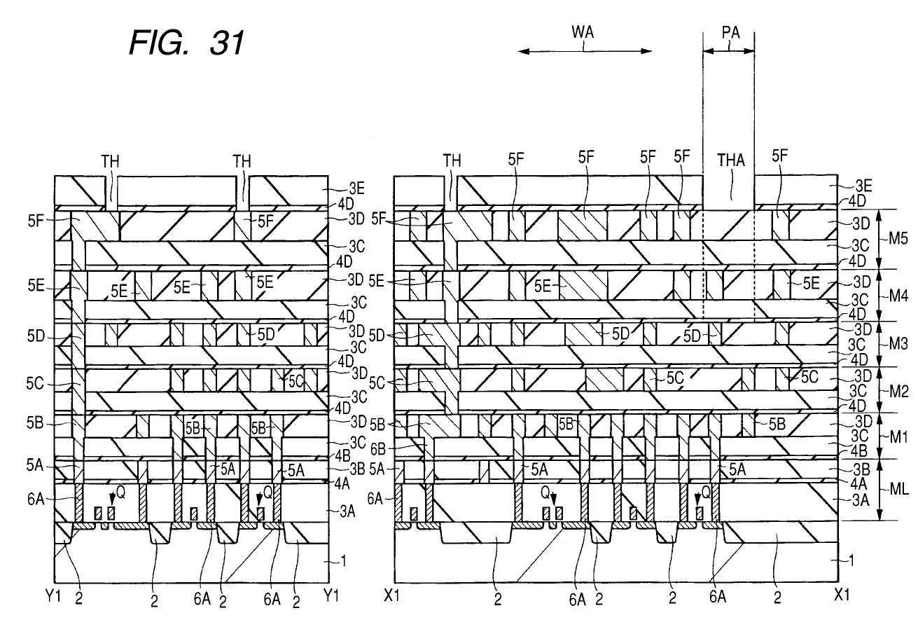

Subsequently, as illustrated in FIG. 31, the insulating films 4D, 3E are deposited in this order over the upper surfaces of the insulating film 3D and fifth wiring 5F in the fifth wiring layer M5 by CVD or the like. Thereafter, through holes TH and holes THA are formed in the insulating films 4D, 3E by photolithography and dry etching at the same step.

The planar size of each hole THA is larger than the planar size of each through hole TH. In the bottom faces of the holes THA, there is exposed the upper surface of the insulating film 3D in the fifth wiring layer M5. In the bottom of each through hole TH, there is exposed part of the upper surface of the fifth wiring 5F.

To form the through holes TH and the holes THA, first, the insulating film 3E is etched using a resist pattern as an etching mask. During this etching step, the insulating film 4D is prevented from being etched. Subsequently, the resist pattern is removed and then the insulating film 4D is etched. (At this time, the insulating film 3E functions as an etching mask.) As a result, the fifth layer wiring 5F can be prevented from being oxidized by oxygen plasma processing for the removal of resist.

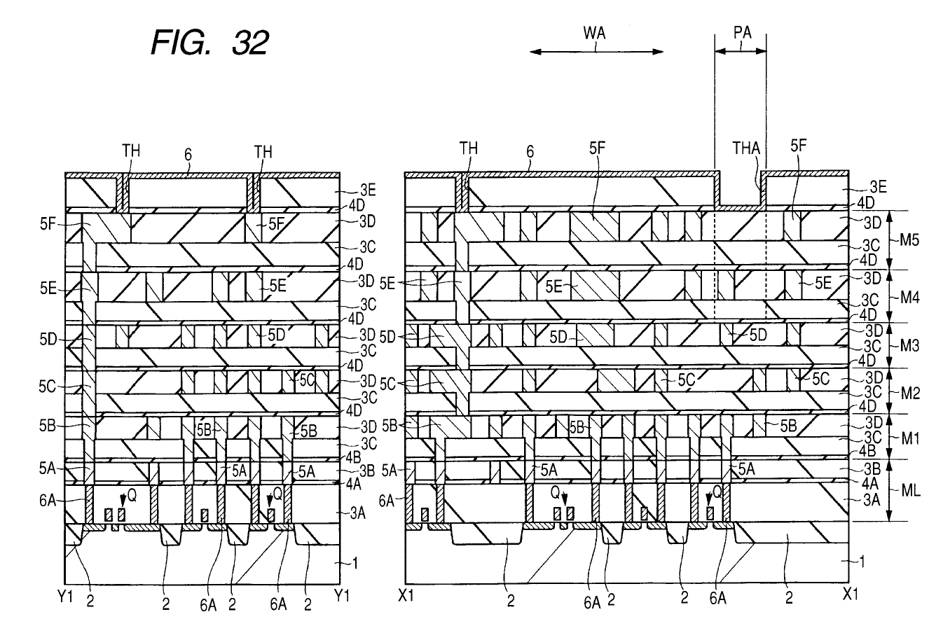

Thereafter, as illustrated in FIG. 32, the conductor film 6 is deposited over the insulating film 3E in the fifth wiring layer M5 over the principal surface of the substrate 1. The conductor film 6 is formed by depositing the barrier metal film BM0 and the main wiring member MM0 in this order from below. The barrier metal film BM0 is deposited by sputtering or the like. The main wiring member MM0 is deposited by CVD or the like.

The planar size of each through hole TH is equal to or smaller than twice the thickness of the conductor film 6 and the planar size of each hole THA is larger than twice the thickness of the conductor film 6. For this reason, the through holes TH are filled with the conductor film 6 but the holes THA are not completely filled with the conductor film 6.

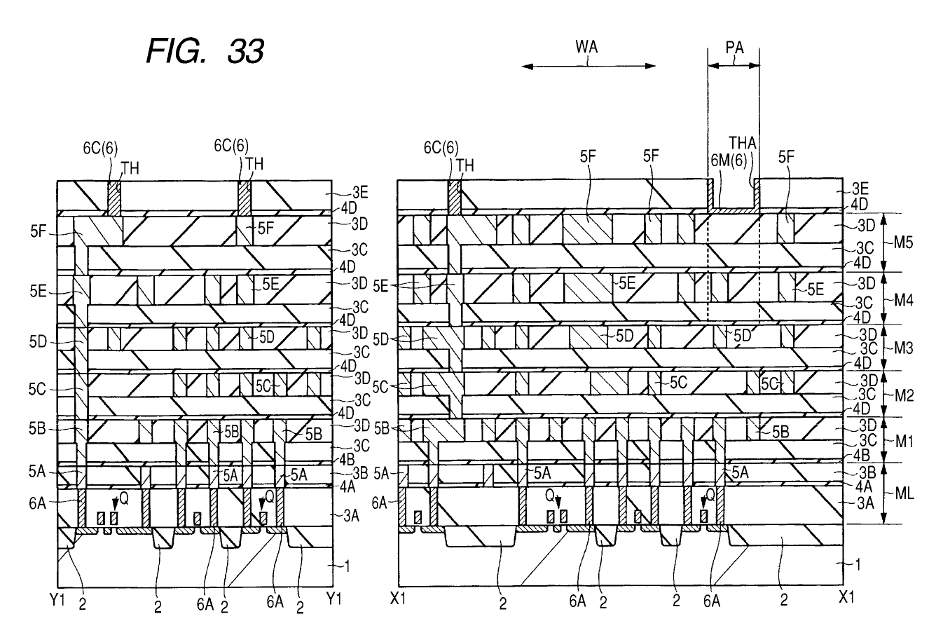

Subsequently, the portion of the conductor film 6 external to the through holes TH and the holes THA is removed by CMP. As a result, the plugs 6C formed of the conductor film 6 are formed in the through holes TH and the conductor patterns (second conductor patterns) 6M formed of the conductor film 6 are formed in the holes THA as illustrated in FIG. 33.

The subsequent steps are the same as in the first embodiment. That is, the uppermost wiring 5G and pads PD illustrated in FIG. 27 are formed in the uppermost wiring layer MH at the same step. Subsequently, the insulating film 3F is so formed that the uppermost wiring 5G and the pads PD are covered therewith and then openings S are formed in the insulating film 3F so that the pads PD are partly exposed.

Thereafter, a probe PRB is brought into contact with the pads PD of each of the multiple semiconductor chips on the principal surface of the substrate 1 to inspect the semiconductor chips on the substrate 1 for electrical characteristics. Also in the fourth embodiment, as mentioned above, a trouble that a crack is produced in an insulating film directly under pads PD can be prevented at this time. Therefore, it is possible to enhance the yield and reliability of the semiconductor device.

Thereafter, the substrate 1 is diced to cut individual semiconductor chips out of the substrate 1. Then a wire is bonded to each pad PD of each semiconductor chip and a sealing step is carried out to finish the manufacture of the semiconductor device. In case bumps are joined with the pads PD, the following procedure is taken: after probe inspection, bumps are joined with the pads in the chip formation regions in the semiconductor wafer and then dicing is carried out.

### Fifth Embodiment

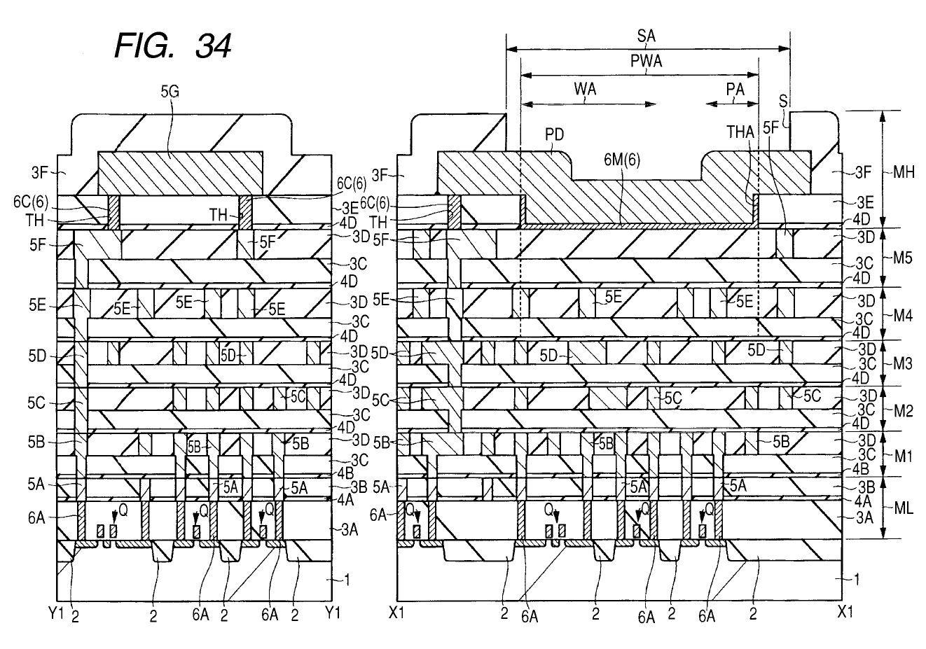

The left sketch in FIG. 34 is a sectional view of the internal area of the semiconductor chip of a semiconductor device in the fifth embodiment, corresponding to the area taken along line Y1-Y1 of FIG. 1. The right sketch is a sectional view of a pad placement area of the same semiconductor chip, corresponding to the area taken along line X1-X1 of FIG. 1.

The layout of the following in the fifth embodiment is substantially identical with that in the second embodiment (FIG. 19 and FIG. 20): the layout of conductor patterns (fifth wiring 5F and dummy wirings DL) in the fifth wiring layer M5 and conductor patterns (fourth wiring 5E and dummy wirings DL) in the fourth wiring layer M4 in proximity to a pad PD formation region. Therefore, the graphical representation of the layout will be omitted here.

In the fifth embodiment, the following measure is taken in the fifth wiring layer M5 directly under the uppermost wiring layer MH as in the second embodiment: a conductor pattern (fifth wiring 5F, dummy wiring DL, and plug 6C) is not formed directly under the wire embracing area PWA of each pad PD. As a result, the same effect as in the second embodiment can be obtained.

In fifth embodiment, a conductor pattern 6M having a U cross-sectional shape is formed directly under the wire embracing area PWA of each pad PD in contact with the under surface of the pad PD. More specific description will be given. In the fifth embodiment, a large hole THA is formed in the wire embracing area PWA wider than the above probe contact area PA in the insulating films 3E, 4D in the uppermost wiring layer MH; and the above conductor pattern 6M having a U cross-sectional shape and part of the conductor film of the pad PD are deposited (buried) in this order in the hole THA.

The configuration of and the formation method for the hole THA and the conductor pattern 6M in the fifth embodiment are the same as described in relation to the fourth embodiment, except planar size. In the fifth embodiment, the formation range (planar position and planar size) of the hole THA and the conductor pattern 6M is identical with the planar range (planar position and planar size) of the wire embracing area PWA. That is, the conductor patterns 6M are so formed that they do not have an interface (edge) in a wire embracing area PWA. Therefore, even though a conductor pattern 6M is provided directly under the wire embracing area PWA of a pad PD, a crack in an insulating film due to stress concentration on an interface (edge) of the conductor pattern is not produced, either.

According to the fifth embodiment, it is possible to further suppress or prevent the production of a crack CLK in an insulating film under a pad PD than in the fourth embodiment. Therefore, it is possible to further enhance the yield and reliability of the semiconductor device. With respect to the other aspects, the same effect as in the fourth embodiment can be obtained.

As a modification to the fifth embodiment, the following measure may be taken in the fifth wiring layer M5 directly under the uppermost wiring layer MH: a conductor pattern (fifth wiring 5F, dummy wiring DL, and plug 6C) is not provided directly under the opening formation region SA of each pad PD.

As another modification to the fifth embodiment, the following measure may be taken as in the above modification (FIG. 23) to the second embodiment: the wire bonding area WA and the probe contact area PA are so disposed that they at least partly overlap each other (overlap each other on a plane). As a result, the planar size (area) of each pad PD can be reduced and thus the planar size (area) of the semiconductor chip can be reduced.

### Sixth Embodiment

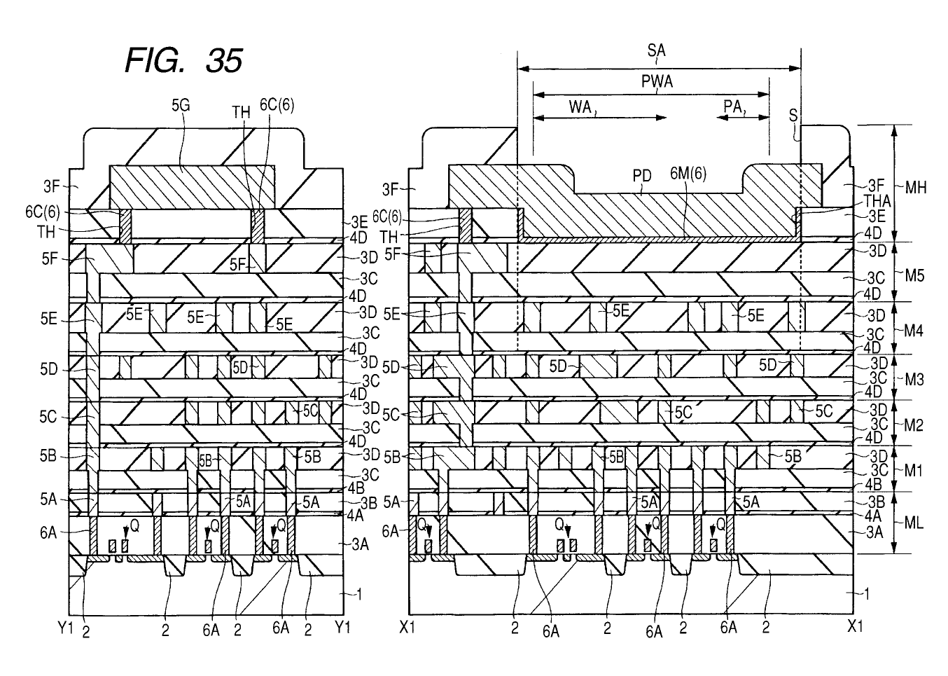

The left sketch in FIG. 35 is a sectional view of the internal area of the semiconductor chip of a semiconductor device in the sixth embodiment, corresponding to the area taken along line Y1-Y1 of FIG. 1. The right sketch is a sectional view of a pad placement area of the same semiconductor chip, corresponding to the area taken along line X1-X1 of FIG. 1.

The layout of the following in the sixth embodiment is substantially identical with that in the third embodiment (FIG. 25 and FIG. 26): the layout of conductor patterns (fifth wiring 5F and dummy wirings DL) in the fifth wiring layer M5 and conductor patterns (fourth wiring 5E and dummy wirings DL) in the fourth wiring layer M4 in proximity to a pad PD formation region. Therefore, the graphical representation of the layout will be omitted here.

In the sixth embodiment, the following measure is taken in the fifth wiring layer M5 directly under the uppermost wiring layer MH as in the third embodiment: a conductor pattern (fifth wiring 5F, dummy wiring DL, and plug 6C) is not formed directly under the opening formation region SA of each pad PD. As a result, the same effect as in the third embodiment can be obtained.

In the sixth embodiment, a conductor pattern 6M having a U cross-sectional shape is formed directly under the opening formation region SA of each pad PD in contact with the under surface of the pad PD. More specific description will be given. In the sixth embodiment, a large hole THA is formed in the opening formation region SA wider than the probe contact area PA and the wire embracing area PWA in the insulating films 3E, 4D in the uppermost wiring layer MH; and the above conductor pattern 6M having a U cross-sectional shape and part of the conductor film of the pad PD are deposited (buried) in this order in the hole THA.

The configuration of and the formation method for the hole THA and the conductor pattern 6M in the sixth embodiment are the same as described in relation to the fourth and fifth embodiments, except planar size. In the sixth embodiment, the formation range (planar position and planar size) of the hole THA and the conductor pattern 6M is identical with the planar range (planar position and planar size) of the opening formation region SA. That is, the conductor patterns 6M are so formed that they do not have an interface (edge) in an opening formation region SA. Therefore, even though a conductor pattern 6M is provided directly under the opening formation region SA of a pad PD, a crack in an insulating film due to stress concentration on an interface (edge) of the conductor pattern is not produced, either.

According to the sixth embodiment, it is possible to further suppress or prevent the production of a crack CLK in an insulating film under a pad PD than in the fifth embodiment. Therefore, it is possible to further enhance the yield and reliability of the semiconductor device. With respect to the other aspects, the same effect as in the fourth and fifth embodiments can be obtained.

As a modification to the sixth embodiment, the wire bonding area WA and the probe contact area PA may be disposed as in the above modification (FIG. 23) to the second embodiment. That is, they may be so disposed that they at least partly overlap each other (overlap each other on a plane). As a result, it is possible to reduce the planar size (area) of each pad PD and reduce the planar size (area) of the semiconductor chip.

### Seventh Embodiment

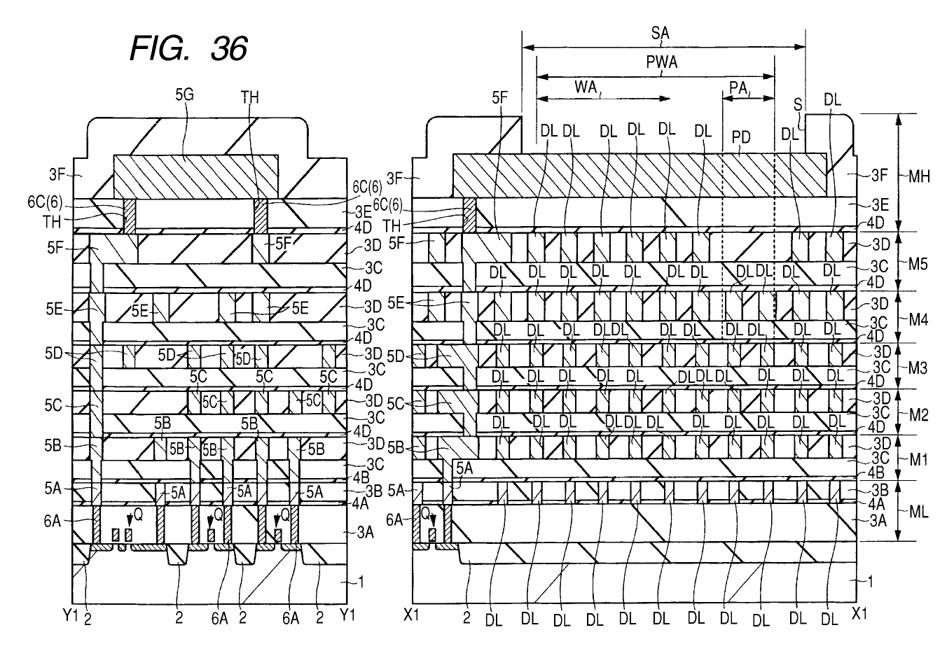

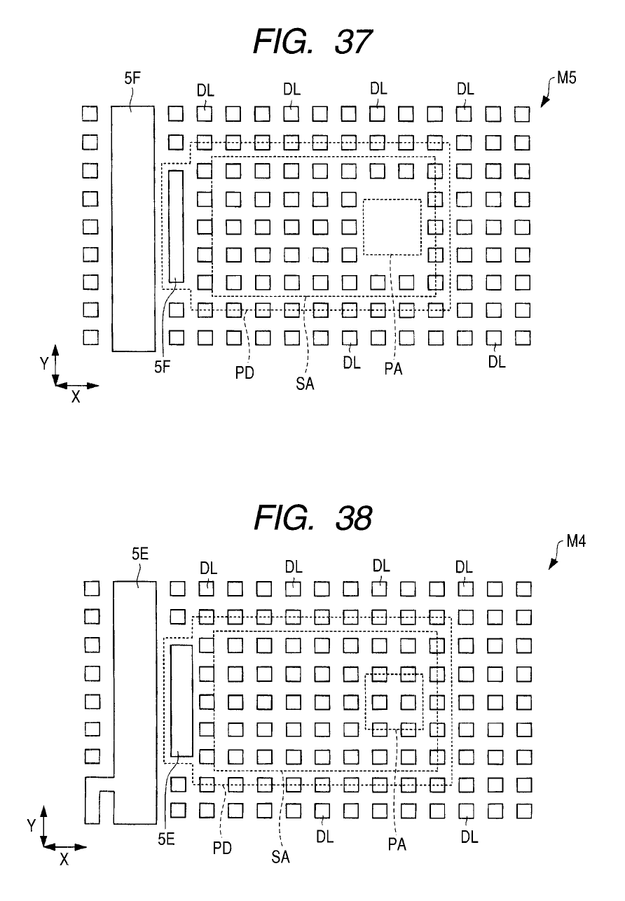

The left sketch in FIG. 36 is a sectional view of the internal area of the semiconductor chip of a semiconductor device in the seventh embodiment, corresponding to the area taken along line Y1-Y1 in FIG. 1. The right sketch is a sectional view of a pad placement area of the same semiconductor chip, corresponding to the area taken along line X1-X1 of FIG. 1. FIG. 37 and FIG. 38 are substantial part plan views illustrating the semiconductor chip of a semiconductor device in the seventh embodiment and respectively correspond to FIG. 5 and FIG. 6. That is, FIG. 37 illustrates an example of the layout of conductor patterns (fifth wiring 5F and dummy wirings DL) in the fifth wiring layer M5 in proximity to a pad PD formation region; and FIG. 38 illustrates an example of the layout of conductor patterns (fourth wiring 5E and dummy wirings DL) in the fourth wiring layer M4 in proximity to the pad PD formation region. In FIG. 37 and FIG. 38, the positions of a pad PD, an opening formation region SA, and a probe contact area PA are indicated by broken lines.

In the seventh embodiment, an element is not formed under each pad PD but a trench-like isolation section 2 is formed there. In this case, it is required to take the following measure to prevent a step from being formed between an area with an element and an area without an element (that is, to ensure the planarity of each wiring layer): it is required to provide a dummy wiring DL in each wiring layer, especially, under each pad PD. In general, the dummy wirings DL are formed at the same step as the wirings in the same layer are formed but they are formed of a conductor pattern irrelevant to the configuration of the integrated circuit itself. The dummy wirings DL are disposed all around areas where no wiring is disposed.

Also in the seventh embodiment, the following measure is taken in the fifth wiring layer M5 directly under the uppermost wiring layer MH as in the first embodiment: a conductor pattern (fifth wiring 5F, dummy wiring DL, and plug 6C) is not formed directly under the probe contact area PA (probe mark) of each pad PD. The minimum process dimensions of the uppermost wiring layer MH are larger than the minimum process dimensions of the fifth wiring layer M5 and lower wiring layers and the focal depth thereof in lithography is large. Therefore, even if some of the dummy wirings DL in the fifth wiring layer M5 are eliminated, degradation in the planarity thereof is acceptable.

In the fifth wiring layer M5, conductor patterns (fifth wiring 5F, dummy wirings DL, and plugs 6C) are formed in the areas other than directly under the probe contact areas PA. That is, in the fifth wiring layer M5, conductor patterns comprised of the fifth wiring 5F and dummy wirings DL are disposed in, preferably all around, the areas other than directly under the probe contact areas PA.

Dummy wirings DL are disposed in the fourth wiring layer M4 and lower wiring layers even directly under the probe contact area PA of each pad PD and thus the planarity of each wiring layer is ensured. The other configurations are the same as in the first embodiment.

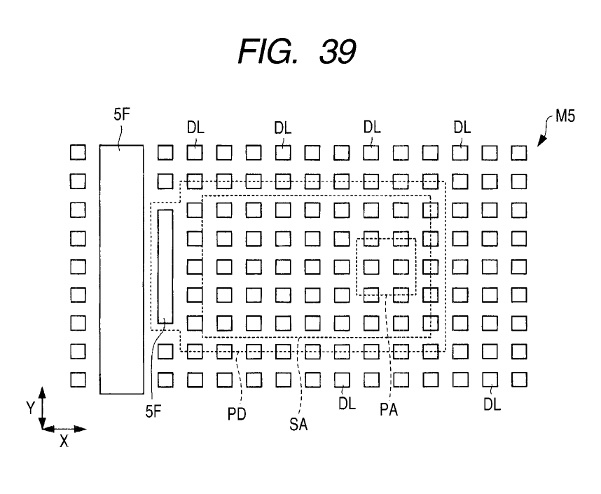

FIG. 39 is a plan view of a substantial part of a semiconductor chip in another comparative example reviewed by the present inventors. The drawing illustrates the layout of conductor patterns (fifth wiring 5F and dummy wirings DL) in the fifth wiring layer M5 in proximity to a pad PD formation region. It corresponds to FIG. 8 illustrating the semiconductor chip in the comparative example described in relation to the first embodiment. The comparative example in FIG. 7 to FIG. 9 described in relation to the first embodiment and the comparative example in FIG. 39 are different from each other in the type of conductor patterns formed under pads PD. (In the example in FIG. 7 to FIG. 9, both wirings and dummy wirings are formed; and in the example in FIG. 39, almost all the conductor patterns are dummy wirings.) Also in the comparative example in FIG. 39, the same problem as in the comparative example in FIG. 7 to FIG. 9 described in relation to the first embodiment arises. The seventh embodiment makes it possible to solve this problem as described in relation to the first embodiment.

According to the seventh embodiment, not only the same effect as in the first embodiment but also the following effect can be obtained. That is, it is possible to ensure the planarity of the wiring layers and thus enhance the accuracy of wiring pattern transfer and formation. For this reason, it is possible to minimize the layout limitation due to degradation in the planarity of wiring layers. Therefore, it is possible to enhance the reliability and yield of the semiconductor device. Further, it is possible to facilitate the reduction of semiconductor chip size.

### Eighth Embodiment

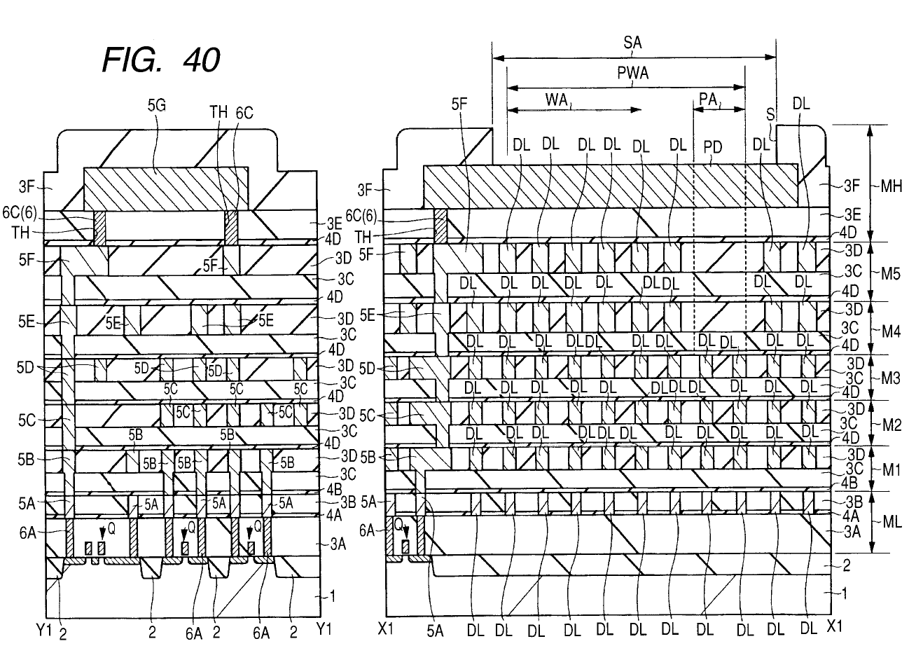

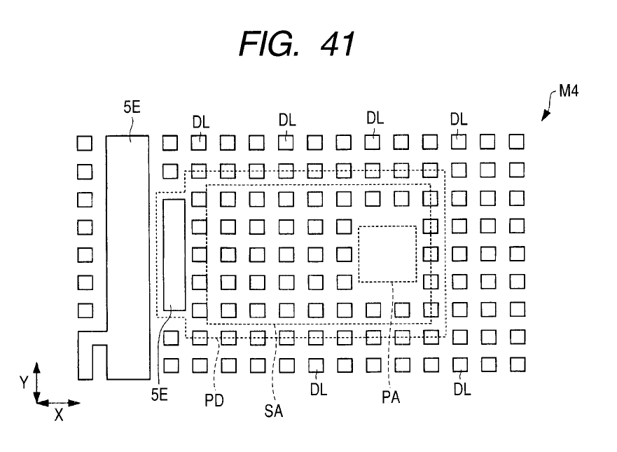

The left sketch in FIG. 40 is a sectional view of the internal area of the semiconductor chip of a semiconductor device in the eighth embodiment, corresponding to the area taken along line Y1-Y1 of FIG. 1. The right sketch is a sectional view of a pad placement area of the same semiconductor chip, corresponding to the area taken along line X1-X1 of FIG. 1. FIG. 41 is a substantial part plan view illustrating the semiconductor chip of a semiconductor device in the eighth embodiment and corresponds to FIG. 38. That is, FIG. 41 illustrates an example of the layout of conductor patterns (fourth wiring 5E and dummy wirings DL) in the fourth wiring layer M4 in proximity to a pad PD formation region. In FIG. 41, the positions of a pad PD, an opening formation region SA, and a probe contact area PA are indicated by broken lines.

The layout of conductor patterns (fifth wiring 5F and dummy wirings DL) in the fifth wiring layer M5 in proximity to a pad PD formation region in the eighth embodiment is substantially identical with that in the seventh embodiment (FIG. 37). Therefore, the graphical representation of the layout will be omitted here.

The eighth embodiment is a modification to the seventh embodiment. That is, also in the eighth embodiment, an element is not formed under each pad PD as in the seventh embodiment. Therefore, dummy wirings DL are provided in each of the multiple wiring layers under pads.

The configuration of the semiconductor device in the eighth embodiment is different from that in the seventh embodiment in the following aspect: in the eighth embodiment, the following measure is taken in two layers, the fifth wiring layer M5 directly under the uppermost wiring layer MH and the fourth wiring layer M4: a conductor pattern (fifth wiring 5F, fourth wiring 5E, dummy wiring DL, and plug 6C) is not formed directly under the probe contact area PA (probe mark) of each pad PD. That is, the measure described below is taken in all the wiring layers without a low-dielectric constant film, low in mechanical strength, above the wiring layers with a low-dielectric constant film. (The wiring layers with a low-dielectric constant film are the first wiring layer M1 to the third wiring layer M3.) (The wiring layers without a low-dielectric constant film are the fourth wiring layer M4 and the fifth wiring layer M5.) The above conductor pattern is selectively eliminated from the relevant areas (directly under the probe contact area PA (probe mark) of each pad PD). As a result, cracking in an insulating film under a pad PD can be more effectively suppressed or prevented than in the first embodiment.

In the fourth wiring layer M4 and the fifth wiring layer M5, conductor patterns (fourth wiring 5E, fifth wiring 5F, dummy wirings DL, and plugs 6C) are formed in the areas other than directly under the probe contact areas PA. That is, the following measure is taken in the fourth wiring layer M4 and the fifth wiring layer M5: conductor patterns comprised of the fourth wiring 5E and dummy wirings DL or conductor patterns comprised of the fifth wiring 5F and dummy wirings DL are disposed in, preferably all around, the areas other than directly under the probe contact areas PA.

The minimum process dimensions of the uppermost wiring layer MH and the fifth wiring layer M5 are larger than the minimum process dimensions of the fourth wiring layer M4 and lower wiring layers and the focal depth thereof in lithography is large. Therefore, even if some of the dummy wirings DL in the fifth wiring layer M5 and the fourth wiring layer M4 are eliminated, degradation in the planarity thereof is acceptable. In the eighth embodiment, dummy wirings DL are disposed in the third wiring layer M3 and lower wiring layers even directly under the probe contact area PA of each pad PD and thus the planarity of each wiring layer is ensured. Therefore, it is possible to ensure the planarity of the wiring layers and thus enhance the accuracy of wiring pattern transfer and formation. For this reason, it is possible to minimize the layout limitation due to degradation in the planarity of wiring layers. Therefore, it is possible to enhance the reliability and yield of the semiconductor device. Further, it is possible to facilitate the reduction of semiconductor chip size. With respect to the other aspects, the same effect as in the first and seventh embodiments can be obtained.

### Ninth Embodiment

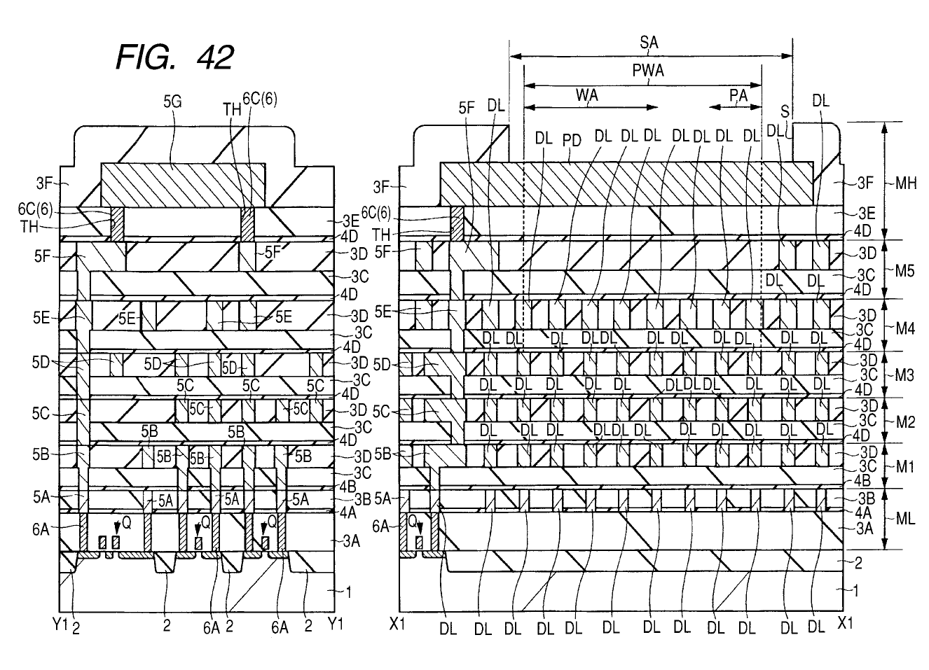

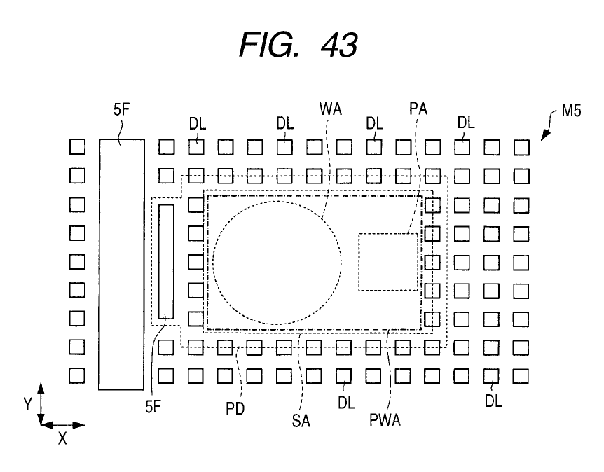

The left sketch in FIG. 42 is a sectional view of the internal area of the semiconductor chip of a semiconductor device in the ninth embodiment, corresponding to the area taken along line Y1-Y1 of FIG. 1. The right sketch is a sectional view of a pad placement area of the same semiconductor chip, corresponding to the area taken along line X1-X1 of FIG. 1. FIG. 43 is a substantial part plan view illustrating the semiconductor chip of a semiconductor device in the ninth embodiment and corresponds to FIG. 37. That is, FIG. 43 illustrates an example of the layout of conductor patterns (fifth wiring 5F and dummy wirings DL) in the fifth wiring layer M5 in proximity to a pad PD formation region. In FIG. 43, the positions of a pad PD, an opening formation region SA, a probe contact area PA, and a wire bonding area WA are indicated by broken lines and the position of a wire embracing area PWA is indicated by an alternate long and short dash line.

The layout of conductor patterns (fourth wiring 5E and dummy wirings DL) in the fourth wiring layer M4 in proximity to a pad PD formation region in the ninth embodiment is substantially identical with that in the seventh embodiment (FIG. 38). Therefore, the graphical representation of the layout will be omitted here.

In the ninth embodiment, an element is not formed under each pad PD as in the seventh and eighth embodiments. Therefore, dummy wirings DL are provided in each of the multiple wiring layers under pads PD as described in relation to the seventh and eighth embodiments.

Also in the ninth embodiment, however, the following measure is taken in the fifth wiring layer M5 directly under the uppermost wiring layer MH as in the second embodiment: a conductor pattern (fifth wiring 5F, dummy wiring DL, and plug 6C) is not formed directly under the wire embracing area PWA of each pad PD. Therefore, cracking in an insulating film under a pad PD can be suppressed or prevented as in the second embodiment.

In the fifth wiring layer M5, conductor patterns (fifth wiring 5F, dummy wirings DL, and plugs 6C) are formed in the areas other than directly under each wire embracing area PWA. That is, in the fifth wiring layer M5, conductor patterns comprised of the fifth wiring 5F and dummy wirings DL are disposed in, preferably all around, the areas other than directly under the wire embracing areas PWA.

The minimum process dimensions of the uppermost wiring layer MH are larger than the minimum process dimensions of the fifth wiring layer M5 and lower wiring layers and the focal depth thereof in lithography is large. Therefore, even if some of the dummy wirings DL in the fifth wiring layer M5 are eliminated, degradation in the planarity thereof is acceptable. Dummy wirings DL are disposed in the fourth wiring layer M4 and lower wiring layers even directly under the wire embracing area PWA of each pad PD and thus the planarity of each wiring layer is ensured. Therefore, it is possible to ensure the planarity of wiring layers and thus enhance the accuracy of wiring pattern transfer and formation. For this reason, it is possible to minimize the layout limitation due to degradation in the planarity of wiring layers. Therefore, it is possible to enhance the reliability and yield of the semiconductor device. Further, it is possible to facilitate the reduction of semiconductor chip size. The other configurations and effect are the same as in the second embodiment.

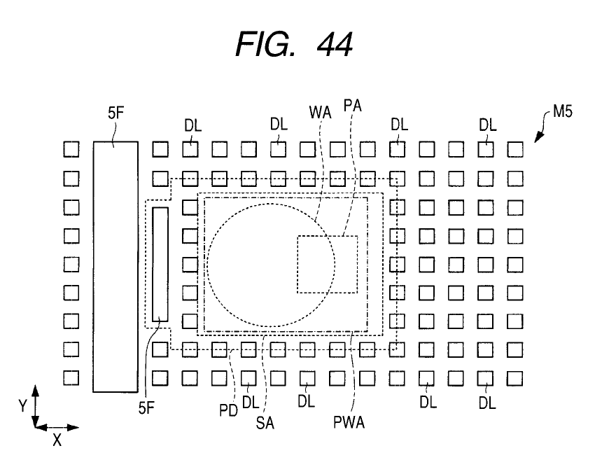

FIG. 44 is a substantial part plan view illustrating a modification to the semiconductor chip of a semiconductor device in the ninth embodiment and corresponds to FIG. 23. That is, FIG. 44 illustrates an example of the layout of conductor patterns (fifth wiring 5F and dummy wirings DL) in the fifth wiring layer M5 in proximity to a pad PD formation region.

In the modification to the ninth embodiment illustrated in FIG. 44, the following measure is taken as in the modification illustrated in FIG. 23: the wire bonding area WA and the probe contact area PA are so disposed that they at least partly overlap each other (overlap each other on a plane). Also in this case, the following measure is taken in the fifth wiring layer M5 directly under the uppermost wiring layer MH: a conductor pattern (fifth wiring 5F, dummy wiring DL, and plug 6C) is not formed directly under the wire embracing area PWA of each pad PD. As a result, it is possible to reduce the planar size (area) of the wire embracing area PWA by an amount equivalent to the area provided to make them overlap each other. Thus it is possible to reduce the planar size (area) of the opening formation region SA and the pad PD. For this reason, the planar size (area) of the semiconductor chip can be reduced.

### 10th Embodiment

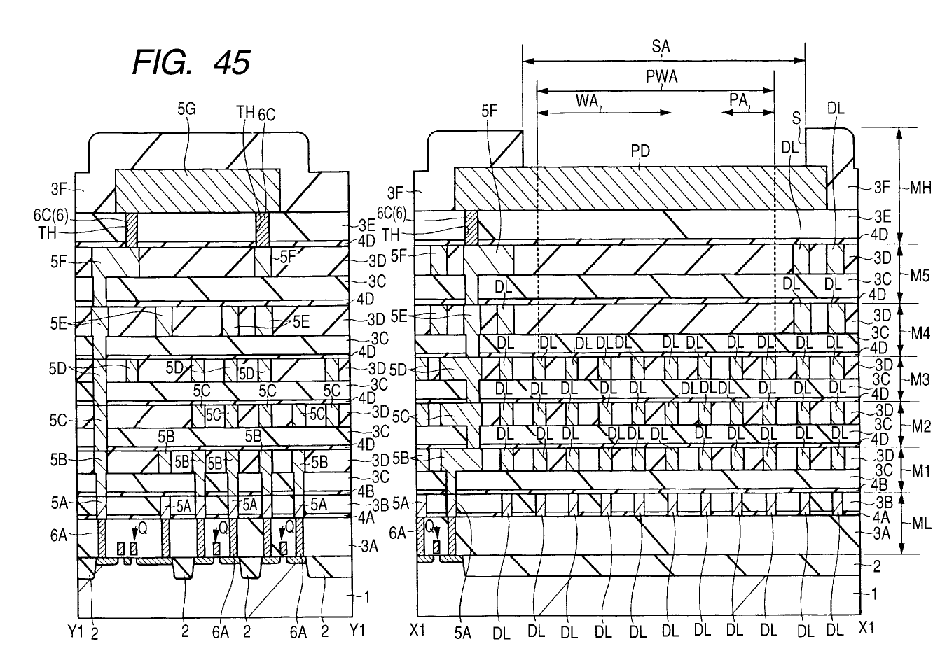

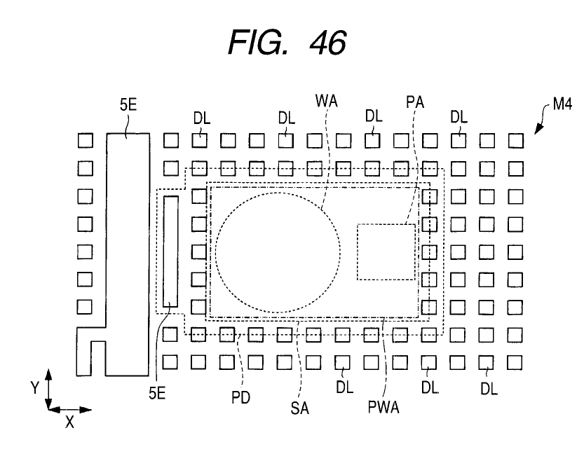

The left sketch in FIG. 45 is a sectional view of the internal area of the semiconductor chip of a semiconductor device in the 10th embodiment, corresponding to the area taken along line Y1-Y1 of FIG. 1. The right sketch is a sectional view of a pad placement area of the same semiconductor chip, corresponding to the area taken along line X1-X1 of FIG. 1. FIG. 46 is a substantial part plan view illustrating the semiconductor chip of a semiconductor device in the 10th embodiment and corresponds to FIG. 38. That is, FIG. 46 illustrates an example of the layout of conductor patterns (fourth wiring 5E and dummy wirings DL) in the fourth wiring layer M4 in proximity to a pad PD formation region. In FIG. 46, the positions of a pad PD, an opening formation region SA, a probe contact area PA, and a wire bonding area WA are indicated by broken lines and the position of a wire embracing area PWA is indicated by an alternate long and short dash line.

The layout of conductor patterns (fifth wiring 5F and dummy wirings DL) in the fifth wiring layer M5 in proximity to a pad PD formation region in the 10th embodiment is substantially identical with that in the ninth embodiment (FIG. 43). Therefore, the graphical representation of the layout will be omitted here.

The 10th embodiment is a modification to the ninth embodiment. That is, also in the 10th embodiment, an element is not formed under each pad PD as in the ninth embodiment. Therefore, dummy wirings DL are provided in each of the multiple wiring layers under pads.

The configuration of the semiconductor device in the 10th embodiment is different from that in the ninth embodiment in the following aspect: in the 10th embodiment, the following measure is taken in two layers, the fifth wiring layer M5 directly under the uppermost wiring layer MH and the fourth wiring layer M4: a conductor pattern (fifth wiring 5F, fourth wiring 5E, dummy wiring DL, and plug 6C) is not formed directly under the wire embracing area PWA of each pad PD. That is, the measure described below is taken in all the wiring layers without a low-dielectric constant film, low in mechanical strength, above the wiring layers with a low-dielectric constant film. (The wiring layers with a low-dielectric constant film are the first wiring layer M1 to the third wiring layer M3.) (The wiring layers without a low-dielectric constant film are the fourth wiring layer M4 and the fifth wiring layer M5.) The above conductor pattern is selectively eliminated from the relevant areas (directly under the wire embracing area PWA of each pad PD). As a result, cracking in an insulating film under a pad PD can be more effectively suppressed or prevented than in the second embodiment.

In the fourth wiring layer M4 and the fifth wiring layer M5, conductor patterns (fourth wiring 5E, fifth wiring 5F, dummy wirings DL, and plugs 6C) are formed in the areas other than directly under the wire embracing areas PWA. That is, the following measure is taken in the fourth wiring layer M4 and the fifth wiring layer M5: conductor patterns comprised of the fourth wiring 5E and dummy wirings DL or conductor patterns comprised of the fifth wiring 5F and dummy wirings DL are disposed in, preferably all around, the areas other than directly under the wire embracing areas PWA.

The minimum process dimensions of the uppermost wiring layer MH and the fifth wiring layer M5 are larger than the minimum process dimensions of the fourth wiring layer M4 and lower wiring layers and the focal depth thereof in lithography is large. Therefore, even if some of the dummy wirings DL in the fifth wiring layer M5 and the fourth wiring layer M4 are eliminated, degradation in the planarity thereof is acceptable. In the 10th embodiment, dummy wirings DL are disposed in the third wiring layer M3 and lower wiring layers even directly under the wire embracing area PWA of each pad PD and thus the planarity of each wiring layer is ensured. Therefore, it is possible to ensure the planarity of the wiring layers and thus enhance the accuracy of wiring pattern transfer and formation. For this reason, it is possible to minimize the layout limitation due to degradation in the planarity of wiring layers. Therefore, it is possible to enhance the reliability and yield of the semiconductor device. Further, it is possible to facilitate the reduction of semiconductor chip size. With respect to the other aspects, the same effect as in the second and ninth embodiments can be obtained.

As a modification to the 10th embodiment, the following measure may be taken as in the modification (FIG. 44) to the ninth embodiment: the wire bonding area WA and the probe contact area PA may be so disposed that they at least partly overlap each other (overlap each other on a plane). As a result, the planar size (area) of each pad PD can be reduced and thus the planar size (area) of the semiconductor chip can be reduced.

### 11th Embodiment

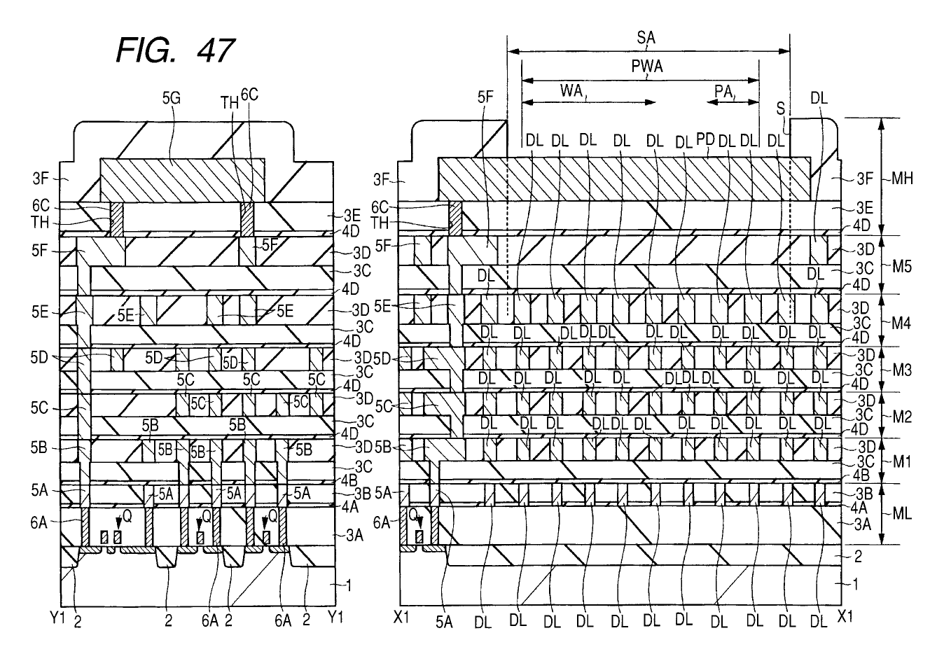

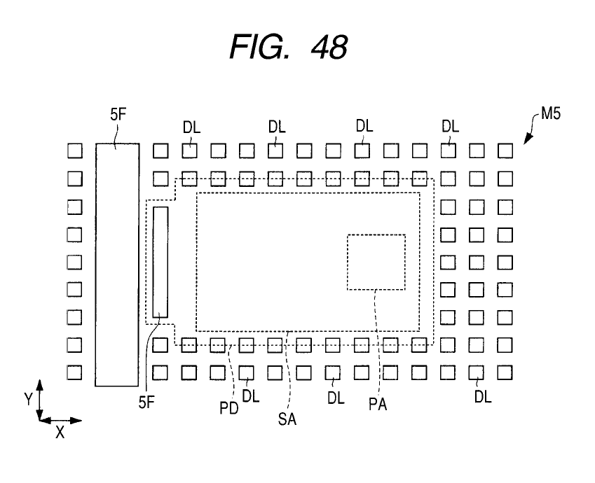

The left sketch in FIG. 47 is a sectional view of the internal area of the semiconductor chip of a semiconductor device in the 11th embodiment, corresponding to the area taken along line Y1-Y1 of FIG. 1. The right sketch is a sectional view of a pad placement area of the same semiconductor chip, corresponding to the area taken along line X1-X1 of FIG. 1. FIG. 48 is a substantial part plan view illustrating the semiconductor chip of a semiconductor device in the 11th embodiment and corresponds to FIG. 37. That is, FIG. 48 illustrates an example of the layout of conductor patterns (fifth wiring 5F and dummy wirings DL) in the fifth wiring layer M5 in proximity to a pad PD formation region. In FIG. 48, the positions of a pad PD, an opening formation region SA, and a probe contact area PA are indicated by broken lines.

The layout of conductor patterns (fourth wiring 5E and dummy wirings DL) in the fourth wiring layer M4 in proximity to a pad PD formation region in the 11th embodiment is substantially identical with that in the seventh embodiment (FIG. 38). Therefore, the graphical representation of the layout will be omitted here.

In the 11th embodiment, an element is not formed under each pad PD as in the seventh to 10th embodiments. Therefore, dummy wirings DL are provided in each of the multiple wiring layers under pads as described in relation to the seventh to 10th embodiments.

Also in the 11th embodiment, however, the following measure is taken in the fifth wiring layer M5 directly under the uppermost wiring layer MH as in the third embodiment: a conductor pattern (fifth wiring 5F, dummy wiring DL, and plug 6C) is not formed directly under the opening formation region SA of each pad PD. Therefore, cracking in an insulating film under a pad PD can be suppressed or prevented as in the third embodiment.

In the fifth wiring layer M5, conductor patterns (fifth wiring 5F, dummy wirings DL, and plugs 6C) are formed in the areas other than directly under the opening formation regions SA. That is, in the fifth wiring layer M5, conductor patterns comprised of the fifth wiring 5F and dummy wirings DL are disposed in, preferably all around, the areas other than directly under the opening formation regions SA.

The minimum process dimensions of the uppermost wiring layer MH are larger than the minimum process dimensions of the fifth wiring layer M5 and lower wiring layers and the focal depth thereof in lithography is large. Therefore, even if some of the dummy wirings DL in the fifth wiring layer M5 are eliminated, degradation in the planarity thereof is acceptable. Dummy wirings DL are disposed in the fourth wiring layer M4 and lower wiring layers even directly under the wire embracing area PWA of each pad PD and thus the planarity of each wiring layer is ensured. Therefore, it is possible to ensure the planarity of wiring layers and thus enhance the accuracy of wiring pattern transfer and formation. For this reason, it is possible to minimize the layout limitation due to degradation in the planarity of wiring layers. Therefore, it is possible to enhance the reliability and yield of the semiconductor device. Further, it is possible to facilitate the reduction of semiconductor chip size. The other configurations and effect are the same as in the third embodiment.

As a modification to the 11th embodiment, the following measure may be taken as in the modification (FIG. 44) to the ninth embodiment: the wire bonding area WA and the probe contact area PA may be so disposed that they at least partly overlap each other (overlap each other on a plane). As a result, the planar size (area) of each pad PD can be reduced and thus the planar size (area) of the semiconductor chip can be reduced.

### 12th Embodiment

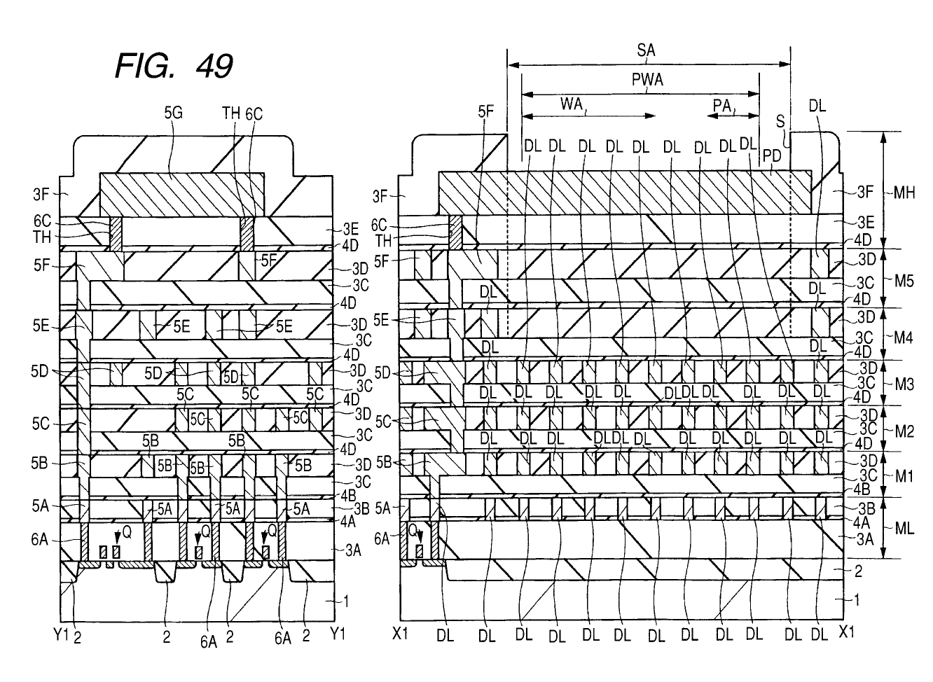

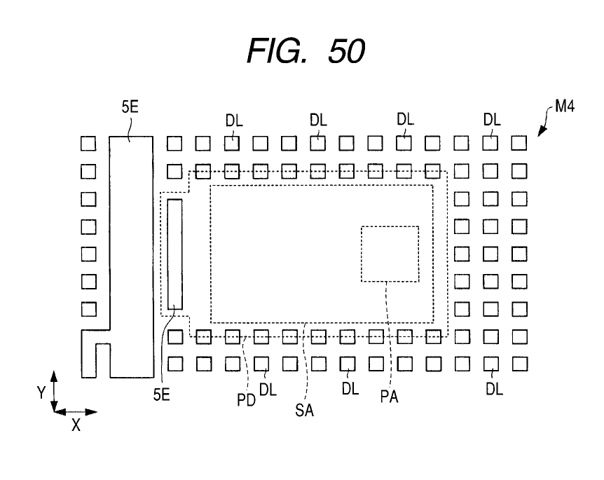

The left sketch in FIG. 49 is a sectional view of the internal area of the semiconductor chip of a semiconductor device in the 12th embodiment, corresponding to the area taken along line Y1-Y1 of FIG. 1. The right sketch is a sectional view of a pad placement area of the same semiconductor chip, corresponding to the area taken along line X1-X1 of FIG. 1. FIG. 50 is a substantial part plan view illustrating the semiconductor chip of a semiconductor device in the 12th embodiment and corresponds to FIG. 38. That is, FIG. 50 illustrates an example of the layout of conductor patterns (fourth wiring 5E and dummy wirings DL) in the fourth wiring layer M4 in proximity a pad PD formation region. In FIG. 50, the positions of a pad PD, an opening formation region SA, and a probe contact area PA are indicated by broken lines.

The layout of conductor patterns (fifth wiring 5F and dummy wirings DL) in the fifth wiring layer M5 in proximity to a pad PD formation region in the 12th embodiment is substantially identical with that in the 11th embodiment (FIG. 48). Therefore, the graphical representation of the layout will be omitted here.

The 12th embodiment is a modification to the 11th embodiment. That is, also in the 12th embodiment, an element is not formed under each pad PD as in the 11th embodiment. Therefore, dummy wirings DL are provided in each of the multiple wiring layers under pads.

The configuration of the semiconductor device in the 12th embodiment is different from that in the 11th embodiment in the following aspect: in the 12th embodiment, the following measure is taken in two layers, the fifth wiring layer M5 directly under the uppermost wiring layer MH and the fourth wiring layer M4: a conductor pattern (fifth wiring 5F, fourth wiring 5E, dummy wiring DL, and plug 6C) is not formed directly under the opening formation region SA of each pad PD.

That is, the measure described below is taken in all the wiring layers without a low-dielectric constant film, low in mechanical strength, above the wiring layers with a low-dielectric constant film. (The wiring layers with a low-dielectric constant film are the first wiring layer M1 to the third wiring layer M3.) (The wiring layers without a low-dielectric constant film are the fourth wiring layer M4 and the fifth wiring layer M5.) The above conductor pattern is selectively eliminated from the relevant areas (directly under the opening formation region SA of each pad PD). As a result, cracking in an insulating film under a pad PD can be more effectively suppressed or prevented than in the second embodiment.

In the fourth wiring layer M4 and the fifth wiring layer M5, conductor patterns (fourth wiring 5E, fifth wiring 5F, dummy wirings DL and plugs 6C) are formed in the areas other than directly under the opening formation regions SA. That is, the following measure is taken in the fourth wiring layer M4 and the fifth wiring layer M5: conductor patterns comprised of the fourth wiring 5E and dummy wirings DL or conductor patterns comprised of the fifth wiring 5F and dummy wirings DL are disposed in, preferably all around, the areas other than directly under the opening formation regions SA.

The minimum process dimensions of the uppermost wiring layer MH and the fifth wiring layer M5 are larger than the minimum process dimensions of the fourth wiring layer M4 and lower wiring layers and the focal depth thereof in lithography is large. Therefore, even if some of the dummy wirings DL in the fifth wiring layer M5 and the fourth wiring layer M4 are eliminated, degradation in the planarity thereof is acceptable. In the 12th embodiment, dummy wirings DL are disposed in the third wiring layer M3 and lower wiring layers even directly under the opening formation region SA of each pad PD and thus the planarity of each wiring layer is ensured. Therefore, it is possible to ensure the planarity of the wiring layers and thus enhance the accuracy of wiring pattern transfer and formation. For this reason, it is possible to minimize the layout limitation due to degradation in the planarity of wiring layers. Therefore, it is possible to enhance the reliability and yield of the semiconductor device. Further, it is possible to facilitate the reduction of semiconductor chip size. With respect to the other aspects, the same effect as in the third and 11th embodiments can be obtained.

As a modification to the 12th embodiment, the following measure may be taken as in the modification (FIG. 44) to the ninth embodiment: the wire bonding area WA and the probe contact area PA may be so disposed that they at least partly overlap each other (overlap each other on a plane). As a result, the planar size (area) of each pad PD can be reduced and thus the planar size (area) of the semiconductor chip can be reduced.

### 13th Embodiment

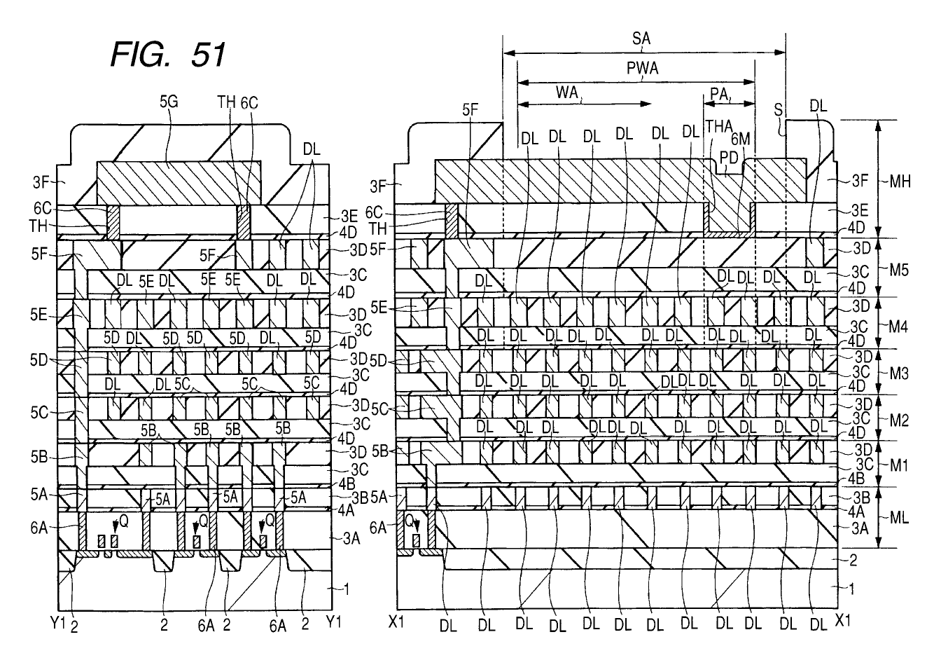

The left sketch in FIG. 51 is a sectional view of the internal area of the semiconductor chip of a semiconductor device in the 13th embodiment, corresponding to the area taken along line Y1-Y1 of FIG. 1. The right sketch is a sectional view of a pad placement area of the same semiconductor chip, corresponding to the area taken along line X1-X1 of the FIG. 1.

The layout of the following in the 13th embodiment is substantially identical with that in the seventh embodiment (FIG. 37 and FIG. 38): the layout of conductor patterns (fifth wiring 5F and dummy wirings DL) in the fifth wiring layer M5 and conductor patterns (fourth wiring 5E and dummy wirings DL) in the fourth wiring layer M4 in proximity to a pad PD formation region. Therefore, the graphical representation of the layout will be omitted here.

In the 13th embodiment, dummy wirings DL are provided in each of the multiple wiring layers in the internal area of the semiconductor chip and an element is not formed under pads PD as in the seventh to 12th embodiments. For this reason, dummy wirings DL are also provided in each of the wiring layers under the pads PD.

In the 13th embodiment, however, the following measure is taken in the fifth wiring layer M5 directly under the uppermost wiring layer MH as in the third embodiment: a conductor pattern (fifth wiring 5F, dummy wiring DL, and plug 6C) is not formed directly under the opening formation region SA of each pad PD. As a result, the same effect as in the third embodiment can be obtained.

Further, in the 13th embodiment, the following measure is taken as in the fourth embodiment: a conductor pattern (second conductor pattern) 6M having a U cross-sectional shape is formed directly under the probe contact area PA (probe mark) of each pad PD in contact with the under surface of the pad PD. More specific description will be given. In the 13th embodiment, a large hole THA is formed in the probe contact area PA of the insulating films 3E, 4D in the uppermost wiring layer MH; and the above conductor pattern 6M having a U cross-sectional shape and part of the conductor film of the pad PD are deposited in this order in the hole THA. The configuration of and the formation method for the conductor pattern 6M are the same as described in relation to the fourth embodiment. As a result, the same effect as in the fourth embodiment can be obtained.

As mentioned above, the minimum process dimensions of the uppermost wiring layer MH are larger than the minimum process dimensions of the fifth wiring layer M5 and lower wiring layers and the focal depth thereof in lithography is large. Therefore, even if some of the dummy wirings DL in the fifth wiring layer M5 are eliminated, degradation in the planarity thereof is acceptable. Dummy wirings DL are disposed in the fourth wiring layer M4 and lower wiring layers even directly under the opening formation region SA of each pad PD and thus the planarity of each wiring layer is ensured. Further, dummy wirings DL are provided in each of the multiple wiring layers in the internal area of the semiconductor chip and thus the planarity of the wiring layers in the internal area is also ensured. Since the planarity of the wiring layers can be ensured as mentioned above, it is possible to enhance the accuracy of wiring pattern transfer and formation. For this reason, it is possible to minimize the layout limitation due to degradation in the planarity of wiring layers. Therefore, it is possible to enhance the reliability and yield of the semiconductor device. Further, it is possible to facilitate the reduction of semiconductor chip size. The other configurations and effect are the same as in the third and fourth embodiments.

As a modification to the 13th embodiment, the following measure may be taken in the fifth wiring layer M5 directly under the uppermost wiring layer MH: a conductor pattern (fifth wiring 5F, dummy wiring DL, and plug 6C) is not provided directly under the probe contact area PA of each pad PD.

In the fifth wiring layer M5 directly under the uppermost wiring layer MH, the following measure may be taken: a conductor pattern (fifth wiring 5F, dummy wiring DL, and plug 6C) is not provided directly under the wire embracing area PWA of each pad PD.

### 14th Embodiment

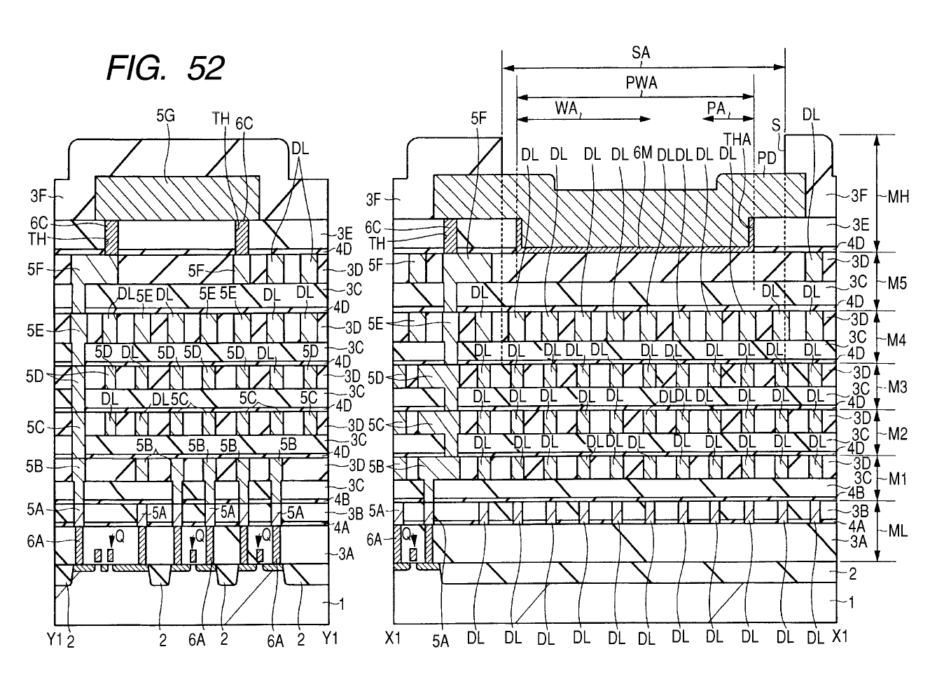

The left sketch in FIG. 52 is a sectional view of the internal area of the semiconductor chip of a semiconductor device in the 14th embodiment, corresponding to the area taken along line Y1-Y1 of FIG. 1. The right sketch is a sectional view of a pad placement area of the same semiconductor chip, corresponding to the area taken along line X1-X1 of FIG. 1.

The layout of the following in the 14th embodiment is substantially identical with that in the ninth embodiment (FIG. 43 and FIG. 38): the layout of conductor patterns (fifth wiring 5F and dummy wirings DL) in the fifth wiring layer M5 and conductor patterns (fourth wiring 5E and dummy wirings DL) in the fourth wiring layer M4 in proximity to a pad PD formation region. Therefore, the graphical representation of the layout will be omitted here.

In the 14th embodiment, dummy wirings DL are provided in each of the multiple wiring layers in the internal area of the semiconductor chip and an element is not formed under pads PD as in the seventh to 13th embodiments. For this reason, dummy wirings DL are provided in each of the wiring layers under the pads.

In the 14th embodiment, however, the following measure is taken in the fifth wiring layer M5 directly under the uppermost wiring layer MH as in the third embodiment: a conductor pattern (fifth wiring 5F, dummy wiring DL, and plug 6C) is not formed directly under the opening formation region SA of each pad PD. As a result, the same effect as in the third embodiment can be obtained.

Further, in the 14th embodiment, the following measure is taken as in the fifth embodiment: a conductor pattern (second conductor pattern) 6M having a U cross-sectional shape is formed directly under the wire embracing area PWA of each pad PD in contact with the under surface of the pad PD. More specific description will be given. In the 14th embodiment, a large hole THA is formed in the wire embracing area PWA of the insulating films 3E, 4D in the uppermost wiring layer MH; and the above conductor pattern 6M having a U cross-sectional shape and part of the conductor film of the pad PD are deposited in this order in the hole THA. The configuration of and the formation method for the conductor pattern 6M are the same as described in relation to the fourth embodiment. As a result, the same effect as in the fourth and fifth embodiments can be obtained.

As mentioned above, the minimum process dimensions of the uppermost wiring layer MH are larger than the minimum process dimensions of the fifth wiring layer M5 and lower wiring layers and the focal depth thereof in lithography is large. Therefore, even if some of the dummy wirings DL in the fifth wiring layer M5 are eliminated, degradation in the planarity thereof is acceptable. Dummy wirings DL are disposed in the fourth wiring layer M4 and lower wiring layers even directly under the opening formation region SA of each pad PD and thus the planarity of each wiring layer is ensured. Further, dummy wirings DL are provided in each of the wiring layers in the internal area of the semiconductor chip and thus the planarity of the wiring layers in the internal area is also ensured. Since the planarity of the wiring layers can be ensured as mentioned above, it is possible to enhance the accuracy of wiring pattern transfer and formation. For this reason, it is possible to minimize the layout limitation due to degradation in the planarity of wiring layers. Therefore, it is possible to enhance the reliability and yield of the semiconductor device. Further, it is possible to facilitate the reduction of semiconductor chip size. The other configurations and effect are the same as in the third and fifth embodiments.

As a modification to the 14th embodiment, the following measure may be taken in the fifth wiring layer M5 directly under the uppermost wiring layer MH: a conductor pattern (fifth wiring 5F, dummy wiring DL, and plug 6C) is not provided directly under the wire embracing area PWA of each pad PD.

As another modification to the 14th embodiment, the following measure may be taken as in the modification (FIG. 44) to the ninth embodiment: the wire bonding area WA and the probe contact area PA are so disposed that they at least partly overlap each other (overlap each other on a plane). As a result, the planar size (area) of each pad PD can be reduced and thus the planar size (area) of the semiconductor chip can be reduced.

### 15th Embodiment

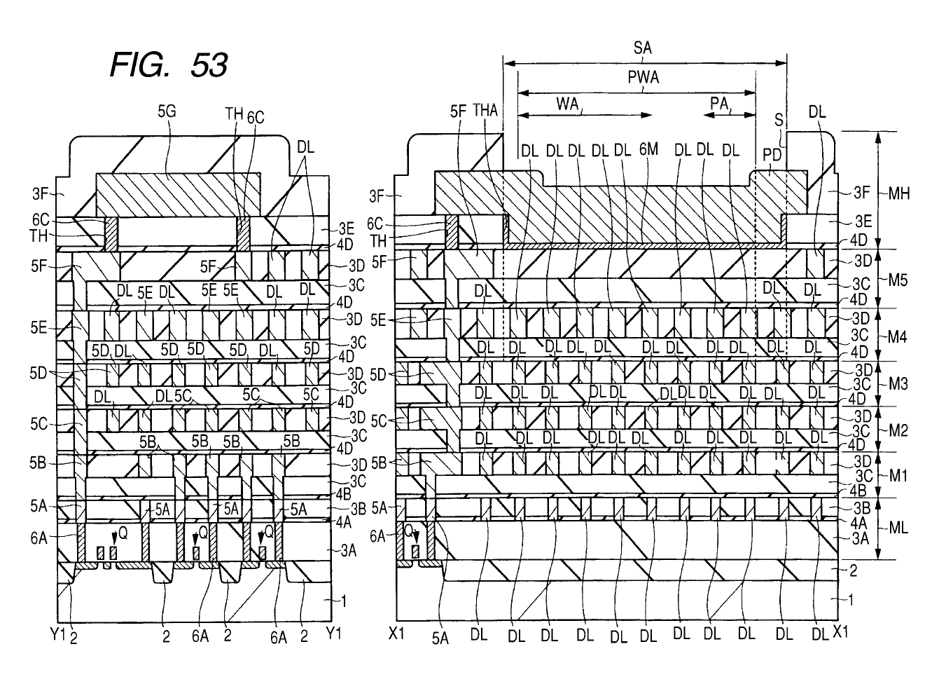

The left sketch in FIG. 53 is a sectional view of the internal area of the semiconductor chip of a semiconductor device in the 15th embodiment, corresponding to the area taken along line Y1-Y1 of FIG. 1. The right sketch is a sectional view of a pad placement area of the same semiconductor chip, corresponding to the area taken along line X1-X1 of FIG. 1.

The layout of the following in the 15th embodiment is substantially identical with that in the 11th embodiment (FIG. 48 and FIG. 38): the layout of conductor patterns (fifth wiring 5F and dummy wirings DL) in the fifth wiring layer M5 and conductor patterns (fourth wiring 5E and dummy wirings DL) in the fourth wiring layer M4 in proximity to a pad PD formation region. Therefore, the graphical representation of the layout will be omitted here.

In the 15th embodiment, dummy wirings DL are provided in each of the multiple wiring layers in the internal area of the semiconductor chip and an element is not formed under pads PD as in the seventh to 14th embodiments. For this reason, dummy wirings DL are provided in each of the wiring layers under the pads.

In the 15th embodiment, however, the following measure is taken in the fifth wiring layer M5 directly under the uppermost wiring layer MH as in the third embodiment: a conductor pattern (fifth wiring 5F, dummy wiring DL, and plug 6C) is not formed directly under the opening formation region SA of each pad PD. As a result, the same effect as in the third embodiment can be obtained.

Further, in the 15th embodiment, the following measure is taken as in the sixth embodiment: a conductor pattern (second conductor pattern) 6M having a U cross-sectional shape is formed directly under the opening formation region SA of each pad PD in contact with the under surface of the pad PD. More specific description will be given. In the 15th embodiment, a large hole THA is formed in the opening formation region SA of the insulating films 3E, 4D in the uppermost wiring layer MH; and the above conductor pattern 6M having a U cross-sectional shape and part of the conductor film of the pad PD are deposited in this order in the hole THA. The configuration of and the formation method for the conductor pattern 6M are the same as described in relation to the fourth embodiment. As a result, the same effect as in the fourth and sixth embodiments can be obtained.

As mentioned above, the minimum process dimensions of the uppermost wiring layer MH are larger than the minimum process dimensions of the fifth wiring layer M5 and lower wiring layers and the focal depth thereof in lithography is large. Therefore, even if some of the dummy wirings DL in the fifth wiring layer M5 are eliminated, degradation in the planarity thereof is acceptable. Dummy wirings DL are disposed in the fourth wiring layer M4 and lower wiring layers even directly under the opening formation region SA of each pad PD and thus the planarity of each wiring layer is ensured. Further, dummy wirings DL are provided in each of the multiple wiring layers in the internal area of the semiconductor chip and thus the planarity of the wiring layers in the internal area is also ensured. Since the planarity of the wiring layers can be ensured as mentioned above, it is possible to enhance the accuracy of wiring pattern transfer and formation. For this reason, it is possible to minimize the layout limitation due to degradation in the planarity of wiring layers. Therefore, it is possible to enhance the reliability and yield of the semiconductor device. Further, it is possible to facilitate the reduction of semiconductor chip size. The other configurations and effect are the same as in the third and sixth embodiments.

As a modification to the 15th embodiment, the following measure may be taken as in the modification (FIG. 44) to the ninth embodiment: the wire bonding area WA and the probe contact area PA are so disposed that they at least partly overlap each other (overlap each other on a plane). As a result, the planar size (area) of each pad PD can be reduced and the planar size (area) of the semiconductor chip can be reduced.

### 16th Embodiment

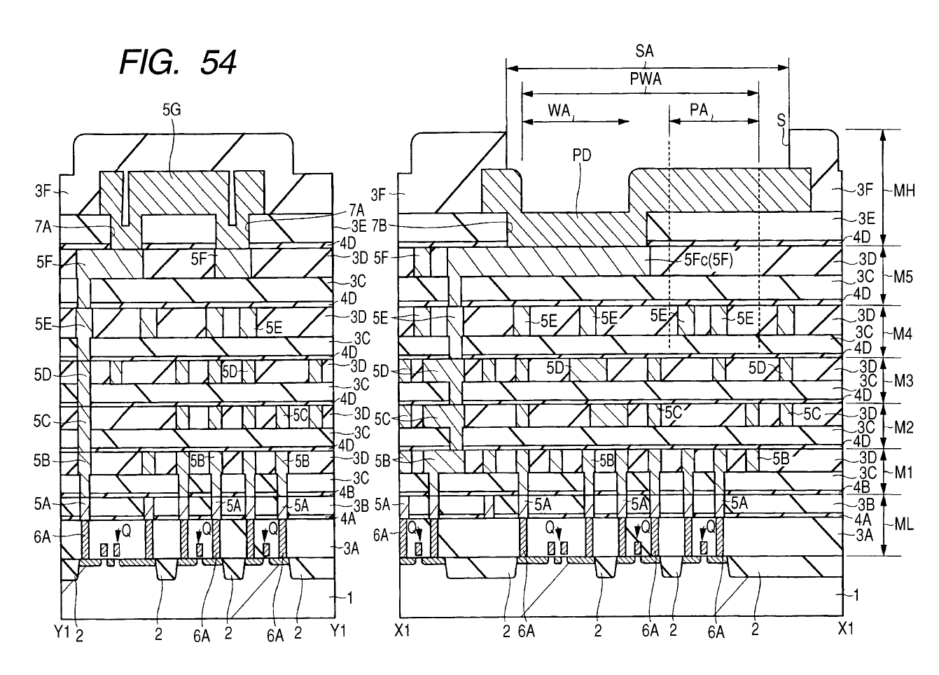

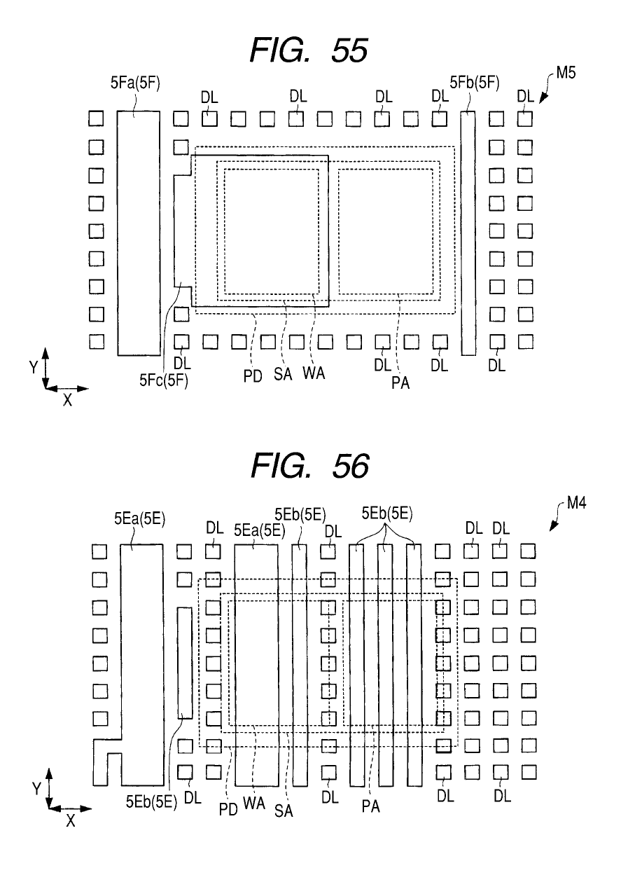

The left sketch in FIG. 54 is a sectional view of the internal area of the semiconductor chip of a semiconductor device in the 16th embodiment, corresponding to the area taken along line Y1-Y1 of FIG. 1. The right sketch is a sectional view of a pad placement area of the same semiconductor chip, corresponding to the area taken along line X1-X1 of FIG. 1. FIG. 55 and FIG. 56 are substantial part plan views illustrating the semiconductor chip of a semiconductor device in the 16th embodiment and respectively correspond to FIG. 5 and FIG. 6. That is, FIG. 55 illustrates an example of the layout of conductor patterns (fifth wiring 5F and dummy wirings DL) in the fifth wiring layer M5 in proximity to a pad PD formation region; and FIG. 56 illustrates an example of the layout of conductor patterns (fourth wiring 5E and dummy wirings DL) in the fourth wiring layer M4 in proximity to the pad PD formation region. In FIG. 55 and FIG. 56, the positions of a pad PD, an opening formation region SA, a probe contact area PA, and a wire bonding area WA are indicated by broken lines.

The 16th embodiment corresponds to another modification obtained by omitting the formation of plugs 6C in the modification to the semiconductor chip of a semiconductor device in the first embodiment, illustrated in FIG. 16 and FIG. 17.

In the 16th embodiment, the above plugs 6C are not formed. Instead, the following measure is taken as illustrated in FIG. 54: openings (holes, through holes) 7A, 7B are formed in the insulating films 3E, 4D and the uppermost wiring 5G and the pads PD are so formed that the openings 7A, 7B are filled therewith. In the openings 7A, there is formed (disposed) part of the uppermost wiring 5G; and in the openings 7B, there is formed (disposed) part of each pad PD.

That is, in the 16th embodiment, the uppermost wiring 5G and the pads PD are formed by carrying out the steps of: after obtaining the structure in FIG. 14 as in the first embodiment, depositing the insulating films 4D, 3E; thereafter, forming the openings 7A, 7B exposing the fifth wiring 5F in the insulating films 3E, 4D; forming a conductor film for the formation of the uppermost wiring 5G and the pads PD over the insulating film 3E including the interior of the openings 7A, 7B; and patterning this conductor film. The steps after the formation of the uppermost wiring 5G and the pads PD are the same as in the first embodiment.

For this reason, the following is implemented in the 16th embodiment: the uppermost wiring 5G and part of each pad PD (part in the openings 7A, 7B) also function as the above plug 6C; the uppermost wiring 5G is electrically coupled with the fifth wiring 5F at the bottom of each opening 7A; and each pad PD is electrically coupled with the fifth wiring 5F (that is, the wiring 5Fc of the fifth wiring 5F) at the bottom of each opening 7B.

The conductor film (the above barrier metal films BM2, BM3 and main wiring member MM2) for the formation of the uppermost wiring 5G and the pads PD is formed by sputtering. Therefore, the conductor film is lower in coverage than tungsten films formed by CVD. For this reason, if the bore of the openings 7A, 7B (diameter of the openings) is too small, the conductor film for the formation of the uppermost wiring 5G and the pads PD cannot be favorably formed in the openings 7A, 7B. As a result, there is a possibility that the electrical coupling cannot be ensured between the uppermost wiring 5G and the pads PD and the fifth wiring 5F. Therefore, it is desirable that the bore of the openings 7A, 7B (diameter of the openings) should be 1 μm or above. In this case, the electrical coupling can be appropriately ensured between the uppermost wiring 5G and the pads PD and the fifth wiring 5F. Since the bore of the openings 7A must be increased (to 1 μm or above) as compared with the through holes filled with the above plug 6C, the area required for the internal area (the left sketch in FIG. 54) of the semiconductor chip is accordingly somewhat increased. However, since the step of forming the plugs 6C can be omitted, it is possible to reduce the number of the steps of the manufacturing process for the semiconductor device and thus reduce the manufacturing cost of the semiconductor device.

Meanwhile, the size of the openings 7B is set to a size substantially equal to that of each wire bonding area WA. (That is, each opening 7B is provided in an entire wire bonding area WA.) The portion of each pad PD placed in an opening 7B is taken as a wire bonding area WA. Each probe contact area PA is provided in a portion of a pad PD positioned outside the opening 7B. Thus increase in the area of each pad formation region can be avoided.

Of the fifth wiring 5F, the wiring 5Fc coupled with a pad PD at the bottom of an opening 7B has such a pattern in which the opening 7B is embraced on a plane. (The area of the wiring 5Fc is equivalent to, for example, half the area of a pad PD.) However, the wiring 5Fc is not extended to under the probe contact area PA.

In the 16th embodiment, as seen from FIG. 54 to FIG. 56, the following measure is taken in the fifth wiring layer M5 directly under the uppermost wiring layer MH: a conductor pattern (fifth wiring 5F and dummy wiring DL) is not formed directly under the probe contact area PA of each pad PD. In the fifth wiring layer M5, conductor patterns (fifth wiring 5F and dummy wirings DL) are formed in the areas other than directly under the probe contact area PA of each pad PD. That is, in the fifth wiring layer M5, conductor patterns comprised of the fifth wiring 5F and dummy wirings DL are disposed in, preferably all around, the areas other than directly under the probe contact areas PA. In the 16th embodiment, conductor patterns (wiring, dummywirings, plugs) are formed in the lowermost wiring layer ML to the fourth wiring layer M4 even directly under the probe contact area PA of each pad PD. Also in the 16th embodiment, the same effect as in the first embodiment can be obtained.

Further, since the step of forming the plugs 6C can be omitted in the 16th embodiment, it is possible to reduce the number of the steps of the manufacturing process for the semiconductor device and reduce the manufacturing cost of the semiconductor device.

Up to this point, concrete description has been given to the invention made by the present inventors based on embodiments of the invention. However, the invention is not limited to the above embodiments and can be variously modified without departing from the subject matter of the invention, needless to add.

The above description has been given mainly to cases where the invention made by the present inventors is applied to semiconductor devices, which is the field of utilization underlying the invention. However, the invention is not limited to these cases and can be applied to various fields. For example, the invention is also applicable to liquid crystal display devices and MEMSs (Micro Electro Mechanical Systems).

The invention can be applied to the manufacturing industry of semiconductor devices.

What is claimed is:

1. A semiconductor device comprising:
a semiconductor substrate having a first principal surface and a second principal surface positioned opposite to each other along the direction of thickness;
a plurality of elements formed in the first principal surface of the semiconductor substrate;
a plurality of wiring layers formed over the first principal surface of the semiconductor substrate; and
junctions electrically coupling the wiring layers together,
wherein each of the wiring layers includes conductor patterns and an insulating film insulating the conductor patterns from each other,
wherein of the wiring layers the uppermost wiring layer includes an external terminal formed of the conductor pattern and the insulating film having an opening exposing part of the external terminal, and
wherein the conductor pattern is not formed directly under a first area of the external terminal in the wiring layer directly under the uppermost wiring layer.

2. The semiconductor device according to claim 1,
wherein the first area is a contact area for a probe.

3. The semiconductor device according to claim 1,
wherein the first area includes a contact area for a probe and a bonding area for a bonding wire.

4. The semiconductor device according to claim 1,
wherein the first area is a formation region for the opening formed in the insulating film of the uppermost wiring layer.

5. The semiconductor device according to claim 1,
wherein in wiring layers lower than the wiring layer directly under the uppermost wiring layer, the conductor pattern is formed directly under the first area of the external terminal.

6. The semiconductor device according to claim 1,
wherein in the wiring layer directly under the wiring layer directly under the uppermost wiring layer, the conductor pattern having a width exceeding 2 μm is not formed directly under the first area of the external terminal.

7. The semiconductor device according to claim 6,
wherein in the wiring layer directly under the wiring layer directly under the uppermost wiring layer, the conductor pattern having a width of 2 μm or below is formed directly under the first area of the external terminal.

8. The semiconductor device according to claim 1,
wherein in the wiring layer directly under the wiring layer directly under the uppermost wiring layer, the conductor pattern is not formed directly under the first area of the external terminal, and
wherein in wiring layers lower than the wiring layer directly under the wiring layer directly under the uppermost wiring layer, the conductor pattern is formed directly under the first area of the external terminal.

9. The semiconductor device according to claim 1,
wherein the conductor pattern is a wiring or a dummy pattern.

10. The semiconductor device according to claim 1,
wherein the conductor pattern in a desired wiring layer of the wiring layers is formed by filling a wiring opening formed in the insulating film with a conductor film.

11. The semiconductor device according to claim 1,
wherein the conductor pattern is formed using copper as the principal material.

12. The semiconductor device according to claim 1,
wherein the insulating film in a desired wiring layer of the wiring layers is formed of a material lower in dielectric constant than silicon oxide.

13. The semiconductor device according to claim 1,
wherein the element is formed in the first principal surface of the semiconductor substrate directly under the external terminal.

14. The semiconductor device according to claim 1,
wherein the element is not formed in the first principal surface of the semiconductor substrate directly under the external terminal.

15. A semiconductor device comprising:
a semiconductor substrate having a first principal surface and a second principal surface positioned opposite to each other along the direction of thickness;
a plurality of elements formed in the first principal surface of the semiconductor substrate;
a plurality of wiring layers formed over the first principal surface of the semiconductor substrate; and
junctions electrically coupling the wiring layers together,
wherein each of the wiring layers includes first conductor patterns and an insulating film insulating the first conductor patterns from each other;
wherein of the wiring layers, the uppermost wiring layer includes an external terminal formed of the first conductor pattern and the insulating film having an opening exposing part of the external terminal;
wherein a second conductor pattern having a U cross-sectional shape is formed directly under a first area of the external terminal in contact with the under surface of the external terminal,
wherein the second conductor pattern is formed of high-melting point metal, high-melting point metal nitride, or a laminated body thereof,
wherein the second conductor pattern is so formed that the second conductor pattern does not have an interface in the first area of the external terminal, and
wherein in the wiring layer directly under the uppermost wiring layer, the first conductor pattern does not exist directly under the first area of the external terminal or the second conductor pattern.

16. The semiconductor device according to claim 15,
wherein the first area is a contact area for a probe.

17. The semiconductor device according to claim 15,
wherein the first area includes a contact area for a probe and a bonding area for a bonding wire.

18. The semiconductor device according to claim 15,
wherein the first area is a formation region for the opening formed in the insulating film of the uppermost wiring layer.

19. The semiconductor device according to claim 15,
wherein in wiring layers lower than the wiring layer directly under the uppermost wiring layer, the first conductor pattern is formed directly under the first area of the external terminal.

20. The semiconductor device according to claim 15,
wherein in the wiring layer directly under the wiring layer directly under the uppermost wiring layer, the first conductor pattern is not formed directly under the first area of the external terminal, and
wherein in wiring layers lower than the wiring layer directly under the wiring layer directly under the uppermost wiring layer, the first conductor pattern is formed directly under the first area of the external terminal.

21. The semiconductor device according to claim 15,
wherein the first conductor pattern is a wiring or a dummy pattern.

22. The semiconductor device according to claim 15,
wherein the first conductor pattern in a desired wiring layer of the wiring layers is formed by filling a wiring opening formed in the insulating film with a conductor film.

23. The semiconductor device according to claim 15,
wherein the first conductor pattern is formed using copper as the principal material.

24. The semiconductor device according to claim 15,
wherein the insulating film in a desired wiring layer of the wiring layers is formed of a material lower in dielectric constant than silicon oxide.

25. The semiconductor device according to claim 15,
wherein the elements are formed in the first principal surface of the semiconductor substrate directly under the external terminal.

26. The semiconductor device according to claim 15,
wherein the elements are not formed in the first principal surface of the semiconductor substrate directly under the external terminal.

27. The semiconductor device according to claim 15,
wherein the second conductor pattern is formed of tungsten, titanium, tantalum, tungsten nitride, titanium nitride, tantalum nitride, or a laminated body of two or more materials selected from thereamong.

28. A method of manufacturing a semiconductor device, comprising the steps of:
(a) preparing a semiconductor substrate having a first principal surface and a second principal surface positioned opposite to each other along the direction of thickness;
(b) forming a plurality of elements in the first principal surface of the semiconductor substrate; and
(c) forming a plurality of wiring layers over the first principal surface of the semiconductor substrate, wherein the step of (c) includes the steps of:
(c1) forming an insulating film and a conductor pattern in each of the wiring layers; and
(c2) forming junctions electrically coupling the wiring layers together, and
wherein the step of (c1) includes the steps of:
forming an external terminal formed of the conductor pattern in the uppermost wiring layer of the wiring layers; and
at the step of forming the wiring layer directly under the uppermost wiring layer, preventing the conductor pattern from being formed directly under a first area of the external terminal and forming the conductor pattern in the other areas.

29. The method of manufacturing a semiconductor device according to claim 28,
wherein the conductor pattern is formed by chemical mechanical polishing.

30. A method of manufacturing a semiconductor device, comprising the steps of:
(a) preparing a semiconductor substrate having a first principal surface and a second principal surface positioned opposite to each other along the direction of thickness;
(b) forming a plurality of elements in the first principal surface of the semiconductor substrate; and
(c) forming a plurality of wiring layers over the first principal surface of the semiconductor substrate,
wherein the step of (c) includes the steps of:
(c1) forming an insulating film and a first conductor pattern in each of the wiring layers; and
(c2) forming junctions electrically coupling the wiring layers together,
wherein the step of (c1) includes the steps of:
forming an external terminal formed of the first conductor pattern in the uppermost wiring layer of the wiring layers; and
at the step of forming the wiring layer directly under the uppermost wiring layer, preventing the first conductor pattern from being formed directly under a first area of the external terminal and forming the first conductor pattern in the other areas,
wherein the step of (c2) includes the step of:
at the step of forming the junctions electrically coupling together the first conductor patterns in the uppermost wiring layer and the wiring layer directly under the uppermost wiring layer, forming a second conductor pattern having a U cross-sectional shape directly under the first area of the external terminal in contact with the under surface of the external terminal, and
wherein the second conductor pattern is formed of high-melting point metal, high-melting point metal nitride, or a laminated body thereof so that the second conductor pattern does not have an interface in the first area.

31. The method of manufacturing a semiconductor device according to claim 30,
wherein the first conductor pattern is formed by chemical mechanical polishing.

32. The method of manufacturing a semiconductor device according to claim 30,
wherein the junctions and the second conductor pattern are formed by chemical mechanical polishing.
